(19) United States
(12) Patent Application Publication
(10) Pub. No.: US 2025/0081424 A1
(43) Pub. Date: Mar. 6, 2025

(54) Semiconductor Device

(71) Applicant: Semiconductor Energy Laboratory Co., Ltd., Kanagawa-ken (JP)

(72) Inventors: Tsutomu MURAKAWA, Isehara (JP); Hiromi SAWAI, Atsugi (JP); Motomu KURATA, Isehara (JP); Sachiaki TEZUKA, Atsugi (JP); Jun YAMADA, Isehara (JP); Shunpei YAMAZAKI, Tokyo (JP)

(73) Assignee: Semiconductor Energy Laboratory Co., Ltd., Kanagawa-ken (JP)

(21) Appl. No.: 18/816,312

(22) Filed: Aug. 27, 2024

(30) Foreign Application Priority Data
Aug. 31, 2023 (JP) 2023-141469
Sep. 12, 2023 (JP) 2023-147298

(51) Int. Cl. H10B 12/00

(52) U.S. Cl. CPC H10B 12/00

(57) ABSTRACT

A semiconductor device that can be highly integrated is provided. The semiconductor device includes first and second transistors. The first transistor includes a semiconductor layer, a pair of first conductive layers, and a pair of second conductive layers over the pair of first conductive layers. The pair of first conductive layers and the pair of second conductive layers function as a source electrode and a drain electrode of the first transistor. A third conductive layer functioning as a gate electrode of the second transistor is in contact with one of the pair of first conductive layers. In a cross-sectional view of the first transistor in the channel width direction, the height of the semiconductor layer is larger than the width of the semiconductor layer. The semiconductor device can include a capacitor, in which the third conductive layer also functions as one of a pair of electrodes.

### BACKGROUND OF THE INVENTION

### 1. Field of the Invention

One embodiment of the present invention relates to a semiconductor device, a memory device, and an electronic device each including an oxide semiconductor layer. One embodiment of the present invention relates to a method for manufacturing the semiconductor device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), a method for driving any of them, and a method for manufacturing any of them.

In this specification and the like, a semiconductor device generally means a device that can function by utilizing semiconductor characteristics. A semiconductor element such as a transistor, a semiconductor circuit, an arithmetic device, and a memory device are each an embodiment of the semiconductor device. A display device (e.g., a liquid crystal display device and a light-emitting display device), a projection device, a lighting device, an electro-optical device, a power storage device, a memory device, a semiconductor circuit, an imaging device, an electronic device, and the like may include a semiconductor device.

### 2. Description of the Related Art

In recent years, semiconductor devices have been developed; an LSI, a central processing unit (CPU), a memory, and the like have been mainly used for semiconductor devices. A CPU is an aggregation of semiconductor elements; the CPU includes a semiconductor integrated circuit (including at least a transistor and a capacitor) formed into a chip by processing a semiconductor wafer, and is provided with an electrode that is a connection terminal.

A semiconductor circuit (IC chip) of an LSI, a CPU, a memory, or the like is mounted on a circuit board, for example, a printed wiring board, to be used as one of components of a variety of electronic devices.

A technique by which a transistor is formed using a semiconductor thin film formed over a substrate having an insulating surface has been attracting attention. The transistor is used in a wide range of electronic devices such as an integrated circuit (IC) and an image display device (also simply referred to as a display device). A silicon-based semiconductor material is widely known as a material for a semiconductor thin film that can be used in a transistor. As another material, an oxide semiconductor has been attracting attention.

It is known that a transistor including an oxide semiconductor has an extremely low leakage current in an off state. For example, Patent Document 1 discloses a low-power CPU utilizing a characteristic of a low leakage current of the transistor including an oxide semiconductor. Furthermore, for example, Patent Document 2 discloses a memory device that can retain stored data for a long time by utilizing a characteristic of a low leakage current of the transistor including an oxide semiconductor.

### REFERENCES

[Patent Document 1] Japanese Published Patent Application No. 2012-257187
[Patent Document 2] Japanese Published Patent Application No. 2011-151383

### SUMMARY OF THE INVENTION

An object of one embodiment of the present invention is to provide a semiconductor device that operates at high speed. Another object of one embodiment of the present invention is to provide a semiconductor device that can be miniaturized or highly integrated. Another object of one embodiment of the present invention is to provide a semiconductor device with favorable electrical characteristics. Another object of one embodiment of the present invention is to provide a semiconductor device with a small variation in electrical characteristics of transistors. Another object of one embodiment of the present invention is to provide a highly reliable semiconductor device. Another object of one embodiment of the present invention is to provide a semiconductor device with a high on-state current. Another object of one embodiment of the present invention is to provide a semiconductor device with low power consumption. Another object of one embodiment of the present invention is to provide a novel semiconductor device. Another object of one embodiment of the present invention is to provide a method for manufacturing a semiconductor device with high productivity. Another object of one embodiment of the present invention is to provide a method for manufacturing a novel semiconductor device.

Another object of one embodiment of the present invention is to provide a memory device that can be miniaturized or highly integrated. Another object of one embodiment of the present invention is to provide a memory device having large memory capacity. Another object of one embodiment of the present invention is to provide a memory device that operates at high speed. Another object of one embodiment of the present invention is to provide a memory device with low power consumption. Another object of one embodiment of the present invention is to provide a novel memory device.

Note that the description of these objects does not preclude the existence of other objects. One embodiment of the present invention does not need to achieve all of these objects. Other objects can be derived from the description of the specification, the drawings, and the claims.

One embodiment of the present invention is a semiconductor device including a first transistor, a second transistor, and a first insulating layer. The first transistor includes a first semiconductor layer, first to fifth conductive layers, and a second insulating layer. The second transistor includes a second semiconductor layer, a sixth conductive layer, and a third insulating layer. The first and second semiconductor layers are positioned to be apart from each other over a substrate. The first and second conductive layers are positioned over the first semiconductor layer. The third conductive layer is positioned over the first conductive layer. The fourth conductive layer is positioned over the second conductive layer. The first insulating layer is positioned over the third conductive layer, the fourth conductive layer, and the second semiconductor layer and has a first opening and a second opening. The first opening is provided to be overlap with a region between the third and fourth conductive layers. The second opening is provided to be overlap with at least part of the second conductive layer and at least part of the second semiconductor layer. The second insulating layer is positioned to be overlap with the first semiconductor layer in the first opening. The fifth conductive layer is positioned over the second insulating layer in the first opening. The third insulating layer is positioned to be overlap with the second semiconductor layer in the second opening and has a third opening overlapping with at least the part of the second conductive layer. The sixth conductive layer includes a region overlapping with the second semiconductor layer with the third insulating layer therebetween in the second opening, and a region in contact with at least the part of the second conductive layer in the third opening. In a cross-sectional view in a channel width direction, a height of the first semiconductor layer is larger than a width of the first semiconductor layer.

In the above semiconductor device, in a cross-sectional view of the second transistor in a channel width direction, the first semiconductor layer preferably includes a region facing the second semiconductor layer.

In the above semiconductor device, a shortest distance between the first and second conductive layers is preferably smaller than a shortest distance between the third and fourth conductive layers.

In the above semiconductor device, the fifth and sixth conductive layers preferably contain the same material.

The above semiconductor device preferably includes a fourth insulating layer. The fourth insulating layer preferably includes, in the first opening, a region in contact with at least part of a top surface of the first conductive layer, a region in contact with at least part of a top surface of the second conductive layer, a region in contact with a side surface of the third conductive layer, and a region in contact with a side surface of the fourth conductive layer.

In the above semiconductor device, the second transistor preferably includes seventh to tenth conductive layers. The seventh and eighth conductive layers are preferably positioned over the second semiconductor layer. The ninth conductive layer is preferably positioned over the seventh conductive layer. The tenth conductive layer is preferably positioned over the eighth conductive layer. The second opening is preferably provided to be overlap with a region between the ninth and tenth conductive layers.

The above semiconductor device preferably includes a fifth insulating layer. The fifth insulating layer preferably includes, in the second opening, a region in contact with at least part of a top surface of the seventh conductive layer, a region in contact with at least part of a top surface of the eighth conductive layer, a region in contact with a side surface of the ninth conductive layer, a region in contact with a side surface of the tenth conductive layer, and a region in contact with a side surface of the fourth conductive layer and at least part of a top surface of the second conductive layer.

In the above semiconductor device, the first, second, seventh, and eighth conductive layers each preferably contain titanium and nitrogen.

In the above semiconductor device, the third, fourth, ninth, and tenth conductive layers each preferably contain tungsten.

One embodiment of the present invention is a semiconductor device including a first transistor including a first semiconductor layer, a second transistor including a second semiconductor layer, a capacitor, a third semiconductor layer, and a first insulating layer. The first transistor includes first to fifth conductive layers and a second insulating layer. The second transistor includes a sixth conductive layer and a third insulating layer. The capacitor includes a seventh conductive layer, the third insulating layer, and the sixth conductive layer. The first, second, and third semiconductor layers are positioned to be apart from each other over a substrate. The first and second conductive layers are positioned over the first semiconductor layer. The third conductive layer is positioned over the first conductive layer. The fourth conductive layer is positioned over the second conductive layer. The seventh conductive layer is positioned over the third conductive layer. The first insulating layer is positioned over the third conductive layer, the fourth conductive layer, the second semiconductor layer, and the seventh conductive layer and has a first opening and a second opening. The first opening is provided to be overlap with a region between the third and fourth conductive layers. The second opening is provided to be overlap with at least part of the second conductive layer, at least part of the seventh conductive layer, and at least part of the second semiconductor layer. The second insulating layer is positioned to be overlap with the first semiconductor layer in the first opening. The fifth conductive layer is positioned over the second insulating layer in the first opening. The third insulating layer is positioned to be overlap with the second semiconductor layer in the second opening and has a third opening overlapping with at least the part of the second conductive layer. The sixth conductive layer includes a region overlapping with the second semiconductor layer with the third insulating layer therebetween and a region overlapping with the seventh conductive layer with the third insulating layer therebetween in the second opening, and a region in contact with at least the part of the second conductive layer in the third opening. In a cross-sectional view in a channel width direction, a height of the first semiconductor layer is larger than a width of the first semiconductor layer.

In the above semiconductor device, in a cross-sectional view of the second transistor in a channel width direction, the first semiconductor layer preferably includes a region facing the second semiconductor layer, and the second semiconductor layer preferably includes a region facing the third semiconductor layer.

In the above semiconductor device, a shortest distance between the first and second conductive layers is preferably smaller than a shortest distance between the third and fourth conductive layers.

In the above semiconductor device, the fifth and sixth conductive layers preferably contain the same material.

The above semiconductor device preferably includes a fourth insulating layer. The fourth insulating layer preferably includes, in the first opening, a region in contact with at least part of a top surface of the first conductive layer, a region in contact with at least part of a top surface of the second conductive layer, a region in contact with a side surface of the third conductive layer, and a region in contact with a side surface of the fourth conductive layer.

In the above semiconductor device, the second transistor preferably includes eighth to eleventh conductive layers. The eighth and ninth conductive layers are preferably positioned over the second semiconductor layer. The tenth conductive layer and the eleventh conductive layer are preferably positioned over the eighth conductive layer and the ninth conductive layer, respectively. The second opening is preferably provided to be overlap with a region between the tenth and eleventh conductive layers.

The above semiconductor device preferably includes a fifth insulating layer. The fifth insulating layer preferably includes, in the second opening, a region in contact with at least part of a top surface of the eighth conductive layer, a region in contact with at least part of a top surface of the ninth conductive layer, a region in contact with a side surface of the tenth conductive layer, a region in contact with a side surface of the eleventh conductive layer, a region in contact with a side surface of the fourth conductive layer and at least part of a top surface of the second conductive layer, and a region between the sixth and seventh conductive layers.

In the above semiconductor device, the first, second, seventh, eighth, and ninth conductive layers each preferably contain titanium and nitrogen.

In the above semiconductor device, the third, fourth, tenth, and eleventh conductive layers each preferably contain tungsten.

In the above semiconductor device, the first semiconductor layer preferably contains indium. The first semiconductor layer is preferably perpendicular or substantially perpendicular to a surface of the substrate. In cross-sectional observation of the first semiconductor layer with a transmission electron microscope, bright spots arranged in a layered manner in a direction perpendicular to the surface of the substrate are preferably observed.

In the above semiconductor device, the first semiconductor layer preferably contains indium. The first semiconductor layer is preferably perpendicular or substantially perpendicular to a surface of the substrate. The first semiconductor layer preferably includes a first region, a second region in contact with the first region, and a third region in contact with the second region. In cross-sectional observation of the first semiconductor layer with a transmission electron microscope, bright spots arranged in a layered manner in a direction perpendicular to the surface of the substrate are preferably observed in each of the first, second, and third regions.

In the above semiconductor device, the second region preferably contains zinc. The second region preferably includes a crystal. A c-axis of the crystal is preferably substantially parallel to a normal direction of a side surface of the first semiconductor layer.

In the above semiconductor device, the first region preferably has a higher indium content than the second region. The third region preferably has a higher indium content than the second region.

Another embodiment of the present invention is a semiconductor device including a first memory cell and a second memory cell. The first and second memory cells each include a first transistor, a second transistor, and a capacitor. In each of the first and second memory cells, a gate electrode of the second transistor includes a region in contact with one of a source electrode and a drain electrode of the first transistor and a region overlapping with a lower electrode of the capacitor with a gate insulating layer of the second transistor therebetween. A semiconductor layer of the second transistor of the first memory cell is provided to be extend in a channel length direction of the second transistor of the first memory cell, and includes a region overlapping with the gate electrode of the second transistor of the second memory cell with the gate insulating layer of the second transistor of the second memory cell therebetween. In a cross-sectional view of the second transistor in a channel width direction, a height of the semiconductor layer is larger than a width of the semiconductor layer.

In the above semiconductor device, in each of the first and second memory cells, the one of the source electrode and the drain electrode of the first transistor preferably includes a first conductive layer and a second conductive layer over the first conductive layer, and the other of the source electrode and the drain electrode of the first transistor preferably includes a third conductive layer and a fourth conductive layer over the third conductive layer. A shortest distance between the first and third conductive layers is preferably smaller than a shortest distance between the second and fourth conductive layers.

In the above semiconductor device, in each of the first and second memory cells, the gate electrode of the second transistor preferably includes a region in contact with a top surface of the first conductive layer of the first transistor.

In the above semiconductor device, the semiconductor layer preferably contains indium. The semiconductor layer is preferably perpendicular or substantially perpendicular to a surface of the substrate. In cross-sectional observation of the semiconductor layer with a transmission electron microscope, bright spots arranged in a layered manner in a direction perpendicular to the surface of the substrate are preferably observed.

In the above semiconductor device, the semiconductor layer preferably contains indium. The semiconductor layer is preferably perpendicular or substantially perpendicular to a surface of the substrate. The semiconductor layer preferably includes a first region, a second region in contact with the first region, and a third region in contact with the second region. In cross-sectional observation of the semiconductor layer with a transmission electron microscope, bright spots arranged in a layered manner in a direction perpendicular to the surface of the substrate are preferably observed in each of the first, second, and third regions.

In the above semiconductor device, the second region preferably contains zinc. The second region preferably includes a crystal. A c-axis of the crystal is preferably substantially parallel to a normal direction of a side surface of the semiconductor layer.

In the above semiconductor device, the first region preferably has a higher indium content than the second region. The third region preferably has a higher indium content than the second region.

One embodiment of the present invention can provide a semiconductor device that operates at high speed. One embodiment of the present invention can provide a semiconductor device that can be miniaturized or highly integrated. One embodiment of the present invention can provide a semiconductor device with favorable electrical characteristics. One embodiment of the present invention can provide a semiconductor device with a small variation in electrical characteristics of transistors. One embodiment of the present invention can provide a highly reliable semiconductor device. One embodiment of the present invention can provide a semiconductor device with a high on-state current. One embodiment of the present invention can provide a semiconductor device with low power consumption. One embodiment of the present invention can provide a novel semiconductor device. One embodiment of the present invention can provide a method for manufacturing a semiconductor device with high productivity. One embodiment of the present invention can provide a method for manufacturing a novel semiconductor device.

One embodiment of the present invention can provide a memory device that can be miniaturized or highly integrated. One embodiment of the present invention can provide a memory device having large memory capacity. One embodiment of the present invention can provide a memory device that operates at high speed. One embodiment of the present invention can provide a memory device with low power consumption. One embodiment of the present invention can provide a novel memory device.

Note that the description of these effects does not preclude the existence of other effects. One embodiment of the present invention does not need to have all of these effects. Other effects can be derived from the description of the specification, the drawings, and the claims.

### BRIEF DESCRIPTION OF THE DRAWINGS

In the accompanying drawings:

FIG. 1A and FIGS. 1B to 1D are, respectively, a plan view and cross-sectional views illustrating a structure example of a semiconductor device;

FIG. 2A and FIGS. 2B to 2D are, respectively, a plan view and cross-sectional views illustrating a structure example of a semiconductor device;

FIGS. 3A to 3C are cross-sectional views illustrating a structure example of a semiconductor device;

FIGS. 4A to 4C are plan views illustrating structure examples of a semiconductor device;

FIGS. 5A to 5C are cross-sectional views illustrating structure examples of a semiconductor device;

FIG. 6 is a cross-sectional view illustrating a structure example of a semiconductor device;

FIGS. 7A to 7D are cross-sectional views illustrating an example of a method for manufacturing an oxide semiconductor layer;

FIGS. 8A to 8D are cross-sectional views illustrating examples of an oxide semiconductor layer;

FIGS. 9A to 9C are cross-sectional views illustrating examples of a semiconductor layer;

FIGS. 10A to 10C are cross-sectional views illustrating structure examples of a semiconductor device;

FIG. 11A and FIG. 11B are, respectively, a plan view and a cross-sectional view illustrating a structure example of a semiconductor device;

FIG. 12A and FIGS. 12B to 12D are, respectively, a plan view and cross-sectional views illustrating a structure example of a semiconductor device;

FIG. 13A and FIGS. 13B and 13C are, respectively, a plan view and cross-sectional views illustrating a structure example of a semiconductor device;

FIGS. 14A and 14B are perspective views illustrating a structure example of a semiconductor device;

FIG. 15A and FIGS. 15B to 15D are, respectively, a plan view and cross-sectional views illustrating a structure example of a semiconductor device;

FIG. 16A and FIG. 16B are, respectively, a plan view and a cross-sectional view illustrating a structure example of a semiconductor device;

FIG. 17A and FIG. 17B are, respectively, a plan view and a cross-sectional view illustrating a structure example of a semiconductor device;

FIG. 18A and FIG. 18B are, respectively, a plan view and a cross-sectional view illustrating an example of a method for manufacturing a semiconductor device;

FIG. 19A and FIG. 19B are, respectively, a plan view and a cross-sectional view illustrating an example of a method for manufacturing a semiconductor device;

FIG. 20A and FIG. 20B are, respectively, a plan view and a cross-sectional view illustrating an example of a method for manufacturing a semiconductor device;

FIG. 21A and FIG. 21B are, respectively, a plan view and a cross-sectional view illustrating an example of a method for manufacturing a semiconductor device;

FIG. 22A and FIG. 22B are, respectively, a plan view and a cross-sectional view illustrating an example of a method for manufacturing a semiconductor device;

FIG. 23A and FIG. 23B are, respectively, a plan view and a cross-sectional view illustrating an example of a method for manufacturing a semiconductor device;

FIG. 24A and FIG. 24B are, respectively, a plan view and a cross-sectional view illustrating an example of a method for manufacturing a semiconductor device;

FIG. 25A and FIG. 25B are, respectively, a plan view and a cross-sectional view illustrating an example of a method for manufacturing a semiconductor device;

FIG. 26A and FIG. 26B are, respectively, a plan view and a cross-sectional view illustrating an example of a method for manufacturing a semiconductor device;

FIG. 27A and FIG. 27B are, respectively, a plan view and a cross-sectional view illustrating an example of a method for manufacturing a semiconductor device;

FIG. 28A and FIG. 28B are, respectively, a plan view and a cross-sectional view illustrating an example of a method for manufacturing a semiconductor device;

FIG. 29A and FIG. 29B are, respectively, a plan view and a cross-sectional view illustrating an example of a method for manufacturing a semiconductor device;

FIG. 30A and FIG. 30B are, respectively, a plan view and a cross-sectional view illustrating an example of a method for manufacturing a semiconductor device;

FIG. 31A and FIG. 31B are, respectively, a plan view and a cross-sectional view illustrating an example of a method for manufacturing a semiconductor device;

FIG. 32A and FIG. 32B are, respectively, a plan view and a cross-sectional view illustrating an example of a method for manufacturing a semiconductor device;

FIG. 33A and FIG. 33B are, respectively, a plan view and a cross-sectional view illustrating an example of a method for manufacturing a semiconductor device;

FIG. 34A and FIG. 34B are, respectively, a plan view and a cross-sectional view illustrating an example of a method for manufacturing a semiconductor device;

FIG. 35 is a plan view illustrating a structure example of a semiconductor device;

FIG. 36A and FIG. 36B are, respectively, a plan view and a cross-sectional view illustrating a structure example of a semiconductor device;

FIG. 37 is a plan view illustrating a structure example of a semiconductor device;

FIG. 38 is a block diagram illustrating a structure example of a semiconductor device;

FIGS. 39A to 39H illustrate circuit configuration examples of memory cells;

FIG. 40 illustrates a circuit configuration example of a semiconductor device;

FIG. 41 is a timing chart showing an example of a method for driving a semiconductor device;

FIGS. 42A and 42B are perspective views illustrating structure examples of a semiconductor device;

FIG. 43 is a block diagram illustrating a CPU;

FIG. 44 is a block diagram illustrating a CPU;

FIGS. 45A and 45B are perspective views of a semiconductor device;

FIGS. 46A and 46B are perspective views of a semiconductor device;

FIGS. 47A and 47B illustrate hierarchies of memory devices used for a semiconductor device;

FIGS. 48A and 48B illustrate examples of electronic devices, and FIGS. 48C to 48E illustrate an example of a large computer;

FIG. 49 illustrates an example of space equipment; and

FIG. 50 illustrates an example of a storage system that can be used in a data center.

### DETAILED DESCRIPTION OF THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

In a plan view, a perspective view, or the like, especially, some components might not be illustrated for easy understanding of the invention. In addition, some hidden lines might not be shown.

Note that in this specification and the like, ordinal numbers such as “first” and “second” are used for convenience and do not limit the number of components or the order of components (e.g., the order of steps or the stacking order of layers). Furthermore, an ordinal number used for a component in a certain part in this specification is not the same as an ordinal number used for the component in another part in this specification or claims in some cases.

Note that the terms “film” and “layer” can be used interchangeably depending on the case or the circumstances. For example, the term “conductive layer” can be replaced with the term “conductive film”. As another example, the term “insulating film” can be replaced with the term “insulating layer”. The term “conductor” can be replaced with the term “conductive layer” or “conductive film” depending on the case or the circumstances. The term “insulator” can be replaced with the term “insulating layer” or “insulating film” depending on the case or the circumstances.

In this specification and the like, the term “parallel” indicates that the angle formed between two straight lines is greater than or equal to −10° and less than or equal to 10°. Thus, the case where the angle is greater than or equal to −5° and less than or equal to 5° is also included. The term “substantially parallel” indicates that the angle formed between two straight lines is greater than or equal to −20° and less than or equal to 20°. The term “perpendicular” indicates that the angle formed between two straight lines is greater than or equal to 80° and less than or equal to 100°. Thus, the case where the angle is greater than or equal to 85° and less than or equal to 95° is also included. In addition, the term “substantially perpendicular” indicates that the angle formed between two straight lines is greater than or equal to 70° and less than or equal to 110°.

In the drawings used in embodiments in this specification, a sidewall of an insulating layer in an opening is perpendicular or substantially perpendicular to a substrate surface or a formation surface, but the sidewall may have a tapered shape.

In this specification and the like, examples of an opening include a groove and a slit.

In this specification and the like, a tapered shape refers to a shape such that at least part of the side surface of a component is inclined with respect to a substrate surface or a formation surface of the component. For example, a tapered shape preferably includes a region where the angle between the inclined side surface and the substrate surface or the formation surface of the component (hereinafter, such an angle is referred to as a taper angle in some cases) is less than 90°. Note that the side surface of the component and the substrate surface are not necessarily completely flat and may be substantially flat with a slight curvature or with slight unevenness.

In this specification and the like, the expression “level or substantially level with” indicates a structure having the same level from a reference surface (e.g., a flat surface such as a substrate surface) in a cross-sectional view. For example, in a manufacturing process of a memory device, planarization treatment (typically, chemical mechanical polishing (CMP) treatment) is performed, whereby the surface(s) of a single layer or a plurality of layers may be exposed. In this case, the surfaces on which the CMP treatment is performed are at the same level from a reference surface. Note that a plurality of layers may be on different levels depending on a treatment apparatus, a treatment method, or a material of the treated surfaces, used for the CMP treatment. This case is also included in the scope of “level or substantially level with” in this specification and the like. For example, the expression “level or substantially level with” also includes the case where two layers (here, a first layer and a second layer) have different two levels with respect to a reference surface and the difference in the top-surface level between the first and second layers is less than or equal to 20 nm.

In this specification and the like, the expression “a side end portion is aligned or substantially aligned with another side end portion” indicates that at least outlines of stacked layers partly overlap with each other in a plan view. For example, the case of patterning or partly patterning an upper layer and a lower layer with the use of the same mask pattern is included. The expression “a side end portion is aligned or substantially aligned with another side end portion” also includes the case where the outlines do not completely overlap with each other; for instance, the outline of the upper layer may be positioned inward or outward from the outline of the lower layer.

### Embodiment 1

In this embodiment, a semiconductor device including an oxide semiconductor layer and a method for manufacturing the semiconductor device will be described. A semiconductor device of one embodiment of the present invention can be used for, for example, a memory cell of an after-mentioned memory device.

### <Structure Example 1 of Semiconductor Device>

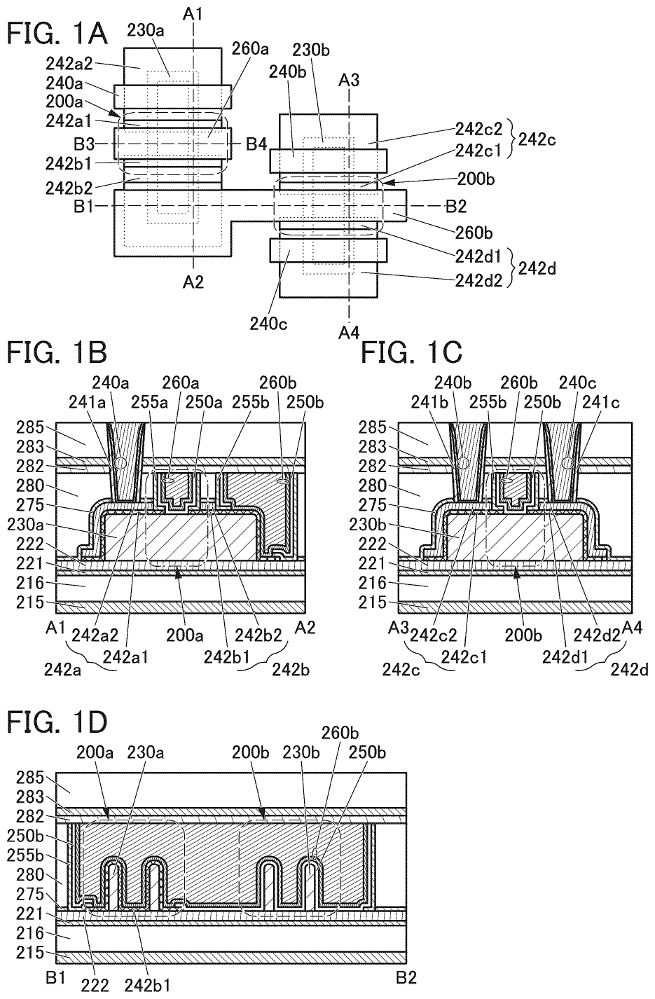

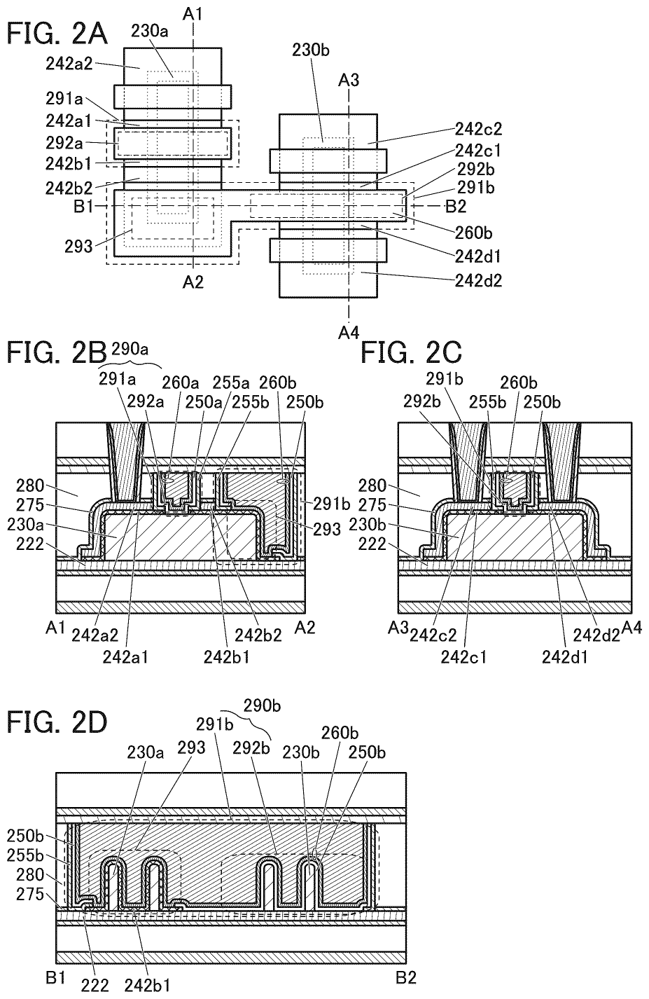

A structure example of a semiconductor device is described with reference to FIGS. 1A to 1D and FIGS. 2A to 2D. FIGS. 1A to 1D and FIGS. 2A to 2D are plan views and cross-sectional views of a semiconductor device including a transistor.

FIG. 1A is the plan view of the semiconductor device. FIGS. 1B to 1D are the cross-sectional views of the semiconductor device. Here, FIG. 1B is the cross-sectional view taken along the dashed-dotted line A1-A2 in FIG. 1A. FIG. 1C is the cross-sectional view taken along the dashed-dotted line A3-A4 in FIG. 1A. FIG. 1D is the cross-sectional view taken along the dashed-dotted line B1-B2 in FIG. 1A. Here, the dashed-dotted line B1-B2 is orthogonal to the dashed-dotted lines A1-A2 and A3-A4, which are parallel to each other. Note that for simplification, in the plan view in FIG. 1A, some components are not illustrated, and some components are illustrated in a see-through manner.

FIGS. 2A to 2D correspond to FIGS. 1A to 1D, respectively. FIGS. 2A to 2D illustrate the positions of openings provided in insulating layers.

The semiconductor device illustrated in FIGS. 1A to 1D includes an insulating layer 215 over a substrate (not illustrated); an insulating layer 216 over the insulating layer 215; an insulating layer 221 over the insulating layer 216; an insulating layer 222 over the insulating layer 221; a transistor 200a and a transistor 200b over the insulating layer 222; an insulating layer 275; and an insulating layer 280. An insulating layer 282 is provided over the transistors 200a and 200b, an insulating layer 283 is provided over the insulating layer 282, and an insulating layer 285 is provided over the insulating layer 283.

The transistor 200a includes a semiconductor layer 230a over the insulating layer 222, a conductive layer 242a and a conductive layer 242b over the semiconductor layer 230a and the insulating layer 222, an insulating layer 255a over the conductive layer 242a and the conductive layer 242b, an insulating layer 250a over the semiconductor layer 230a and the insulating layer 255a, and a conductive layer 260a over the insulating layer 250a. The conductive layer 242a includes a conductive layer 242a1 and a conductive layer 242a2 over the conductive layer 242a1. The conductive layer 242b includes a conductive layer 242b1 and a conductive layer 242b2 over the conductive layer 242b1. In FIG. 1B, the conductive layer 260a has a two-layer structure.

The transistor 200b includes a semiconductor layer 230b over the insulating layer 222, a conductive layer 242c and a conductive layer 242d over the semiconductor layer 230b and the insulating layer 222, an insulating layer 255b over the conductive layers 242c and 242d, an insulating layer 250b over the semiconductor layer 230b and the insulating layer 255b, and a conductive layer 260b over the insulating layer 250b. The conductive layer 242c includes a conductive layer 242c1 and a conductive layer 242c2 over the conductive layer 242cl. The conductive layer 242d includes a conductive layer 242d1 and a conductive layer 242d2 over the conductive layer 242d1. In FIGS. 1C and 1D, the conductive layer 260b has a two-layer structure.

The insulating layer 275 is provided over the conductive layers 242a to 242d, and the insulating layer 280 is provided over the insulating layer 275. An opening 291a and an opening 291b are formed in the insulating layers 280 and 275 (see FIGS. 2A to 2D). The opening 291a is provided to overlap with a region between the conductive layers 242a2 and 242b2. The opening 291a is provided to overlap with at least part of the semiconductor layer 230a. The opening 291b is provided to overlap with a region between the conductive layers 242c2 and 242d2. The opening 291b is provided to overlap with at least part of the conductive layer 242b1 and at least part of the semiconductor layer 230b.

The insulating layer 255a is positioned in the opening 291a. In the opening 291a, the insulating layer 255a includes a region in contact with the side surface of the insulating layer 280, a region in contact with the side surface of the insulating layer 275, a region in contact with the side surface of the conductive layer 242a2, a region in contact with the side surface of the conductive layer 242b2, a region in contact with the top surface of the conductive layer 242a1, and a region in contact with the top surface of the conductive layer 242b1.

An opening 292a reaching the semiconductor layer 230a is formed in the insulating layer 255a (see FIGS. 2A and 2B). The opening 292a is provided to overlap with a region between the conductive layers 242a1 and 242b1. Note that the opening 292a is provided in a region overlapping with the opening 291a. Thus, the openings 291a and 292a can be collectively regarded as one opening. In view of the above, the one opening (the opening including the openings 291a and 292a) is referred to as an opening 290a in some cases.

The insulating layer 250a and the conductive layer 260a are positioned in the opening 290a. The insulating layer 250a is in contact with the semiconductor layer 230a in the opening 290a. The insulating layer 250a includes a region in contact with the side surface of the insulating layer 255a, a region in contact with the side surface of the conductive layer 242a1, and a region in contact with the side surface of the conductive layer 242b1 in the opening 290a.

The insulating layer 255b is provided in the opening 291b. In the opening 291b, the insulating layer 255b includes a region in contact with the side surface of the insulating layer 280, a region in contact with the side surface of the insulating layer 275, a region in contact with the side surface of the conductive layer 242c2, a region in contact with the side surface of the conductive layer 242d2, a region in contact with the top surface of the conductive layer 242c1, and a region in contact with the top surface of the conductive layer 242d1. In the opening 291b, the insulating layer 255b includes a region in contact with the side surface of the insulating layer 280, a region in contact with the side surface of the insulating layer 275, a region in contact with the side surface of the conductive layer 242b2, and a region in contact with part of the top surface of the conductive layer 242b1.

An opening 292b reaching the semiconductor layer 230b is formed in the insulating layer 255b (see FIGS. 2A, 2C, and 2D). The opening 292b is provided to overlap with a region between the conductive layers 242c1 and 242d1.

The insulating layer 250b is positioned in the openings 291b and 292b. The insulating layer 250b is in contact with the semiconductor layer 230b in the openings 291b and 292b. The insulating layer 250b includes a region in contact with the side surface of the insulating layer 255b, a region in contact with the side surface of the conductive layer 242c1, and a region in contact with the side surface of the conductive layer 242d1 in the openings 291b and 292b.

An opening 293 reaching the conductive layer 242b1 is formed in the insulating layers 255b and 250b (see FIGS. 2A, 2B, and 2D). Note that the openings 292b and 293 are provided in regions overlapping with the opening 291b. Thus, the openings 291b, 292b, and 293 can be collectively regarded as one opening. In view of the above, the one opening (the opening including the openings 291b, 292b, and 293) is referred to as an opening 290b in some cases.

The conductive layer 260b is positioned in the opening 290b. The conductive layer 260b includes a region in contact with the side surface of the insulating layer 250b and a region in contact with the top surface of the conductive layer 242b1 in the opening 290b.

The semiconductor layer 230a includes a region functioning as a channel formation region of the transistor 200a. The conductive layer 260a includes a region functioning as a first gate electrode (an upper gate electrode) of the transistor 200a. The insulating layer 250a includes a region functioning as a first gate insulating layer of the transistor 200a. The conductive layer 242a includes a region functioning as one of a source electrode and a drain electrode of the transistor 200a. The conductive layer 242b includes a region functioning as the other of the source electrode and the drain electrode of the transistor 200a. FIG. 1B can also be referred to as a cross-sectional view of the transistor 200a in the channel length direction.

The semiconductor layer 230b includes a region functioning as a channel formation region of the transistor 200b. The conductive layer 260b includes a region functioning as a first gate electrode (an upper gate electrode) of the transistor 200b. The insulating layer 250b includes a region functioning as a first gate insulating layer of the transistor 200b. The conductive layer 242c includes a region functioning as one of a source electrode and a drain electrode of the transistor 200b. The conductive layer 242d includes a region functioning as the other of the source electrode and the drain electrode of the transistor 200b. FIG. 1C can also be referred to as a cross-sectional view of the transistor 200b in the channel length direction. FIG. 1D is also a cross-sectional view of the transistor 200b in the channel width direction.

The conductive layer 260b is in contact with the conductive layer 242b1. That is, the other of the source electrode and the drain electrode of the transistor 200a is electrically connected to the gate electrode of the transistor 200b. Such a structure does not require an electrode for connecting the other of the source electrode and the drain electrode of the transistor 200a and the gate electrode of the transistor 200b; thus, the semiconductor device can be formed without reducing transistor density. Accordingly, the semiconductor device can have a high degree of integration and large memory capacity. Furthermore, the number of steps in the manufacturing process of the semiconductor device can be reduced.

With the above structure, the other of a source and a drain of the transistor 200a and the gate of the transistor 200b can be electrically connected to each other, whereby a memory cell formed of two transistors (also referred to as a 2TOC memory cell) can be formed.

The insulating layer 282 is provided over the insulating layer 280, the insulating layer 255a, the insulating layer 250a, the conductive layer 260a, the insulating layer 255b, the insulating layer 250b, and the conductive layer 260b.

An insulating layer 241a is provided in contact with an inner wall of an opening formed in the insulating layers 285, 283, 282, 280, and 275, and a conductive layer 240a is provided in contact with the side surface of the insulating layer 241a. The bottom surface of the conductive layer 240a is in contact with the top surface of the conductive layer 242a2. An insulating layer 241b is provided in contact with an inner wall of an opening formed in the insulating layers 285, 283, 282, 280, and 275, and a conductive layer 240b is provided in contact with the side surface of the insulating layer 241b. The bottom surface of the conductive layer 240b is in contact with the top surface of the conductive layer 242c2. An insulating layer 241c is provided in contact with an inner wall of an opening formed in the insulating layers 285, 283, 282, 280, and 275, and a conductive layer 240c is provided in contact with the side surface of the insulating layer 241c. The bottom surface of the conductive layer 240c is in contact with the top surface of the conductive layer 242d2.

The conductive layer 240a functions as a plug connected to the conductive layer 242a. The conductive layer 240b functions as a plug connected to the conductive layer 242c. The conductive layer 240c functions as a plug connected to the conductive layer 242d.

[Transistor 200a]

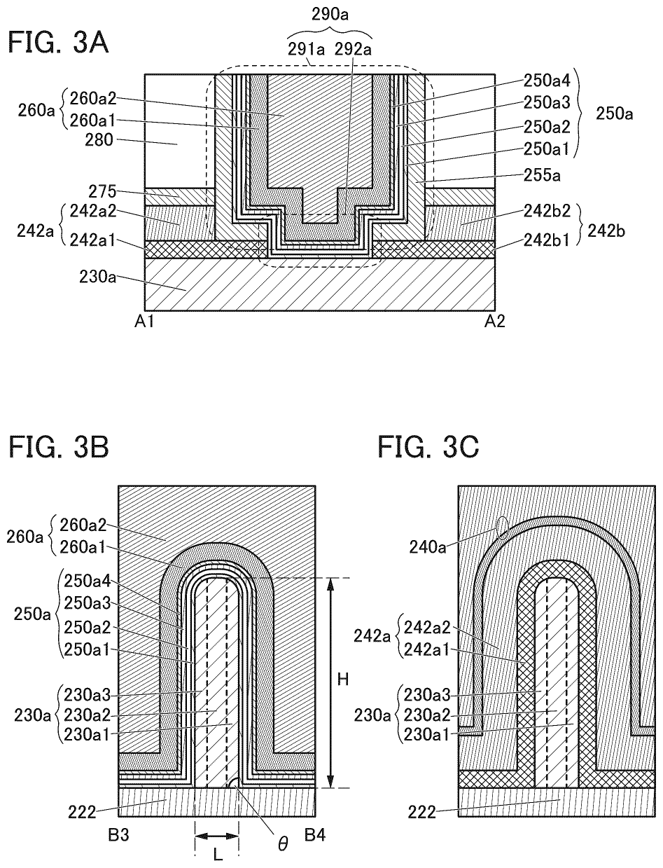

A structure example of the transistor 200a is described here. FIG. 3A is an enlarged view of the vicinity of the conductive layer 260a in FIG. 1B. FIG. 3B is a cross-sectional view of the transistor 200a in the channel width direction, and is also an enlarged view of the vicinity of the semiconductor layer 230a. Note that since the transistor 200a has a structure similar to that of the transistor 200b, FIG. 1D can be referred to for a cross-sectional view of the transistor 200a in the channel width direction.

The semiconductor layer 230a is formed on and in contact with the insulating layer 222. As illustrated in FIG. 3B, the semiconductor layer 230a has a shape with a high aspect ratio in the cross-sectional view in the channel width direction. Thus, it can be said that the semiconductor layer 230a has a fin shape.

Here, the aspect ratio of the semiconductor layer 230a in the cross-sectional view in the channel width direction refers to the ratio of a length L of the semiconductor layer 230a in the B3-B4 direction (also referred to as a width L of the semiconductor layer 230a) to a length H of the semiconductor layer 230a in a direction perpendicular to the formation surface of the semiconductor layer 230a (e.g., the insulating layer 222). The aspect ratio of the semiconductor layer 230a is preferably as high as possible unless the semiconductor layer 230a falls in the manufacturing process of the transistor 200a. In the semiconductor layer 230a, the height H is larger than at least the width L. In the semiconductor layer 230a, the height H is greater than 1 time and less than or equal to 400 times, preferably greater than or equal to 2 times and less than or equal to 100 times, further preferably greater than or equal to 5 times and less than or equal to 40 times, still further preferably greater than or equal to 10 times and less than or equal to 20 times the width L. For another example, the height H can be greater than or equal to 2 times and less than or equal to 10 times the width L. The width L can be, for example, greater than or equal to 5 nm and less than or equal to 100 nm, preferably greater than or equal to 5 nm and less than or equal to 50 nm, further preferably greater than or equal to 10 nm and less than or equal to 30 nm. The height H can be, for example, greater than or equal to 50 nm and less than or equal to 2000 nm, preferably greater than or equal to 100 nm and less than or equal to 1000 nm. For another example, the height H may be greater than or equal to 50 nm and less than or equal to 100 nm. When the aspect ratio of the semiconductor layer 230a is within the above range, the insulating layer 255a, the insulating layer 250a, the conductive layer 260a, the conductive layer 242a, the conductive layer 242b, the conductive layer 240a, and the like can be provided to cover the semiconductor layer 230a with good coverage.

As illustrated in FIG. 3B, an angle θ formed between the side surface of the semiconductor layer 230a and the top surface of the insulating layer 222 is preferably perpendicular or substantially perpendicular in the cross-sectional view in the channel width direction. For example, the angle θ is preferably greater than or equal to 80° and less than or equal to 100°, further preferably greater than or equal to 85° and less than or equal to 95°.

The insulating layer 250a, the conductive layer 260a, the conductive layer 242a, and the conductive layer 242b are provided to cover the above semiconductor layer 230a having a high aspect ratio. As illustrated in FIG. 3B, the insulating layer 250a and the conductive layer 260a are provided in the transistor 200a so as to be partly folded in half while sandwiching the semiconductor layer 230a. Thus, the upper portion, side surface on the B3 side, and side surface on the B4 side of the semiconductor layer 230a face the conductive layer 260a with the insulating layer 250a therebetween in the cross-sectional view in the channel width direction. That is, the upper portion, side surface on the B3 side, and side surface on the B4 side of the semiconductor layer 230a each function as a channel formation region. Therefore, the channel width of the transistor 200a is larger by the height H of each of the side surfaces on the B3 side and the B4 side of the semiconductor layer 230a than that in the case of forming a flat-plate semiconductor layer 230a.

The transistor 200a having the large channel width can have favorable on-state current, mutual conductance, frequency characteristics, and the like. Accordingly, a semiconductor device that operates at high speed can be provided. Moreover, a memory device including the semiconductor device can operate at high speed. The above structure including the semiconductor layer 230a enables a large channel width without increasing the area occupied by the transistor 200a. Accordingly, miniaturization or high integration of the semiconductor device can be achieved. Furthermore, a memory device including the semiconductor device can have large memory capacity. The facing area between the conductive layer 260a and the side surface of the semiconductor layer 230a is large in the above structure, so that the transistor 200a can be made normally off by controlling the threshold voltage thereof.

As illustrated in FIG. 3B and the like, the upper portion of the semiconductor layer 230a may have a curved shape. Such a curved shape can prevent formation of defects such as a void in the insulating layer 250a, the conductive layer 242a, and the conductive layer 242b in the vicinity of the upper portion of the semiconductor layer 230a. Although the semiconductor layer 230a illustrated in FIG. 3B has a bilaterally symmetrical structure in which the upper portions on both the B3 side and the B4 side have a curved shape, the present invention is not limited thereto. For example, the semiconductor layer 230a may have a bilaterally asymmetrical structure in which the upper portion on either the B3 side or the B4 side has a curved shape.

The semiconductor layer 230a has a shape with a high aspect ratio, and thus is preferably formed to have a sidewall shape on the side surface of a pillar (an insulating layer 223a described later). Therefore, the semiconductor layer 230a is preferably formed by an atomic layer deposition (ALD) method, which enables favorable coverage. In the case where the semiconductor layer 230a is formed to have a stacked-layer structure, at least one layer, preferably a layer in contact with the pillar is preferably formed by an ALD method.

The semiconductor layer 230a is formed to have a sidewall shape in contact with the pillar, so that the top surface of the semiconductor layer 230a has an enclosing shape where both edges are aligned with each other (also referred to as a frame-like shape, a ring-like shape, a donut-like shape, or a closed curve-like shape) as illustrated in FIG. 1A. The semiconductor layer 230a can also be regarded as having an opening in its center portion. Although the top surface shape of the semiconductor layer 230a is linearly symmetric with respect to the dashed-dotted line B3-B4 in FIG. 1A, the present invention is not limited thereto. For example, the top surface shape of the semiconductor layer 230a may be asymmetric.

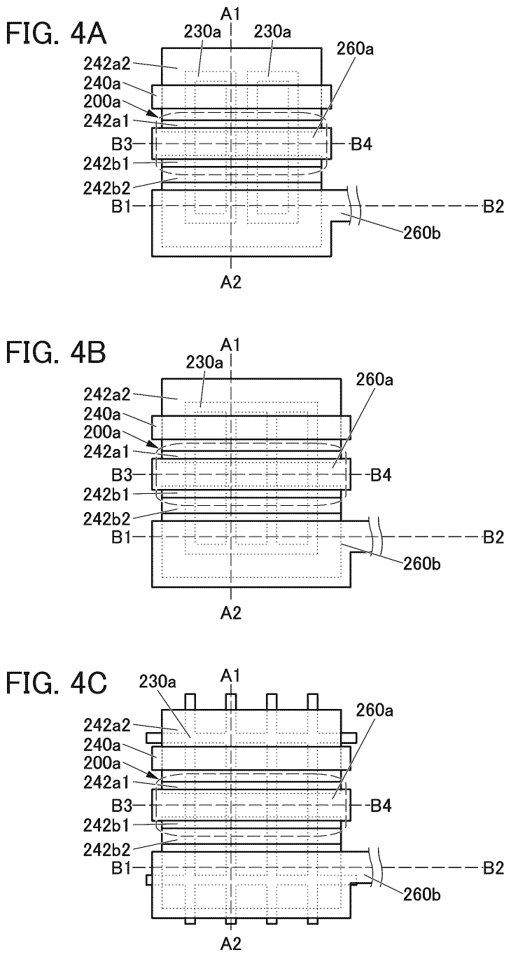

Note that although the structure in which the transistor 200a includes one enclosing-shaped semiconductor layer 230a is described above, the present invention is not limited thereto. For example, the transistor 200a can include two or more enclosing-shaped semiconductor layers 230a. For example, as illustrated in FIG. 4A, two pillars can be arranged in the B3-B4 direction and the enclosing-shaped semiconductor layer 230a can be formed in contact with the side surface of each pillar. Note that FIG. 4A does not illustrate the transistor 200b.

As illustrated in FIG. 1A and FIG. 4A, the semiconductor layer 230a preferably overlaps with the conductive layer 260a in two or more portions in the plan view. That is, the transistor 200a preferably includes two or more regions where the semiconductor layer 230a and the conductive layer 260a overlap with each other. In such a structure, a plurality of fin-shaped semiconductor layers 230a are formed in the cross-sectional view in the channel width direction. The plurality of fin-shaped semiconductor layers 230a each function as a channel formation region. That is, the transistor 200a functions as a multi-channel transistor. Thus, the channel width of the transistor 200a can be further increased.

In the case where the semiconductor layer 230a is formed to have a sidewall shape in contact with the side surface of each of a plurality of pillars, a plurality of semiconductor layers 230a illustrated in FIG. 4A can be formed concurrently. The distance between the plurality of semiconductor layers 230a formed in such a manner can be set in accordance with the size and shape of the pillar. Thus, the distance between the semiconductor layers 230a can be reduced and the area occupied by the transistor 200a can be reduced, leading to high integration of the semiconductor device.

Alternatively, enclosing-shaped semiconductor layers 230a may be connected to form the semiconductor layer 230a having a plurality of openings. For example, as illustrated in FIG. 4B, the semiconductor layer 230a can be formed to have three openings arranged in the B3-B4 direction in the plan view. In this case, three pillars may be formed adjacent to each other at small intervals, and the semiconductor layer 230a may be formed to have a sidewall shape in contact with each of the three pillars. Here, part of the semiconductor layer 230a is provided between the pillars. For another example, as illustrated in FIG. 4C, the semiconductor layer 230a can be formed to have a lattice shape in the plan view. In this case, a lattice-shaped trench may be formed in a pillar, and the semiconductor layer 230a may be formed to fill the trench. Note that the number of semiconductor layers 230a is not limited to one, and can be two or more. As described above, the semiconductor layer 230a preferably includes a plurality of portions extending in the channel width direction (B3-B4 direction) and a plurality of portions extending in the channel length direction (A1-A2 direction). Accordingly, the semiconductor layer 230a with a high aspect ratio can be inhibited from falling in the manufacturing process of the transistor.

The conductive layer 242a and the conductive layer 242b are positioned apart from each other and in contact with the semiconductor layer 230a. As illustrated in FIG. 3C and the like, the conductive layers 242a and 242b are provided to cover the semiconductor layer 230a having a high aspect ratio. As illustrated in FIG. 1D and the like, the conductive layers 242a and 242b are each preferably in contact with two or more fin-shaped semiconductor layers 230 in the cross-sectional view.

As illustrated in FIG. 3C, the conductive layer 242a in the vicinity of the source or the drain of the transistor 200a is provided so as to be folded in half while sandwiching the semiconductor layer 230a. Thus, the upper portion, side surface on the B3 side, and side surface on the B4 side of the semiconductor layer 230a are in contact with the conductive layer 242a in the cross-sectional view in the channel width direction. Therefore, the contact area between the conductive layer 242a and the semiconductor layer 230a is larger by the height H of each of the side surfaces on the B3 side and the B4 side of the semiconductor layer 230a than that in the case of forming a flat-plate semiconductor layer 230a. Furthermore, when the plurality of fin-shaped semiconductor layers 230a and the conductive layer 242a are in contact with each other as illustrated in FIG. 1A, the contact area can be further increased. The same applies to the conductive layer 242b although FIG. 3C and FIG. 1A illustrate the vicinity of the conductive layer 242a. That is, like the contact area between the conductive layer 242a and the semiconductor layer 230a described above, the contact area between the conductive layer 242b and the semiconductor layer 230a is increased.

With the above large contact area between the conductive layer 242a and the semiconductor layer 230a and the large contact area between the conductive layer 242b and the semiconductor layer 230a, the transistor 200a can have favorable on-state current, frequency characteristics, and the like without a large occupied area. Accordingly, a semiconductor device that operates at high speed can be provided. In addition, a memory device including the semiconductor device can operate at high speed. Moreover, miniaturization or high integration of the semiconductor device can be achieved. Furthermore, a memory device including the semiconductor device can have large memory capacity.

As illustrated in FIG. 1B, the conductive layer 242a has a stacked-layer structure of the conductive layer 242a1 and the conductive layer 242a2 over the conductive layer 242a1, and the conductive layer 242b has a stacked-layer structure of the conductive layer 242b1 and the conductive layer 242b2 over the conductive layer 242b1. At this time, for a layer (the conductive layers 242a1 and 242b1) in contact with the semiconductor layer 230a, a conductive material that is less likely to be oxidized or a conductive material having a function of inhibiting diffusion of oxygen is preferably used. Thus, a decrease in conductivity of the conductive layers 242a and 242b can be inhibited. Oxygen is inhibited from being extracted from the semiconductor layer 230a, that is, an excessive amount of oxygen vacancies can be inhibited from being formed. For a layer (the conductive layers 242a1 and 242b1) in contact with the semiconductor layer 230a, a material that is likely to absorb (extract) hydrogen is preferably used, in which case the hydrogen concentration in the semiconductor layer 230a can be reduced.

For each of the conductive layers 242a1 and 242b1, metal nitride is preferably used; for example, a nitride containing tantalum, a nitride containing titanium, a nitride containing molybdenum, a nitride containing tungsten, a nitride containing tantalum and aluminum, or a nitride containing titanium and aluminum is preferably used. In one embodiment of the present invention, a nitride containing tantalum is particularly preferable. As another example, ruthenium oxide, ruthenium nitride, an oxide containing strontium and ruthenium, or an oxide containing lanthanum and nickel may be used. These materials are preferable because they are conductive materials that are not easily oxidized or materials that maintain the conductivity even when absorbing oxygen.

The conductive layers 242a2 and 242b2 preferably have higher conductivity than the conductive layers 242a1 and 242b1. For example, the conductive layers 242a2 and 242b2 preferably have a larger thickness than the conductive layers 242a1 and 242b1. For each of the conductive layers 242a2 and 242b2, a conductor that can be used for the conductive layer 260b described later may be used. The above-described structure can reduce the resistance of the conductive layers 242a2 and 242b2. As a result, the on-state current of the transistor 200a can be increased and the operation speed of the semiconductor device of this embodiment can be improved.

For example, tantalum nitride or titanium nitride can be used for each of the conductive layers 242a1 and 242b1, and tungsten can be used for each of the conductive layers 242a2 and 242b2.

In the cross-sectional view of the transistor 200a in the channel length direction in FIG. 1B, the conductive layer 242a1 and the conductive layer 242b1 protrude toward the opening 292a more than the conductive layer 242a2 and the conductive layer 242b2, respectively. Protruding portions of the conductive layers 242a1 and 242b1 are covered with the insulating layer 250a. Here, the shortest distance between the conductive layers 242a1 and 242b1 is smaller than the shortest distance between the conductive layers 242a2 and 242b2. With such a structure, the distance between the source and the drain can be shortened, and accordingly the channel length can also be shortened.

The shortest distance between the conductive layers 242a1 and 242b1 is preferably short because the channel length of the transistor 200a reflects the distance. For example, the shortest distance is preferably greater than or equal to 1 nm and less than or equal to 60 nm, further preferably greater than or equal to 1 nm and less than or equal to 50 nm, still further preferably greater than or equal to 2 nm and less than or equal to 50 nm, still further preferably greater than or equal to 2 nm and less than or equal to 30 nm, yet still further preferably greater than or equal to 2 nm and less than or equal to 20 nm. With such a structure, the distance between the source and the drain can be shortened, and accordingly the channel length can be shortened. Thus, the frequency characteristics of the transistor 200a can be improved. By miniaturization of the semiconductor device in this manner, the semiconductor device can have improved operation speed.

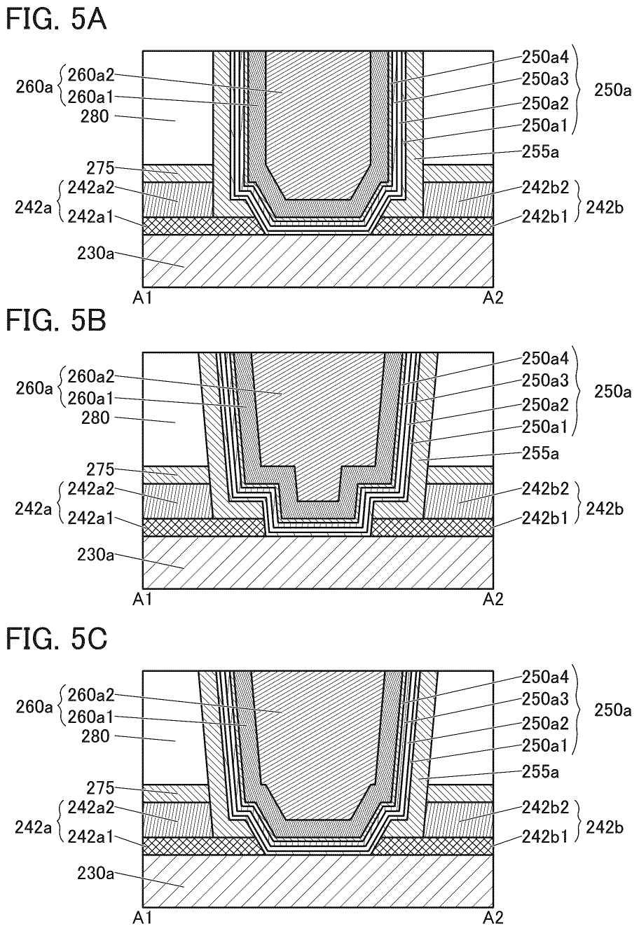

In the transistor 200a illustrated in FIG. 3A, the side surface of the conductive layer 242a1 and the side surface of the conductive layer 242b1, which face to each other, are substantially perpendicular to the top surface of the semiconductor layer 230a; however, the present invention is not limited to this structure. For example, as illustrated in FIG. 5A, the facing side surfaces of the conductive layers 242a1 and 242b1 may have tapered shapes. With such shapes, the distance between the conductive layer 260a and the semiconductor layer 230a is shortened in the vicinity of side end portions of the conductive layers 242a1 and 242b1, which reduces the influence of an Loff region.

As illustrated in FIG. 5B, the facing side surfaces of the conductive layers 242a1 and 242b1 and the facing side surfaces of the conductive layers 242a2 and 242b2 may have tapered shapes.

As illustrated in FIG. 5C, the taper angles of the conductive layer 242a1 and the conductive layer 242b1 may be made more acute than those of the conductive layer 242a2 and the conductive layer 242b2, respectively. With such shapes, the distance between the conductive layer 260a and the semiconductor layer 230a is further shortened in the vicinity of the side end portions of the conductive layers 242a1 and 242b1, which reduces the influence of the Loff region.

The conductive layer 260a is positioned in the opening 290a as illustrated in FIG. 1B. The conductive layer 260a is provided in the opening 290a to cover the top surface of the insulating layer 222, the side surface of the semiconductor layer 230a, and the top surface of the semiconductor layer 230a with the insulating layers 255a and 250a therebetween. The conductive layer 260a is positioned so that its top surface is level or substantially level with the uppermost portions of the insulating layers 255a and 250a and the top surface of the insulating layer 280.

Note that a sidewall of the opening 290a may be perpendicular or substantially perpendicular to the top surface of the insulating layer 222 or may have a tapered shape. The sidewall with a tapered shape can improve the coverage with the insulating layer 250a and the like formed in the opening 290a, so that the number of defects such as voids can be reduced.

The conductive layer 260a can be provided to extend in the channel width direction. With such a structure, the conductive layer 260a functions as a wiring when a plurality of transistors 200a are provided.

The conductive layer 260a is provided so as to be partly folded in half while sandwiching the fin-shaped semiconductor layer 230a. Thus, as illustrated in FIG. 3B, the upper portion, side surface on the B3 side, and side surface on the B4 side of the semiconductor layer 230a face the conductive layer 260a with the insulating layer 250a therebetween in the cross-sectional view in the channel width direction. That is, the upper portion, side surface on the B3 side, and side surface on the B4 side of the semiconductor layer 230a each function as a channel formation region. Therefore, the channel width of the transistor 200a is larger by the height H of each of the side surfaces on the B3 side and the B4 side of the semiconductor layer 230a than that in the case of forming a flat-plate semiconductor layer 230a.

In FIG. 1B and the like, the conductive layer 260a has a two-layer structure. Here, the conductive layer 260a preferably includes a conductive layer 260a1 and a conductive layer 260a2 over the conductive layer 260a1. For example, the conductive layer 260a1 is preferably positioned so as to cover the bottom and side surfaces of the conductive layer 260a2. In that case, a conductive material that is less likely to be oxidized or a conductive material having a function of inhibiting diffusion of oxygen is preferably used for the conductive layer 260a1.

The conductive layer 260a1 preferably includes a conductive material having a function of inhibiting diffusion of impurities such as a hydrogen atom, a hydrogen molecule, a water molecule, a nitrogen atom, a nitrogen molecule, a nitrogen oxide molecule, and a copper atom. Alternatively, the conductive layer 260a1 preferably includes a conductive material having a function of inhibiting diffusion of oxygen (e.g., at least one of an oxygen atom and an oxygen molecule).

When the conductive layer 260a1 has a function of inhibiting diffusion of oxygen, the conductivity of the conductive layer 260a2 can be inhibited from being lowered because of oxidization of the conductive layer 260a2 due to oxygen in the insulating layer 280 and the like. As the conductive material having a function of inhibiting diffusion of oxygen, for example, titanium, titanium nitride, tantalum, tantalum nitride, ruthenium, or ruthenium oxide is preferably used.

The conductive layer 260a2 is preferably formed using a conductor having high conductivity. For example, a conductive material containing tungsten, copper, or aluminum as its main component can be used for the conductive layer 260a2. The conductive layer 260a2 may have a stacked-layer structure, for example, a stacked-layer structure of titanium or titanium nitride and the above conductive material.

In the transistor 200a, the conductive layer 260a is formed in a self-aligned manner so as to fill the opening 290a. With such a structure, the side surface of the insulating layer 280 in the opening 290a is aligned or substantially aligned with the side surface of the conductive layer 242a2 and the side surface of the conductive layer 242b2. Thus, the conductive layer 260a can be positioned to overlap with a region between the conductive layers 242a and 242b without alignment.

If impurities and oxygen vacancies exist in a channel formation region in an oxide semiconductor, a transistor including the oxide semiconductor might have variable electrical characteristics and poor reliability. In some cases, a defect that is an oxygen vacancy into which hydrogen enters (hereinafter also referred to as VoH in some cases) generates an electron serving as a carrier. Therefore, when the channel formation region in the oxide semiconductor includes oxygen vacancies, the transistor tends to have normally-on characteristics (the channel is generated even when no voltage is applied to the gate electrode and current flows through the transistor). Thus, impurities, oxygen vacancies, and VoH are preferably reduced as much as possible in the channel formation region in the oxide semiconductor. In other words, the channel formation region in the oxide semiconductor is preferably an i-type (intrinsic) or substantially i-type region with a low carrier concentration.

By contrast, when an insulator containing oxygen that is released by heating (hereinafter sometimes referred to as excess oxygen) is provided in the vicinity of the oxide semiconductor and heat treatment is performed, oxygen can be supplied from the insulator to the oxide semiconductor so as to reduce oxygen vacancies and VoH. Note that too much oxygen supplied to the source region or the drain region might cause a decrease in the on-state current or the field-effect mobility of the transistor. Furthermore, a variation in the amount of oxygen supplied to a source region or a drain region in the substrate plane leads to variations in characteristics of the semiconductor device including the transistor. When oxygen supplied from the insulator to the oxide semiconductor is diffused into a conductor such as the gate electrode, the source electrode, or the drain electrode, the conductor might be oxidized and the conductivity might be impaired, for example, so that electrical characteristics and reliability of the transistor might be adversely affected.

Therefore, the oxide semiconductor preferably includes an i-type or substantially i-type channel formation region with a low carrier concentration and n-type source and drain regions with a high carrier concentration. That is, the amounts of oxygen vacancies and VoH in the channel formation region in the oxide semiconductor are preferably reduced. Excessive supply of oxygen to the source and drain regions and excessive reduction in the amount of VoH in the source and drain regions are preferably inhibited. Furthermore, a reduction in the conductivity of the conductive layers 260a, 242a, and 242b and the like is preferably inhibited. For example, oxidation of the conductive layers 260a, 242a, and 242b and the like is preferably inhibited. Note that hydrogen in an oxide semiconductor can form VoH; thus, the hydrogen concentration needs to be reduced in order to reduce the amount of VoH.

The semiconductor device of this embodiment has a structure in which the hydrogen concentration in the channel formation region is reduced, oxidation of the conductive layers 242a, 242b, and 260a is inhibited, and the hydrogen concentration in the source and drain regions is inhibited from being reduced.

The insulating layer 255a is formed in contact with the side surfaces of the conductive layers 242a2 and 242b2. The insulating layer 255a preferably has a barrier property against oxygen. The insulating layer 255a is preferably less permeable to oxygen than at least the insulating layer 280 is. When the insulating layer 255a has a barrier property against oxygen, oxidation of the side surfaces of the conductive layers 242a2 and 242b2 and formation of oxide films on the side surfaces can be inhibited. Accordingly, a reduction in on-state current or field-effect mobility of the transistor 200a can be inhibited.

The insulating layer 255a is formed in contact with the side surfaces of the conductive layers 242a2 and 242b2, and thus has a function of protecting the conductive layers 242a2 and 242b2. Thus, heat treatment may be performed in an oxygen-containing atmosphere after the formation of the conductive layers 242a2 and 242b2 and before the formation of an insulating film (an insulating film 250P described later) to be the insulating layers 250a and 250b. In this case, the conductive layers 242a2 and 242b2 can be prevented from being excessively oxidized.

Silicon nitride has a barrier property against oxygen and thus can be suitably used for the insulating layer 255a.

In this embodiment, the insulating layer 255a is provided between the insulating layer 250a and each of the conductive layers 242a2 and 242b2. Accordingly, the distance between the conductive layer 260a and each of the conductive layers 242a2 and 242b2 can be increased by the thickness of the insulating layer 255a. Thus, the thickness of the insulating layer 250a can be reduced while reducing the parasitic capacitance generated between the conductive layer 260a and each of the conductive layers 242a2 and 242b2, whereby the influence of the Loff region can be reduced.

The thickness of the insulating layer 255a is preferably larger than the thickness of any one of insulating layers 250a1 to 250a4 described later. The thickness of the insulating layer 255a is preferably greater than or equal to 1 nm and less than or equal to 20 nm, further preferably greater than or equal to 1 nm and less than or equal to 15 nm, still further preferably greater than or equal to 3 nm and less than or equal to 10 nm, and for example, can be approximately 5 nm.

When the insulating layer 255a has the above thickness, the distance between the conductive layer 260a and the conductive layer 242a2 or the conductive layer 242b2 can be increased, so that the parasitic capacitance can be reduced. Note that the insulating layer 255a at least partly has a region with the above thickness. The insulating layer 255a is provided in the opening 290a, and thus is preferably formed by a method capable of forming a film with good coverage, such as an ALD method.

The insulating layer 250a in contact with the channel formation region in the semiconductor layer 230a preferably has a function of capturing or fixing hydrogen. Thus, the hydrogen concentration in the channel formation region in the semiconductor layer 230a can be reduced. Accordingly, VoH in the channel formation region can be reduced, so that the channel formation region can be an i-type or substantially i-type region.

Here, as illustrated in FIG. 3A, the insulating layer 250a preferably has a stacked-layer structure including the insulating layer 250a1 in contact with the semiconductor layer 230a, the insulating layer 250a2 over the insulating layer 250a1, the insulating layer 250a3 over the insulating layer 250a2, and the insulating layer 250a4 over the insulating layer 250a3. In that case, the insulating layers 250a1 and 250a3 preferably have a function of capturing or fixing hydrogen.

An example of the insulator having a function of capturing or fixing hydrogen is a metal oxide having an amorphous structure. For each of the insulating layers 250a1 and 250a3, for example, a metal oxide, such as magnesium oxide or an oxide containing aluminum and/or hafnium, is preferably used. In such a metal oxide having an amorphous structure, an oxygen atom has a dangling bond with which hydrogen is trapped or fixed in some cases. That is, the metal oxide having an amorphous structure has high capability of capturing or fixing hydrogen.

Moreover, a high dielectric constant (high-k) material is preferably used for each of the insulating layers 250a1 and 250a3. An example of the high-k material is an oxide containing aluminum and/or hafnium. With use of the high-k material for each of the insulating layers 250a1 and 250a3, a gate potential applied during operation of the transistor can be reduced while the physical thickness of the gate insulator is maintained. In addition, the equivalent oxide thickness (EOT) of the insulator functioning as the gate insulator can be reduced.

For each of the insulating layers 250a1 and 250a3, an oxide containing aluminum and/or hafnium is preferably used, and an oxide containing aluminum and/or hafnium and having an amorphous structure is more preferably used.

In this embodiment, an aluminum oxide film is used as the insulating layer 250a1. The aluminum oxide film preferably has an amorphous structure. Here, when the insulating layer 250a1 is provided in contact with the semiconductor layer 230a, hydrogen contained in the semiconductor layer 230a or the like can be captured and fixed more effectively.

In this embodiment, hafnium oxide is used for the insulating layer 250a3. Here, when the insulating layer 250a3 is provided between the insulating layer 250a2 and the insulating layer 250a4, hydrogen contained in the insulating layer 250a2 or the like can be captured and fixed more effectively.

Next, an insulator having thermal stability, such as silicon oxide or silicon oxynitride, is preferably used for the insulating layer 250a2. Note that in this specification and the like, an oxynitride refers to a material that contains more oxygen than nitrogen, and a nitride oxide refers to a material that contains more nitrogen than oxygen. For example, silicon oxynitride refers to a material that contains more oxygen than nitrogen, and silicon nitride oxide refers to a material that contains more nitrogen than oxygen.

A silicon oxide film used as the insulating layer 250a2 is preferably formed by a plasma-enhanced ALD (PEALD) method.

In order to inhibit oxidation of the conductive layers 242a, 242b, and 260a, an insulating layer formed using a barrier insulator against oxygen is preferably provided in the vicinity of each of the conductive layers 242a, 242b, and 260a. In the semiconductor device described in this embodiment, the insulating layer corresponds to, for example, the insulating layers 250a1, 250a4, 250a3, and 275.

Note that in this specification and the like, a barrier insulator refers to an insulator having a barrier property. In this specification and the like, “having a barrier property” means having a property of hindering transmission of a target substance (also referred to as having a low permeability). For example, an insulator having a barrier property hardly allows a target substance to be diffused into the insulator. As another example, an insulator having a barrier property has a function of capturing or fixing (also referred to as gettering) a target substance in the insulator.

Examples of a barrier insulator against oxygen include an oxide containing aluminum and/or hafnium, magnesium oxide, gallium oxide, silicon nitride, and silicon nitride oxide. Examples of the oxide containing aluminum and/or hafnium include aluminum oxide, hafnium oxide, an oxide containing aluminum and hafnium (hafnium aluminate), and an oxide containing hafnium and silicon (hafnium silicate). For example, each of the insulating layers 250a1, 250a3, 250a4, and 275 preferably has a single-layer structure or a stacked-layer structure of the barrier insulator against oxygen.

The insulating layer 250a1 preferably has a barrier property against oxygen. The insulating layer 250a1 is preferably less permeable to oxygen than at least the insulating layer 280 is. The insulating layer 250a1 includes a region in contact with the side surface of the conductive layer 242a and a region in contact with the side surface of the conductive layer 242b. When the insulating layer 250a1 has a barrier property against oxygen, oxidation of the side surfaces of the conductive layers 242a and 242b and formation of oxide films on the side surfaces can be inhibited. Accordingly, a reduction in on-state current or field-effect mobility of the transistor 200a can be inhibited.

The insulating layer 250a1 is provided in contact with the top and side surfaces of the semiconductor layer 230a and the top surface of the insulating layer 222. When the insulating layer 250a1 has a barrier property against oxygen, release of oxygen from the channel formation region in the semiconductor layer 230a caused by heat treatment or the like can be inhibited. This can inhibit formation of oxygen vacancies in the semiconductor layer 230a.

By providing the insulating layer 250a1, excessive supply of oxygen from the insulating layer 280 to the semiconductor layer 230a can be inhibited and an appropriate amount of oxygen can be supplied to the semiconductor layer 230a. Thus, excessive oxidation of the source and drain regions can be inhibited, and a reduction in on-state current or field-effect mobility of the transistor 200a can be inhibited.

An oxide containing aluminum and/or hafnium has a barrier property against oxygen and thus can be suitably used for the insulating layer 250a1.

The insulating layer 250a4 also preferably has a barrier property against oxygen. The insulating layer 250a4 is provided between the conductive layer 260a and the channel formation region in the semiconductor layer 230a and between the insulating layer 280 and the conductive layer 260a. Such a structure can inhibit oxygen contained in the channel formation region in the semiconductor layer 230a from being diffused into the conductive layer 260a and thus can inhibit formation of oxygen vacancies in the channel formation region in the semiconductor layer 230a. Oxygen contained in the semiconductor layer 230a and oxygen contained in the insulating layer 280 can be inhibited from being diffused into the conductive layer 260a and oxidizing the conductive layer 260a. The insulating layer 250a4 is preferably less permeable to oxygen than at least the insulating layer 280 is. For example, a silicon nitride film is preferably used as the insulating layer 250a4. In that case, the insulating layer 250a4 contains at least nitrogen and silicon.

The insulating layer 250a4 preferably has a barrier property against hydrogen. This can prevent diffusion of impurities contained in the conductive layer 260a, such as hydrogen, into the semiconductor layer 230a.

The insulating layer 275 also preferably has a barrier property against oxygen. The insulating layer 275 is provided between the insulating layer 280 and each of the conductive layers 242a and 242b. The insulating layer 275 is provided in contact with the side surface of the conductive layer 242a and the top surface of the insulating layer 222. This structure can inhibit diffusion of oxygen contained in the insulating layer 280 into the conductive layers 242a and 242b. Accordingly, oxidation of the conductive layers 242a and 242b by oxygen contained in the insulating layer 280 can be inhibited, so that an increase in resistivity due to the oxidation can be inhibited. The insulating layer 275 is preferably less permeable to oxygen than at least the insulating layer 280 is. For example, silicon nitride is preferably used for the insulating layer 275. In that case, the insulating layer 275 contains at least nitrogen and silicon.

In order to inhibit a reduction in hydrogen concentration in the source and drain regions in the semiconductor layer 230a, an insulating layer formed using a barrier insulator against hydrogen is preferably provided in the vicinity of each of the source and drain regions. In the semiconductor device described in this embodiment, the insulating layer corresponds to, for example, the insulating layer 275.

Examples of the barrier insulator against hydrogen include an oxide such as aluminum oxide, hafnium oxide, and tantalum oxide and a nitride such as silicon nitride. For example, the insulating layer 275 preferably has a single-layer structure or a stacked-layer structure of the above barrier insulator against hydrogen.

Providing the insulating layer 275 described above can reduce the amount of hydrogen diffused from the source and drain regions into the outside, so that a reduction in the hydrogen concentration in the source and drain regions can be inhibited. Thus, the source and drain regions can be n-type regions.

With the above structure, the i-type or substantially i-type channel formation region and the n-type source and drain regions can be formed; therefore, a semiconductor device with favorable electrical characteristics can be provided. The semiconductor device with the above structure can have favorable electrical characteristics even when being miniaturized or highly integrated. Furthermore, miniaturization of the transistor 200a can improve the frequency characteristics. Specifically, the cutoff frequency can be improved.

The insulating layers 250a1 to 250a4 function as a part of the gate insulator. The insulating layers 250a1 to 250a4 are provided together with the insulating layer 255a and the conductive layer 260a in the opening 290a. The thickness of each of the insulating layers 250a1 to 250a4 is preferably small for miniaturization of the transistor 200a. The thickness of each of the insulating layers 250a1 to 250a4 is preferably greater than or equal to 0.1 nm and less than or equal to 10 nm, further preferably greater than or equal to 0.1 nm and less than or equal to 5.0 nm, further preferably greater than or equal to 0.5 nm and less than or equal to 5.0 nm, further preferably greater than or equal to 1.0 nm and less than 5.0 nm, further preferably greater than or equal to 1.0 nm and less than or equal to 3.0 nm. Note that each of the insulating layers 250a1 to 250a4 at least partly includes a region with the above thickness.

The thickness of the silicon oxide film used as the insulating layer 250a2 is preferably greater than or equal to 0.7 nm and less than or equal to 3 nm.

In order that the insulating layers 250a1 to 250a4 have small thicknesses as described above, an ALD method is preferably employed. Furthermore, in the case where the insulating layers 250a1 to 250a4 are provided in the opening 290a, an ALD method is preferably employed. Examples of the ALD method include a thermal ALD method, in which a precursor and a reactant react with each other only by a thermal energy, and a PEALD method, in which a reactant excited by plasma is used. A PEALD method utilizing plasma is preferable, in which case film formation at lower temperatures is possible in some cases.

An ALD method enables a single atomic layer to be formed at a time, and has various advantages enabling formation of an extremely thin film, film formation on a component with a high aspect ratio, formation of a film with few defects such as pinholes, formation of a film with excellent coverage, low-temperature film formation, and the like. Thus, the insulating layer 250a can be formed with the above-described small thickness and high coverage on the side surface of the insulating layer 255a, the side surfaces of the conductive layers 242a1 and 242b1, and the like in the opening 290.

Note that a precursor used in the ALD method sometimes contains carbon or the like. Thus, a film formed by the ALD method may contain impurities such as carbon in a larger amount than a film formed by another film formation method. Note that impurities can be quantified by secondary ion mass spectrometry (SIMS), X-ray photoelectron spectroscopy (XPS), or auger electron spectroscopy (AES).

Although the case where the insulating layer 250a has a four-layer structure of the insulating layers 250a1 to 250a4 is described above, the present invention is not limited to this structure. The insulating layer 250a can have a structure including at least one of the insulating layers 250a1 to 250a4. When the insulating layer 250a is formed using one, two, or three layers selected from the insulating layers 250a1 to 250a4, the manufacturing process of the semiconductor device can be simplified and the productivity can be improved.

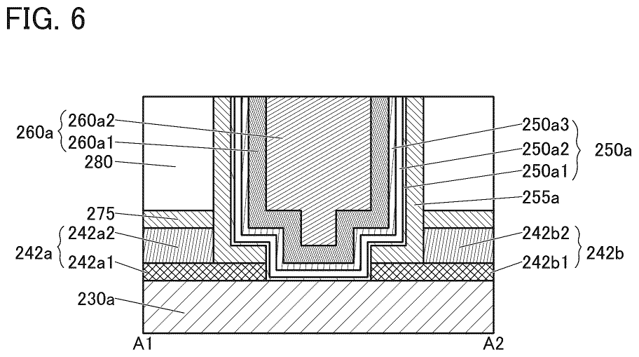

For example, as illustrated in FIG. 6, the insulating layer 250a may have a three-layer structure. In this case, the insulating layer 250 preferably has a stacked-layer structure of the insulating layer 250a1, the insulating layer 250a2 over the insulating layer 250a1, and the insulating layer 250a3 over the insulating layer 250a2. That is, the stacked-layer structure is obtained by removing the insulating layer 250a4 from the structure illustrated in FIG. 3A.

In forming the insulating layer 250a, an ALD process is preferably performed twice or more. For example, the insulating layer 250a preferably has a stacked-layer structure of a plurality of insulating films, and two or more of the plurality of insulating films are preferably formed through an ALD process. By forming at least two or more insulating films through an ALD process, coverage and thickness uniformity of the insulating layer 250a can be improved. Moreover, by successively forming two or more different kinds of films, e.g., two or more insulating films, through an ALD process, the productivity can be increased.

In addition to the above structure, hydrogen is preferably inhibited from entering the transistor 200a and the like. For example, an insulating layer including an insulator having a function of inhibiting diffusion of hydrogen is preferably provided over and/or below the transistor 200a and the like. In the semiconductor device described in this embodiment, the insulating layer corresponds to, for example, the insulating layers 283, 282, 222, and 221. The insulating layer 215 provided below the transistor 200a may have a structure similar to the structure(s) of the insulating layer 282 and/or the insulating layer 283. In that case, the insulating layer 215 may have a stacked-layer structure of the insulating layer 282 and the insulating layer 283; the insulating layer 283 may be positioned over the insulating layer 282 or the insulating layer 282 may be positioned over the insulating layer 283.

One or a plurality of the insulating layers 283, 282, 222, and 221 preferably has a function of inhibiting diffusion of impurities such as water and hydrogen from the substrate side or from above the transistor 200a and the like into the transistor 200a and the like. Therefore, one or a plurality of the insulating layers 283, 282, 222, and 221 preferably includes an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom, that is, an insulating material through which the above impurities are less likely to pass. Alternatively, one or a plurality of the insulating layers 283, 282, 222, and 221 preferably includes an insulating material having a function of inhibiting diffusion of oxygen (e.g., at least one of an oxygen atom and an oxygen molecule), that is, an insulating material which is less likely to transmit the oxygen.

Each of the insulating layers 283, 282, 222, and 221 preferably includes an insulator having a function of inhibiting diffusion of oxygen and impurities such as water and hydrogen. Examples of the insulator include aluminum oxide, magnesium oxide, hafnium oxide, zirconium oxide, an oxide containing aluminum and hafnium (hafnium aluminate), an oxide containing hafnium and zirconium (a hafnium zirconium oxide), gallium oxide, silicon nitride, and silicon nitride oxide. For example, silicon nitride, which has a higher hydrogen barrier property, is preferably used for each of the insulating layers 283 and 221. For example, aluminum oxide, which has high capability of capturing or fixing hydrogen, is preferably used for the insulating layer 282. For example, hafnium oxide, which has high capability of capturing or fixing hydrogen and is a high dielectric constant (high-k) material, is preferably used for the insulating layer 222.

Note that at least one of the insulating layers 221 and 222 can have a stacked-layer structure of the above-described material and silicon oxide or silicon oxynitride. For example, the insulating layer 221 can have a stacked-layer structure of silicon nitride and silicon oxide. For another example, the insulating layer 222 can have a stacked-layer structure of hafnium oxide and silicon oxide.

Such a structure can inhibit impurities such as water and hydrogen from being diffused from an interlayer insulating film or the like positioned above the insulating layer 283 into the transistor 200a or the like. Furthermore, impurities such as water and hydrogen can be inhibited from being diffused from an interlayer insulating film or the like positioned below the insulating layer 221 into the transistor 200a or the like. Moreover, hydrogen contained in the insulating layers 280 and 250 and the like can be captured and fixed in the insulating layer 282 or the insulating layer 222. Providing the insulating layers 282 and 283 can inhibit oxygen contained in the insulating layer 280 and the like from being diffused above the transistor 200a or the like. Providing the insulating layers 222 and 221 can inhibit oxygen contained in the semiconductor layer 230a and the like from being diffused below the transistor 200a or the like. With such a structure where the transistor 200a is surrounded by the insulating layers having a function of inhibiting diffusion of oxygen and impurities such as water and hydrogen, excess oxygen and excess hydrogen can be inhibited from being diffused into the oxide semiconductor. Therefore, the electrical characteristics and reliability of the semiconductor device can be improved.

Moreover, silicon nitride, which has a higher hydrogen barrier property, is preferably used for each of the insulating layers 275 and 250a4, for example. Aluminum oxide, which has high capability of capturing or fixing hydrogen, is preferably used for the insulating layer 250a1, for example. Hafnium oxide, which has high capability of capturing or fixing hydrogen, is preferably used for the insulating layer 250a3, for example.

The insulating layers 216 and 280 preferably have a lower dielectric constant than the insulating layer 222. In the case where a material with a low dielectric constant is used for the interlayer films, the parasitic capacitance between wirings can be reduced.

For example, each of the insulating layers 216 and 280 preferably includes one or more of silicon oxide, silicon oxynitride, silicon oxide to which fluorine is added, silicon oxide to which carbon is added, silicon oxide to which carbon and nitrogen are added, and porous silicon oxide.

Silicon oxide and silicon oxynitride are particularly preferable because of their thermal stability. In particular, materials such as silicon oxide, silicon oxynitride, and porous silicon oxide are preferably used, in which case a region containing oxygen released by heating can be easily formed.

Each of the top surfaces of the insulating layer 216 and the insulating layer 280 may be planarized.

The concentration of impurities such as water and hydrogen in the insulating layer 280 is preferably reduced. For example, the insulating layer 280 preferably includes an oxide containing silicon such as silicon oxide or silicon oxynitride.

### [Oxide Semiconductor Layer]

Here, an oxide semiconductor layer that can be used as the semiconductor layer 230 will be described. The oxide semiconductor layer includes a metal oxide.

When a metal oxide is used for a semiconductor layer of a transistor, a lattice defect in the metal oxide might cause generation, capture, or the like of a carrier. Thus, when a metal oxide with a large number of lattice defects is used for a semiconductor layer of a transistor, the electrical characteristics of the transistor might be unstable. Therefore, a metal oxide used for a semiconductor layer of a transistor preferably has a small number of lattice defects. Examples of the lattice defect include point defects such as an atomic vacancy and an exotic atom, linear defects such as dislocation, plane defects such as a crystal grain boundary, and volume defects such as a cavity.

By using a metal oxide having crystallinity for an oxide semiconductor layer, the density of defect states in the oxide semiconductor layer can be reduced. Examples of the structure of a metal oxide having crystallinity include a c-axis aligned crystalline (CAAC) structure, a polycrystalline structure, and a nanocrystalline (nc) structure.

The metal oxide included in the oxide semiconductor layer of one embodiment of the present invention includes a plurality of microcrystals. A clear crystal grain boundary (grain boundary) is not observed between the plurality of microcrystals. The metal oxide included in the oxide semiconductor layer of one embodiment of the present invention preferably includes a plurality of microcrystals that are aligned, and preferably has a crystal structure in which the plurality of microcrystals are connected without a clear crystal grain boundary when observed from the alignment direction.

The oxide semiconductor layer of one embodiment of the present invention includes a metal oxide having a crystal structure different from a single crystal structure and a polycrystalline structure. It is particularly preferable that the oxide semiconductor layer of one embodiment of the present invention include a metal oxide having the CAAC structure.

The CAAC structure is a crystal structure in which a plurality of microcrystals (typically, a plurality of microcrystals each having a hexagonal crystal structure) have c-axis alignment and are connected on the a-b plane without a clear crystal grain boundary. According to a high-resolution cross-sectional transmission electron microscope (TEM) image of the oxide semiconductor layer having the CAAC structure, metal atoms are arranged in a layered manner in crystal parts. Thus, the oxide semiconductor layer having the CAAC structure can also be regarded as having a structure including the layered crystal parts. The metal atoms arranged in a layered manner can be observed as arranged bright spots in a cross section of the oxide semiconductor layer observed with the TEM image. The bright spots are arranged in a direction parallel to the formation surface of the oxide semiconductor layer, for example.

Note that the CAAC structure may refer to the following structure: in each of a plurality of microcrystals, metal atoms are arranged in a layered manner in a direction parallel or substantially parallel to a formation surface, and layers of the arranged metal atoms are stacked in a direction perpendicular or substantially perpendicular to the formation surface. As long as the microcrystal has such a structure, the crystal structure of the microcrystal is not limited to a hexagonal crystal structure. For example, some of the plurality of microcrystals may have a crystal structure other than a hexagonal crystal structure (e.g., a cubic crystal structure).

The CAAC structure is formed such that the c-axis is perpendicular or substantially perpendicular to a formation surface, for example. In the CAAC structure, metal atoms are arranged in a layered manner in a direction parallel or substantially parallel to the formation surface. In a region having the CAAC structure, an angle formed by the c-axis and the formation surface is preferably within 90°±20° (greater than or equal to 70° and less than or equal to) 110°, further preferably within 90°±15° (greater than or equal to 75° and less than or equal to) 105°, still further preferably within 90°±10° (greater than or equal to 80° and less than or equal to) 100°, yet still further preferably within 90°±5° (greater than or equal to 85° and less than or equal to) 95°.

A polycrystalline structure includes a crystal grain boundary (grain boundary). When an oxide semiconductor layer having the polycrystalline structure is formed and then subjected to heat treatment, a minute gap (also referred to as a nano crack or a micro crack) or a minute space (also referred to as a nano space or a micro space) can be formed between crystal parts. When a minute gap or a minute space is formed in the oxide semiconductor layer, the electric resistance of the oxide semiconductor layer is increased. This is because the electric resistance of the minute gap or the minute space is extremely high, for example, infinite. In the case where an oxide semiconductor layer including a minute gap or a minute space is used for a channel formation region of a transistor, the contact resistance between the oxide semiconductor layer and one or both of a source electrode and a drain electrode becomes high. This adversely affects initial characteristics or reliability of the transistor. Meanwhile, in the CAAC structure, a crystal grain boundary is not clearly observed in the a-b plane, and thus a highly reliable semiconductor device can be achieved. Furthermore, since the CAAC structure has a small number of crystal grain boundaries, an energy barrier for carrier conduction in a channel of a transistor is low, and an on-state current is expected to be increased. Furthermore, an increase in electric resistance of a semiconductor layer of a transistor including the oxide semiconductor layer can be inhibited or initial characteristics (particularly on-state current) of the transistor can be improved; thus, a transistor suitable for high-speed driving can be expected.

For the channel formation region of a transistor, a metal oxide that increases the on-state current of the transistor is preferably used. To increase the on-state current of the transistor, the carrier mobility of the metal oxide used for the transistor is preferably increased. To increase the carrier mobility of the metal oxide, the transfer of carriers (electrons in the case of an n-channel transistor) needs to be facilitated or scattering factors that affect the carrier transfer need to be reduced. Note that the carriers flow from the source to the drain through the channel formation region. Hence, the on-state current of the transistor can be increased by providing a channel formation region through which carriers can easily flow in the channel length direction.

The crystallinity of the oxide semiconductor layer can be analyzed by X-ray diffraction (XRD), TEM, or electron diffraction (ED), for example. Alternatively, these methods may be combined as appropriate for the analysis.

When the oxide semiconductor layer having the CAAC structure is subjected to electron diffraction, spots indicating c-axis alignment (bright spots) are observed in the electron diffraction pattern. The c-axes of the CAAC structure are preferably aligned in a direction parallel to the normal vector of the formation surface of the oxide semiconductor layer or the normal vector of a surface of the oxide semiconductor layer.

Fast Fourier transform (FFT) on a TEM image yields an FFT pattern reflecting reciprocal lattice space information like an electron diffraction pattern.

When the cross-sectional TEM image of the oxide semiconductor layer having the CAAC structure is obtained and each region in the cross-sectional TEM image is subjected to FFT processing to form an FFT pattern, the crystal axis direction in each region can be calculated from the obtained FFT pattern. Specifically, the direction of a line segment connecting two spots that have high luminance and are at substantially the same distance from the center, among spots observed in the obtained FFT pattern, is referred to as a crystal axis direction. A region in which an angle formed by the crystal axis direction calculated from the FFT pattern and the formation surface is preferably greater than or equal to 70° and less than or equal to 110° (within 90°±20°), further preferably greater than or equal to 75° and less than or equal to 105° (within 90°±15°), still further preferably greater than or equal to 80° and less than or equal to 100° (within 90°±10°), yet still further preferably greater than or equal to 85° and less than or equal to 95° (within 90°±5°) can be regarded as having the CAAC structure.

When the oxide semiconductor layer having the CAAC structure is observed from the direction perpendicular to the formation surface using the TEM image, a triangular or hexagonal atomic arrangement and crystallinity are observed in the a-b plane. In a Voronoi diagram formed by analysis of the TEM image of the oxide semiconductor layer having the CAAC structure observed from the direction perpendicular to the formation surface, pentagonal, hexagonal, and heptagonal Voronoi regions are mainly observed, typically a hexagonal Voronoi region is observed. For example, the hexagonal Voronoi region accounts for higher than or equal to 30% and lower than 100% of the Voronoi regions observed in the Voronoi diagram.

A method for forming a Voronoi diagram is described. First, in TEM image analysis, FFT processing is performed, only information within a certain range is left by filtering, and then reverse fast Fourier transform is performed to obtain an FFT filtering image. Lattice points are extracted from the obtained FFT filtering image, and perpendicular bisectors of line segments each connecting adjacent lattice points are formed. A point at which three perpendicular bisectors intersect with each other is referred to as a Voronoi point, and a polygonal region surrounded by a line segment connecting the Voronoi points is referred to as a Voronoi region. In the above manner, a Voronoi diagram can be formed.

Note that as the TEM observation range for forming a Voronoi diagram, a rectangular region that is 50 nm wide and 50 nm long is preferably observed, for example. Note that the observation range is not limited to this.

In addition, when distribution of hexagonal lattice orientations is analyzed using lattice points extracted by analysis of a plan-view TEM image, at a boundary between two structures with different hexagonal lattice orientations, the difference in hexagonal lattice orientation is small, the boundary is blurred, and the two structures are connected to be tangled with each other. That is, no clear boundary portion is observed in the CAAC structure.

Note that as the hexagonal lattice orientation, the orientation of a hexagon formed by six lattice points closest to each other can be calculated.

Note that there is no particular limitation on the crystallinity of a semiconductor material contained in the oxide semiconductor layer. For example, the oxide semiconductor layer sometimes contains one or more of an amorphous semiconductor (a semiconductor having an amorphous structure), a single crystal semiconductor (a semiconductor having a single crystal structure), and a semiconductor having crystallinity other than single crystal (a microcrystalline semiconductor, a polycrystalline semiconductor, or a semiconductor partly including a crystal region). When the oxide semiconductor layer has crystallinity, degradation of the transistor characteristics can be inhibited in some cases.

The metal oxide of one embodiment of the present invention preferably contains at least indium (In) or zinc (Zn), particularly preferably contains indium as its main component. Here, the metal oxide contains indium as its main component, and can further contain an element M. The metal oxide preferably contains two or three selected from indium, the element M, and zinc, and particularly preferably contains indium and zinc as its main components. Here, the metal oxide contains indium and zinc as its main components, and can further contain the element M. The element M is a metal element or metalloid element that has a high bonding energy with oxygen, such as a metal element or metalloid element whose bonding energy with oxygen is higher than that of indium. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more of the above elements, further preferably one or more selected from gallium, tin, yttrium, and aluminum, still further preferably one or more selected from gallium and tin. When the element M contained in the metal oxide is gallium, the metal oxide of one embodiment of the present invention preferably contains one or more selected from indium, gallium, and zinc. In this specification and the like, a metal element and a metalloid element may be collectively referred to as a “metal element”, and a “metal element” in this specification and the like may refer to a metalloid element.

A main component in a metal oxide refers to, for example, a metal element having a proportion of 0.1 atomic % or higher or 1 atomic % or higher with respect to all metal elements contained in the metal oxide.

In the cross section of the oxide semiconductor layer observed using the TEM image, metal atoms arranged in a layered manner in a direction parallel or substantially parallel to the formation surface are observed. In a TEM image, the metal atoms arranged in a layered manner are observed as bright spots. For example, in a metal oxide containing indium, indium atoms arranged in a layered manner are observed. As another example, in a metal oxide containing indium and zinc, indium atoms and zinc atoms arranged in a layered manner are observed.

As the metal oxide of one embodiment of the present invention, for example, an indium zinc oxide (In—Zn oxide), an indium tin oxide (In—Sn oxide), an indium titanium oxide (In—Ti oxide), an indium gallium oxide (In—Ga oxide), an indium gallium aluminum oxide (In—Ga—Al oxide), an indium gallium tin oxide (also referred to as In—Ga—Sn oxide or IGTO), a gallium zinc oxide (also referred to as Ga—Zn oxide or GZO), an aluminum zinc oxide (also referred to as Al—Zn oxide or AZO), an indium aluminum zinc oxide (also referred to as In—Al—Zn oxide or IAZO), an indium tin zinc oxide (also referred to as In—Sn—Zn oxide or ITZO (registered trademark)), an indium titanium zinc oxide (In—Ti—Zn oxide), an indium gallium zinc oxide (also referred to as In—Ga—Zn oxide or IGZO), an indium gallium tin zinc oxide (also referred to as In—Ga—Sn—Zn oxide or IGZTO), or an indium gallium aluminum zinc oxide (also referred to as In—Ga—Al—Zn oxide, IGAZO, or IAGZO) can be used. Alternatively, an indium tin oxide containing silicon (also referred to as ITSO), a gallium tin oxide (Ga—Sn oxide), an aluminum tin oxide (Al—Sn oxide), or the like can be used. As the metal oxide of one embodiment of the present invention, an indium oxide can be used. Alternatively, as the metal oxide of one embodiment of the present invention, a gallium oxide, a zinc oxide, or the like can be used.

By increasing the proportion of the number of indium atoms in the total number of atoms of all the metal elements contained in the metal oxide, a high on-state current and high frequency characteristics of the transistor can be achieved.

By increasing the proportion of the number of zinc atoms in the total number of atoms of all the metal elements contained in the metal oxide, the metal oxide has high crystallinity, so that diffusion of impurities in the metal oxide can be inhibited. Consequently, changes in electrical characteristics of the transistor are reduced and the transistor can have high reliability.

By increasing the proportion of the number of element M atoms in the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, changes in the electrical characteristics of the transistor are reduced and the transistor can have high reliability.

Instead of indium, the metal oxide may contain one or more kinds of metal elements whose period number in the periodic table is large. Alternatively, in addition to indium, the metal oxide may contain one or more kinds of metal elements whose period number in the periodic table is large. The larger the overlap between orbits of metal elements is, the more likely it is that the metal oxide will have high carrier conductivity. Thus, when a metal element with a large period number in the periodic table is contained in the metal oxide, the field-effect mobility of the transistor can be increased in some cases. Examples of the metal element with a large period number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds selected from nonmetallic elements. A transistor including the metal oxide containing a nonmetallic element can have high field-effect mobility in some cases. Examples of the nonmetallic element include carbon, nitrogen, phosphorus, sulfur, fluorine, chlorine, bromine, and hydrogen.

### [Formation Method of Oxide Semiconductor Layer]

The oxide semiconductor layer of one embodiment of the present invention can be formed by forming metal oxides using two kinds of film formation methods.

In the formation of the oxide semiconductor layer of one embodiment of the present invention, a metal oxide having the CAAC structure is formed. Here, by using a sputtering method as a film formation method, a metal oxide with high crystallinity can be formed. Alternatively, a film formation method such as a pulsed laser deposition (PLD) method may be used.

In the case where a metal oxide is formed by the above-described film formation method (hereinafter referred to as first film formation method), a mixed layer is sometimes formed at the interface between the metal oxide and a formation surface over which the metal oxide is formed. There is a concern that the mixed layer may hinder crystallization of the metal oxide. A metal oxide is formed in advance as a first layer over the formation surface by a film formation method (hereinafter referred to as second film formation method) that causes less damage than a sputtering method, a PLD method, or the like described as the first film formation method, and then a metal oxide is formed as a second layer by the first film formation method, which can inhibit the formation of a mixed layer at the interface between the oxide semiconductor layer and the formation surface. Moreover, entry of impurities contained in the formation surface into the second layer can be inhibited. Accordingly, the crystallinity of the second layer can be further increased.

An ALD method and a chemical vapor deposition (CVD) method are suitable as the second film formation method because they enables damage to a formation surface to be reduced as compared with a sputtering method. Examples of the second film formation method include a molecular beam epitaxy (MBE) method and a wet process. Examples of the CVD method include a plasma enhanced CVD (PECVD) method using plasma, a thermal CVD (TCVD) method using heat, a photo CVD method using light, and a metal organic CVD (MOCVD) method. The MBE method is a film formation method in which a thin film having a crystal structure reflecting a crystal system of a substrate is grown, and is one of film formation methods that causes less damage to a formation surface. The wet method is one of film formation methods that cause less damage to a formation surface. An example of the wet method is a spray coating method.

Furthermore, a third layer can be formed over the second layer. The third layer can be formed by the second film formation method, for example.

After the oxide semiconductor layer is formed, heat treatment is preferably performed.

In the method for forming an oxide semiconductor layer of one embodiment of the present invention, the crystallinity of the oxide semiconductor layers (the first and third layers) above and below the second layer can be increased by using the second layer (i.e., CAAC) having high crystallinity as a nucleus or a seed. This can increase the crystallinity of the entire oxide semiconductor layer. In other words, the second layer serves as a nucleus or a seed to cause solid-phase growths of the metal oxides in the oxide semiconductor layers above and below the second layer, so that the oxide semiconductor layer with high crystallinity can be formed. An oxide semiconductor layer formed by such a film formation method, specifically, an oxide semiconductor layer having the CAAC structure, can be referred to as an axial growth CAAC (AG CAAC).

With use of the method for forming the oxide semiconductor layer of one embodiment of the present invention, the first and third layers can have high crystallinity even when they are not formed by a method that facilitates formation of a metal oxide with high crystallinity. The heat treatment has an assist function of increasing the crystallinity of the first and third layers.

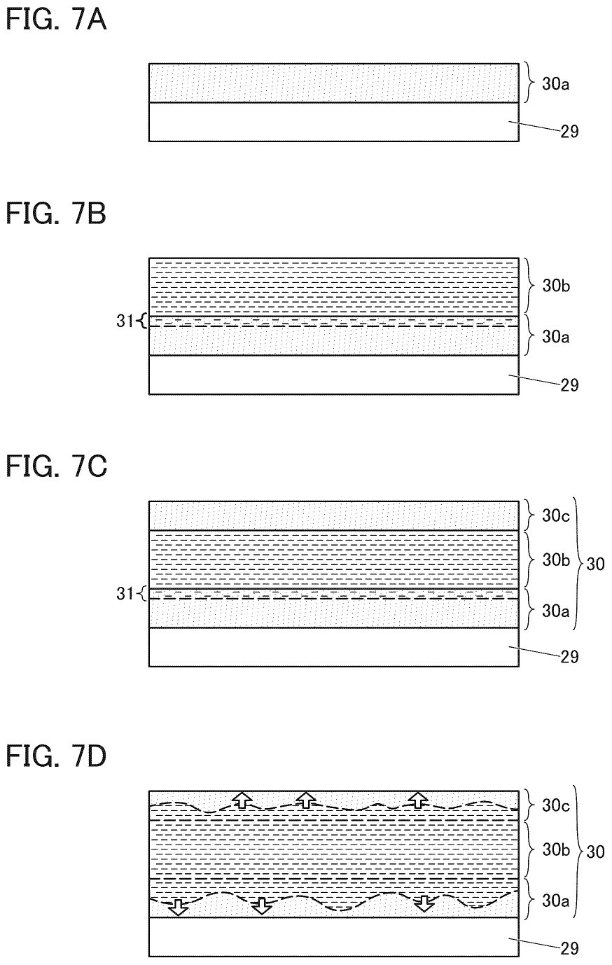

An example of a method for forming an oxide semiconductor layer 30 is described below with reference to FIGS. 7A to 7D.

First, a layer 29 is formed. The layer 29 corresponds to an insulating film or a conductive film included in the semiconductor device. As the insulating layer 29, for example, an insulating film such as a silicon oxide film, a silicon oxynitride film, a silicon nitride film, a silicon nitride oxide film, an aluminum oxide film, or a hafnium oxide film can be used. For another example, a conductive film functioning as an electrode of the semiconductor device can be used as the layer 29. The layer 29 does not need to have crystallinity. In other words, the layer 29 may have an amorphous structure. In the case where the layer 29 has crystallinity, the layer 29 may have a crystal structure with low lattice matching with the metal oxide included in the oxide semiconductor layer 30.

Next, an oxide semiconductor layer 30a is formed over the layer 29 (FIG. 7A).

In the manufacturing method of one embodiment of the present invention, an oxide semiconductor layer 30b is formed by a sputtering method as described later. In the case where a metal oxide film is formed by a sputtering method, a mixed layer of a component of the metal oxide film to be formed and a component contained in the layer serving as the formation surface may be formed (i.e., alloying may occur) due to sputtered particles ejected from a target or the like or energy or the like applied to the substrate side by sputtered particles or the like. The alloying might hinder crystallization of the oxide semiconductor layer above the mixed layer. In the case where alloying occurs, it is difficult to increase the crystallinity of the alloyed region even when heat treatment described later is performed. When an oxide semiconductor layer including the alloyed region is used for a transistor, the initial characteristics or reliability of the transistor may be adversely affected.

In view of the above, before the formation of the oxide semiconductor layer 30b, the oxide semiconductor layer 30a is formed in advance by a film formation method that causes less damage to the formation surface. This can inhibit alloying of the component contained in the oxide semiconductor layer 30 with the component contained in the layer 29, enabling the alloyed region to be thin or thin enough not to be observed. Here, the oxide semiconductor layer 30a is formed by an ALD method.

Examples of the ALD method include a thermal ALD method and a PEALD method.

Unlike in a film formation method in which particles ejected from a target or the like are deposited, in an ALD method, a film is formed by reaction at a surface of an object to be processed. An ALD method enables one atomic layer to be formed at a time, and has various advantages enabling formation of an extremely thin film, formation of a film on a component with a high aspect ratio or a surface with a large step, formation of a film with few defects such as pinholes, formation of a film with excellent coverage, low-temperature film formation, and the like. By forming the oxide semiconductor layer 30a and an after-mentioned oxide semiconductor layer 30c by an ALD method, the entire oxide semiconductor layer can have high coverage. Thus, the oxide semiconductor layer can favorably cover a step, an opening, or the like with a high aspect ratio.

A PEALD method utilizing plasma is preferable, because film formation at lower temperature is possible in some cases. Note that a precursor used in the ALD method sometimes contains an element such as carbon or chlorine. Thus, a film formed by the ALD method may contain an element such as carbon or chlorine in a larger quantity than a film formed by another film formation method.

Here, a method for forming an In-M-Zn oxide as the oxide semiconductor layer 30a by an ALD method is described.

First, a source gas that contains a precursor containing indium is introduced into a chamber so that the precursor is adsorbed on the surface of the layer 29. Then, an oxidizer is introduced as a reactant into the chamber to react with the adsorbed precursor, and components other than indium are released while indium is adsorbed on the substrate, whereby the layer in which indium and oxygen are bonded to each other is formed.

Subsequently, a source gas that contains a precursor containing the element M is introduced into the chamber, so that the precursor is adsorbed on the layer in which indium and oxygen are bonded to each other. Then, an oxidizer is introduced as a reactant into the chamber to react with the adsorbed precursor, and components other than the element M are released while the element M is adsorbed on the substrate, whereby the layer in which the element M and oxygen are bonded to each other is formed.

Subsequently, a source gas that contains a precursor containing zinc is introduced into the chamber, so that the precursor is adsorbed on the layer in which the element M and oxygen are bonded to each other. Then, an oxidizer is introduced as a reactant into the chamber to react with the adsorbed precursor, and components other than zinc are released while zinc is adsorbed on the substrate, whereby the layer in which zinc and oxygen are bonded to each other is formed.

By repeating the above steps, an In-M-Zn oxide can be formed as the oxide semiconductor layer 30a over the layer 29 by an ALD method.

The substrate heating temperature is preferably a temperature corresponding to the decomposition temperature of the precursor. Here, in the case of a thermal ALD method in which triethylindium is used as the precursor containing indium, triethylgallium is used as a precursor containing gallium, and diethylzinc is used as the precursor containing zinc, the substrate heating temperature is higher than or equal to 100° C. and lower than or equal to 350° C., preferably higher than or equal to 150° C. and lower than or equal to 300° C., for example.

It is preferable that after the precursor is adsorbed in the above manner, introduction of the source gas containing the precursor be stopped and the chamber be purged so that an excess precursor, a reaction product, and the like are removed from the chamber. Moreover, it is preferable that after the adsorbed precursor reacts with the oxidizer in the above manner, introduction of the oxidizer be stopped and the chamber be purged so that an excess reactant, a reaction product, and the like are removed from the chamber.

In the description of this specification and the like, in the case of using ozone, oxygen, and water as a reactant or an oxidizer, they include not only those in gas or molecular states but also those in a plasma, radical, and ion states, unless otherwise specified.

Note that when the oxide semiconductor layer 30a is formed by an ALD method, an oxide semiconductor layer having a microcrystalline structure or an amorphous structure that has lower crystallinity than the CAAC structure may be formed.

Next, as the oxide semiconductor layer 30b, an In-M-Zn oxide is formed over the oxide semiconductor layer 30a by a sputtering method (FIG. 7B). The oxide semiconductor layer 30b preferably has a composition suitable for forming the CAAC structure.

When the oxide semiconductor layer 30b is formed by a sputtering method, a mixed layer 31 is formed on the surface of the oxide semiconductor layer 30a or in the vicinity of the surface. A fine crystal region is sometimes formed in the mixed layer 31 by, for example, sputtered particles or energy or the like applied to the substrate side by sputtered particles or the like at the time of forming the oxide semiconductor layer 30b. In the subsequent heat treatment step, the mixed layer 31 or the fine crystal region formed in the mixed layer 31 serves as a nucleus, and at least part of the oxide semiconductor layer 30a is crystallized in some cases.

Examples of the sputtering method include an RF sputtering method using a high-frequency power source for a sputtering power source, a DC sputtering method using a DC power source, and a pulsed DC sputtering method in which a voltage applied to an electrode is changed in a pulsed manner. The DC sputtering method can be suitably used for forming a metal conductive film, and its high film formation rate can increase productivity. The pulsed DC sputtering method can be suitably used for forming a metal conductive film and a semiconductor film. The RF sputtering method can be suitably used for forming an insulating film. A film of a compound such as an oxide, a nitride, or a carbide can be formed by a reactive sputtering method using a reactive gas. The metal oxide film used as the oxide semiconductor layer of one embodiment of the present invention can be formed by any of the above methods selected as appropriate in accordance with, for example, the conductivity of a target used in a sputtering method.

As a target used in a sputtering method, an In-M-Zn oxide can be used. In the case where a metal oxide is formed by a sputtering method, oxygen or a mixed gas of oxygen and a noble gas can be used as a sputtering gas. In addition, an increase in the proportion of oxygen in the sputtering gas can increase the amount of excess oxygen contained in the oxide film to be formed.

A higher proportion of the flow rate of an oxygen gas to the flow rate of the whole formation gas (also referred to as oxygen flow rate ratio) used at the time of forming the metal oxide enables the formed metal oxide to have higher crystallinity in some cases.

When the metal oxide is formed by a sputtering method and the proportion of oxygen in the sputtering gas is higher than 30% and lower than or equal to 100%, preferably higher than or equal to 70% and lower than or equal to 100%, an oxygen-excess metal oxide is formed in some cases. A transistor including an oxygen-excess oxide semiconductor layer in a channel formation region can have relatively high reliability. However, one embodiment of the present invention is not limited thereto. When the proportion of oxygen in the sputtering gas is higher than or equal to 1% and lower than or equal to 30%, preferably higher than or equal to 5% and lower than or equal to 20%, an oxygen-deficient metal oxide is formed. A transistor including the oxygen-deficient metal oxide in a channel formation region can have relatively high field-effect mobility.

In the case where the metal oxide is formed by a sputtering method, the atomic ratio of the formed metal oxide may be different from the atomic ratio of the sputtering target. In particular, the zinc content of the formed metal oxide may be reduced to approximately 50% of that of the sputtering target.

In the formation of the oxide semiconductor layer 30b by a sputtering method, substrate heating is preferably performed. In forming a metal oxide, the substrate temperature (stage temperature) at the time of forming the metal oxide is increased, whereby a metal oxide with high crystallinity can be formed in some cases. In the formation of the oxide semiconductor layer 30b by a sputtering method, the substrate heating temperature is preferably higher than or equal to 100° C. and lower than or equal to 400° C., further preferably higher than or equal to 200° C. and lower than or equal to 300° C., for example.

Here, a formation model of the CAAC structure using a sputtering method is described. First, a microcrystal is formed during film formation by sputtering. The microcrystal is sometimes formed by energy or the like applied to the substrate side by sputtered particles (sometimes referred to as atomic particles), gas particles, or the like. In addition, planar or pellet-like sputtered particles (sometimes referred to as nanoclusters) separated from a sputtering target and then deposited on the formation surface may form the microcrystal. Subsequently, sputtered particles are adsorbed on an end portion of the microcrystal, and the microcrystal grows in the lateral direction (direction substantially parallel to the formation surface). Owing to the lateral growth of the microcrystal, adjacent microcrystals are combined with each other and the end portion of the microcrystal disappears. After the end portion of the microcrystal disappears, sputtered particles are adsorbed on the microcrystal, and the microcrystal grows in the vertical direction (direction substantially perpendicular to the formation surface). Sputtered particles are adsorbed on an end portion of the microcrystal that has grown in the vertical direction, and the microcrystal grows in the lateral direction. Lateral growth and vertical growth of the microcrystal are repeated in the above manner, whereby the CAAC structure is formed. That is, the CAAC structure is formed by growth of a microcrystal that is included in an oxide semiconductor and serves as a nucleus or a seed.

Note that the CAAC structure is less likely to be formed in an oxide semiconductor including impurities such as silicon, carbon, and water. Thus, the oxide semiconductor layer 30b is preferably formed by a film formation method in which entry of the above impurities hardly occurs. An oxide semiconductor with a low concentration of the above impurities can be formed by a sputtering method using a sputtering target with a low concentration of the above impurities and a film formation gas with a small amount of the above impurities; thus, the sputtering method is suitable for forming the oxide semiconductor layer 30b.

Next, the oxide semiconductor layer 30c is formed over the oxide semiconductor layer 30b (FIG. 7C). Here, the oxide semiconductor layer 30c is formed by an ALD method. For the formation of the oxide semiconductor layer 30c by an ALD method, the method for forming the oxide semiconductor layer 30a can be referred to.

When the oxide semiconductor layer 30c having lower crystallinity than the CAAC structure is formed by an ALD method over the oxide semiconductor layer 30b having the CAAC structure, the oxide semiconductor layer 30c may epitaxially grow with the oxide semiconductor layer 30b as a nucleus. Thus, at the time of forming the oxide semiconductor layer 30c, the oxide semiconductor layer 30c may include a region having the CAAC structure. A region having the CAAC structure is preferably formed in the entire oxide semiconductor layer 30c.

The oxide semiconductor layer 30c can be used as a layer in contact with the gate insulating layer of the transistor, for example. Increasing the crystallinity of the layer in contact with the gate insulating layer can increase the carrier mobility in an on state of the transistor.

Moreover, by forming the oxide semiconductor layer 30c by an ALD method, damage to the oxide semiconductor layer 30b is reduced, so that the entire oxide semiconductor layer 30 can have high crystallinity.

By forming the oxide semiconductor layers 30a and 30c by an ALD method, which provides good coverage, the entire oxide semiconductor layer can have high coverage. Moreover, the oxide semiconductor layer 30b with high crystallinity is formed by a sputtering method, and is subjected to epitaxial growth or the like, so that the crystallinity of the upper and lower oxide semiconductor layers (the oxide semiconductor layers 30a and 30c) is increased; thus, the entire oxide semiconductor layer 30 can have high crystallinity. Accordingly, the oxide semiconductor layer 30 can have both high coverage and high crystallinity.

Next, a heat treatment step may be performed.

The temperature of the heat treatment is higher than or equal to 100° C. and lower than or equal to 800° C., preferably higher than or equal to 250° C. and lower than or equal to 650° C., further preferably higher than or equal to 350° C. and lower than or equal to 550° C., for example. Typically, the temperature can be set to 400° C.±25° C. (greater than or equal to 375° C. and less than or equal to 425° C.). The treatment time can be shorter than or equal to 10 hours, longer than or equal to 1 minute and shorter than or equal to 5 hours, or longer than or equal to 1 minute and shorter than or equal to 2 hours. In the case of using a rapid thermal anneal (RTA) apparatus, the treatment time can be longer than or equal to 1 second and shorter than or equal to 5 minutes, for example. By the heat treatment, the oxide semiconductor layer 30c (in other words, crystal molecules formed by an ALD method) is expected to repair the atomic-level space between crystal parts of the CAAC structure of the oxide semiconductor layer 30b.

There is no particular limitation on a heat treatment apparatus used for the heat treatment, and the apparatus may be provided with a device for heating an object to be processed by heat conduction or heat radiation from a heating element such as a resistance heating element. For example, an electric furnace, or an RTA apparatus such as a lamp rapid thermal annealing (LRTA) apparatus or a gas rapid thermal annealing (GRTA) apparatus can be used. An LRTA apparatus is an apparatus for heating an object to be processed by radiation of light (an electromagnetic wave) emitted from a lamp such as a halogen lamp, a metal halide lamp, a xenon arc lamp, a carbon arc lamp, a high pressure sodium lamp, or a high pressure mercury lamp. A GRTA apparatus is an apparatus for heat treatment using a high-temperature gas.

By the heat treatment step, the crystallinity of the region having the CAAC structure in the oxide semiconductor layer 30c is increased in some cases. In the case where the region having the CAAC structure is formed only below the oxide semiconductor layer 30c after film formation by an ALD method, the region having the CAAC structure may be extended upward by the heat treatment step (FIG. 7D). That is, by the heat treatment, the region having the CAAC structure is sometimes formed in the entire oxide semiconductor layer 30c.

By the heat treatment step, the oxide semiconductor layer 30b is further repaired by the oxide semiconductor layer 30c that fills the atomic-level space between crystal parts of the CAAC structure of the oxide semiconductor layer 30b in some cases.

At least part of the oxide semiconductor layer 30a preferably has the CAAC structure by the heat treatment step (FIG. 7D). The CAAC structure is expected to be easily generated when the mixed layer 31 formed in the oxide semiconductor layer 30a in the formation of the oxide semiconductor layer 30b becomes a nucleus or a seed. The oxide semiconductor layer 30a preferably has a large CAAC region, and the CAAC region preferably extends to the vicinity of the layer 29.

Since the CAAC region extends from the upper portion to the lower portion of the oxide semiconductor layer 30a, the CAAC region can extend to the vicinity of the layer 29, regardless of the material and crystallinity of the layer 29. For example, even when the layer 29 has an amorphous structure, the oxide semiconductor layer 30a having high crystallinity can be formed. Thus, the method for forming the oxide semiconductor layer of one embodiment of the present invention is suitable for the case where a layer serving as the formation surface has an amorphous structure, in particular.

After the formation of the oxide semiconductor layer 30c, microwave plasma treatment may be performed.

In this specification and the like, a microwave refers to an electromagnetic wave having a frequency greater than or equal to 300 MHz and less than or equal to 300 GHz. The microwave plasma treatment refers to, for example, treatment using an apparatus including a power source for generating high-density plasma using microwaves. The microwave plasma treatment can also be referred to as microwave excitation high-density plasma treatment.

By performing microwave plasma treatment in an oxygen-containing atmosphere, the impurity concentration in the oxide semiconductor layer 30 can be reduced. Examples of the impurity especially include hydrogen and carbon. Although the microwave plasma treatment in an oxygen-containing atmosphere is performed on the metal oxide in the above, one embodiment of the present invention is not limited thereto. For example, the microwave plasma treatment in an oxygen-containing atmosphere may be performed on an insulating film, more specifically a silicon oxide film, which is positioned in the vicinity of the metal oxide. Furthermore, the crystallinity of the oxide semiconductor layer is sometimes increased by heat in the microwave plasma treatment.

The microwave plasma treatment is preferably performed under reduced pressure, and the pressure is preferably higher than or equal to 10 Pa and lower than or equal to 1000 Pa, further preferably higher than or equal to 300 Pa and lower than or equal to 700 Pa. It is preferable to perform the microwave plasma treatment with the substrate heated. The substrate temperature can be higher than or equal to room temperature (e.g., 25° C.) and lower than or equal to 500° C., preferably higher than or equal to 200° C. and lower than or equal to 500° C., further preferably higher than or equal to 300° C. and lower than or equal to 500° C., still further preferably higher than or equal to 400° C. and lower than or equal to 500° C. The substrate temperature can be higher than or equal to 400° C. and lower than or equal to 450° C., for example.

The microwave plasma treatment may be followed successively by heat treatment without exposure to the air. The temperature of the heat treatment is preferably, for example, higher than or equal to 100° C. and lower than or equal to 750° C., further preferably higher than or equal to 300° C. and lower than or equal to 500° C., still further preferably higher than or equal to 400° C. and lower than or equal to 450° C.

The microwave plasma treatment can be performed using an oxygen gas and an argon gas, for example. The microwave plasma treatment in an oxygen-containing atmosphere converts an oxygen gas into plasma using a high-frequency wave such as microwave or RF, and applies the oxygen plasma to the oxide semiconductor layer. By the effects of plasma, microwave, and the like, VoH in the oxide semiconductor layer can be divided into oxygen vacancies and hydrogen, and hydrogen which is an impurity can be removed from the oxide semiconductor layer. In this manner, VoH contained in the oxide semiconductor layer can be reduced. At this time, carbon bonded to oxygen, hydrogen, or the like can also be removed in some cases. Performing the microwave plasma treatment in such a manner can reduce impurities such as carbon and hydrogen. In addition, oxygen radicals generated by the oxygen plasma can be supplied to oxygen vacancies formed in the oxide semiconductor layer, thereby further reducing oxygen vacancies in the oxide semiconductor layer.

Oxygen injected into the oxide semiconductor layer has a variety of forms such as an oxygen atom, an oxygen molecule, an oxygen ion, and an oxygen radical (also referred to as O radical which is an atom, a molecule, or an ion having an unpaired electron). The oxygen injected into the oxide semiconductor layer preferably has one or more of the above forms. An oxygen radical is particularly preferable.

In the above manner, impurities in the oxide semiconductor layer can be reduced. Crystal growth of the oxide semiconductor layer with a low impurity concentration can further make crystallinity higher.

Note that one or both of the heat treatment and the microwave plasma treatment may be performed directly on the oxide semiconductor layer or performed on an insulating film or the like formed over the oxide semiconductor layer.

The oxide semiconductor layer having the CAAC structure formed by the two kinds of film formation methods sometimes has one or more of a higher dielectric constant, higher film density, and higher film hardness than the oxide semiconductor layer having the CAAC structure formed by one kind of film formation method.

With the use of the oxide semiconductor layer having the CAAC structure formed by two kinds of film formation methods for a channel formation region of a transistor, the transistor can have excellent characteristics (e.g., a high on-state current, high field-effect mobility, a low S value, high frequency characteristics (also referred to as f characteristics), or high reliability).

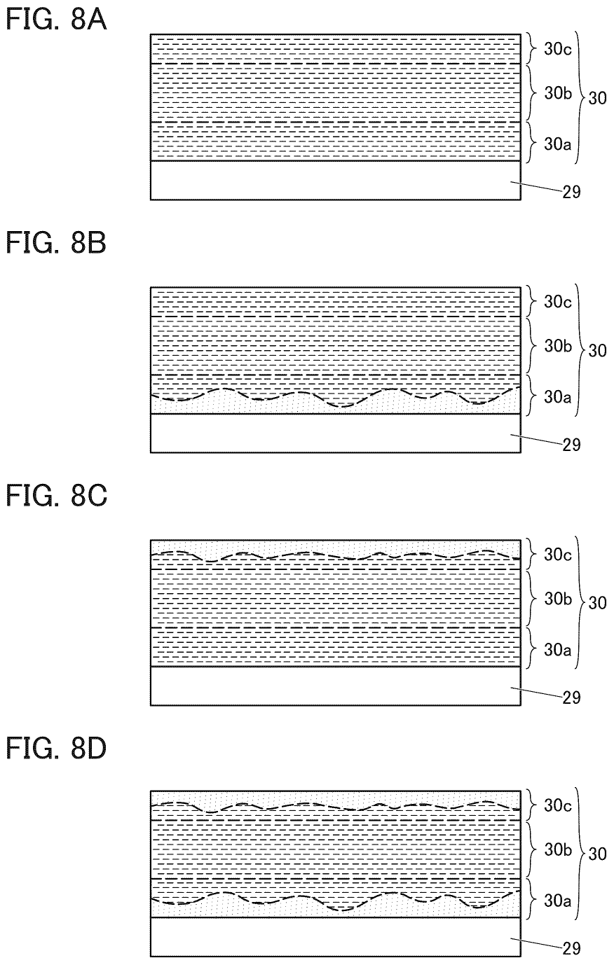

The region having the CAAC structure preferably spreads in the entire oxide semiconductor layer 30 including the oxide semiconductor layers 30a and 30c. FIG. 8A illustrates a state where the oxide semiconductor layers 30a, 30b, and 30c are each crystallized. Crystals in the region having the CAAC structure in the oxide semiconductor layer 30a are connected to crystals in the region having the CAAC structure in the oxide semiconductor layer 30b. Crystals in the region having the CAAC structure in the oxide semiconductor layer 30c are connected to the crystals in the region having the CAAC structure in the oxide semiconductor layer 30b. The oxide semiconductor layer 30 may be expressed as one layer where the interfaces are not clearly observed. The oxide semiconductor layer 30 may be expressed as a single layer in some cases.

In cross-sectional observation with a high-resolution TEM, for example, bright spots arranged parallel to the formation surface are observed in the region having the CAAC structure in each of the oxide semiconductor layers 30a, 30b, and 30c. The c-axis of the CAAC structure included in each of the oxide semiconductor layers 30a, 30b, and 30c is preferably substantially parallel to the normal direction of the formation surface of the oxide semiconductor layer.

Part of the oxide semiconductor layer 30a or part of the oxide semiconductor layer 30c is not crystallized in some cases. In addition, a region having crystallinity lower than that of the CAAC structure may be present in part of the oxide semiconductor layer 30a or part of the oxide semiconductor layer 30c. An example illustrated in FIG. 8B illustrates a state of the oxide semiconductor layer 30a where the vicinity of the interface between the oxide semiconductor layer 30a and the layer 29 is not crystallized or a region having crystallinity lower than that of the CAAC structure is present in the vicinity of the interface between the oxide semiconductor layer 30a and the layer 29. FIG. 8C illustrates a state where the vicinity of the surface of the oxide semiconductor layer 30c is not crystallized or a region having crystallinity lower than that of the CAAC structure is present in the vicinity of the surface of the oxide semiconductor layer 30c. FIG. 8D illustrates a state where the vicinity of the interface between the oxide semiconductor layer 30a and the layer 29 and the vicinity of the surface of the oxide semiconductor layer 30c are not crystallized or regions having crystallinity lower than that of the CAAC structure are present in the vicinity of the interface between the oxide semiconductor layer 30a and the layer 29 and in the vicinity of the surface of the oxide semiconductor layer 30c.

The oxide semiconductor layer of one embodiment of the present invention has high crystallinity in the entire layer. Thus, in the oxide semiconductor layer 30, the boundaries between the stacked films of the oxide semiconductor layers 30a, 30b, and 30c are not observed in some cases. In particular, after heat treatment is performed, the boundaries between the stacked films are difficult to observe in some cases. Whether the boundaries between the stacked films are present can be checked in cross-sectional observation with a TEM or a scanning transmission electron microscope (STEM), for example.

It is preferable that crystals included in the oxide semiconductor layer 30b and crystals included in the oxide semiconductor layer 30a or 30c have a small lattice mismatch. Thus, the oxide semiconductor layer 30a or 30c can form crystals reflecting the orientation of crystals included in the oxide semiconductor layer 30b. In this case, for example, in high-resolution TEM cross-sectional observation of the oxide semiconductor layer 30, bright spots arranged in a layered manner in a direction parallel to the formation surface are observed in the oxide semiconductor layer 30a or 30c.

As long as crystals included in the oxide semiconductor layer 30b and crystals included in the oxide semiconductor layer 30a or 30c have a small lattice mismatch, there is no particular limitation on the crystal structure of the oxide semiconductor layer 30a or 30c. The crystal structure of the oxide semiconductor layer 30a or 30c may be any of a cubic crystal structure, a tetragonal crystal structure, an orthorhombic crystal structure, a hexagonal crystal structure, a monoclinic crystal structure, and a trigonal crystal structure.

The oxide semiconductor layer of one embodiment of the present invention can be used as a semiconductor layer of a transistor.

In the case where the oxide semiconductor layer 30 is used as a semiconductor layer of a transistor, the thickness of the oxide semiconductor layer 30 is preferably greater than or equal to 3 nm and less than or equal to 200 nm, further preferably greater than or equal to 3 nm and less than or equal to 100 nm, still further preferably greater than or equal to 5 nm and less than or equal to 100 nm, yet further preferably greater than or equal to 10 nm and less than or equal to 100 nm, yet still further preferably greater than or equal to 10 nm and less than or equal to 70 nm, yet still further preferably greater than or equal to 15 nm and less than or equal to 70 nm, yet still further preferably greater than or equal to 15 nm and less than or equal to 50 nm, yet still further preferably greater than or equal to 20 nm and less than or equal to 50 nm. In a transistor used for a miniaturized semiconductor device, the thickness of the oxide semiconductor layer 30 is preferably greater than or equal to 1 nm and less than or equal to 20 nm, further preferably greater than or equal to 3 nm and less than or equal to 15 nm, yet further preferably greater than or equal to 5 nm and less than or equal to 12 nm.

The thickness of the oxide semiconductor layer 30b is preferably less than or equal to 200 nm, for example. In the case where the oxide semiconductor layer 30b is in a form of layer, the thickness of the oxide semiconductor layer 30b is preferably, for example, greater than or equal to 1 nm and less than or equal to 200 nm, further preferably greater than or equal to 1 nm and less than or equal to 100 nm, yet further preferably greater than or equal to 2 nm and less than or equal to 100 nm.

Alternatively, when the oxide semiconductor layer 30b can function as a crystal nucleus, the oxide semiconductor layer 30b is not in a form of layer and may be an aggregate of island-shaped regions. For example, such island-shaped regions included in the oxide semiconductor layer 30b are discretely located.

The thicknesses of the oxide semiconductor layers 30a and 30c are each preferably greater than or equal to 1 nm and less than or equal to 50 nm, further preferably greater than or equal to 1 nm and less than or equal to 30 nm, still further preferably greater than or equal to 1 nm and less than or equal to 20 nm, yet still further preferably greater than or equal to 2 nm and less than or equal to 20 nm, for example.

The thickness of the region formed by alloying of the component contained in the oxide semiconductor layer 30 with the component contained in the layer 29 is greater than or equal to 0 nm and less than or equal to 3 nm, preferably greater than or equal to 0 nm and less than or equal to 2 nm, further preferably greater than or equal to 0 nm and less than or equal to 1 nm, still further preferably greater than or equal to 0 nm and less than 0.3 nm. Note that FIGS. 7A and 7B illustrate an example in which an alloyed region is not formed between the layer 29 and the oxide semiconductor layer 30a.

Note that the thickness of the alloyed region can sometimes be calculated by performing SIMS or composition line analysis by energy dispersive X-ray spectroscopy (EDX) on the region and its vicinity.

For example, EDX line analysis is performed on the region and its vicinity with the direction perpendicular to the formation surface of the oxide semiconductor layer 30a as the depth direction. Next, in profiles of quantitative values of elements in the depth direction obtained by the analysis, the depth at which the quantitative value of a metal that is the main component of the oxide semiconductor layer 30a and is not the main component of a layer (here, the layer 29) serving as a formation surface (the metal is In when the oxide semiconductor layer 30a contains In) becomes half is defined as a depth (position) of the interface between the region and the oxide semiconductor layer 30a. Furthermore, the depth at which the quantitative value of an element (e.g., Si) that is the main component of the layer serving as the formation surface and that is not the main component of the oxide semiconductor layer 30a becomes half is defined as a depth (position) of the interface between the region and the layer serving as the formation surface. In the above manner, the thickness of the alloyed region can be calculated.

For example, in the case where SIMS analysis of the oxide semiconductor layer 30 formed over the layer 29 that is formed using a silicon oxide layer is performed, the depth at which the silicon concentration is 50% of the maximum value of the silicon concentration of the layer 29 is defined as an interface, and the distance between the interface and the depth at which the silicon concentration decreases to 1.0×10²¹ atoms/cm³, preferably 5.0×10²⁰ atoms/cm³, further preferably 1.0×10²⁰ atoms/cm³ is defined as a thickness t_s. The thickness t_s is preferably less than or equal to 3 nm, further preferably less than or equal to 2 nm.

Note that when the thickness of the alloyed region is reduced, the CAAC structure can be formed in the vicinity of the formation surface. Here, the vicinity of the formation surface refers to, for example, a region ranging from the formation surface of the oxide semiconductor layer 30 to greater than 0 nm and less than or equal to 3 nm, preferably greater than 0 nm and less than or equal to 2 nm, further preferably greater than or equal to 1 nm and less than or equal to 2 nm in a direction substantially perpendicular to the formation surface of the oxide semiconductor layer 30.

The oxide semiconductor layer 30a includes a region positioned in a range of 0 nm to 3 nm, both inclusive, from the top surface of the layer 29, for example. The oxide semiconductor layer 30c is positioned in a range of 0 nm to 3 nm, both inclusive, from the top surface of the oxide semiconductor layer 30b. The oxide semiconductor layers 30a, 30b, and 30c have substantially the same thicknesses, for example. Alternatively, the oxide semiconductor layers 30a, 30b, and 30c may have different thicknesses.

Although the structure in which the oxide semiconductor layer 30 has a three-layer structure of the oxide semiconductor layers 30a to 30c is described above, the present invention is not limited thereto. The oxide semiconductor layer 30 may have either a two-layer structure or a stacked-layer structure of four or more layers.

In the case where the oxide semiconductor layer 30 has a two-layer structure, the oxide semiconductor layers 30a and 30b can be stacked in this order. This can inhibit alloying of the component contained in the oxide semiconductor layer 30 with the component contained in the layer 29, enabling the alloyed region to be thin or thin enough not to be observed.

Alternatively, in the case where the oxide semiconductor layer 30 has a five-layer structure, first, second, third, fourth, and fifth oxide semiconductors can be stacked in this order to form the oxide semiconductor layer 30. For example, the first, third, and fifth oxide semiconductors are formed preferably by the second film formation method, particularly by an ALD method. The second and fourth oxide semiconductors are formed preferably by the first film formation method, particularly by a sputtering method. With such a structure, crystal growth is promoted from one or both of the second and fourth oxide semiconductors, so that the crystallinity of the third oxide semiconductor can be increased, even when the third oxide semiconductor has a composition in which the CAAC structure is less likely to be formed.

In the case where the oxide semiconductor layer 30 has a stacked-layer structure of two or more layers, typically a stacked-layer structure of two to five layers, the layers are preferably formed successively without exposure to the air. For example, the layers are preferably formed successively using a multi-chamber film formation apparatus. In this case, the oxide semiconductor layer 30 can be formed while inhibiting entry of impurities into the layers.

### [C-Axis Alignment Proportion]

The oxide semiconductor layer of one embodiment of the present invention has the CAAC structure. The crystallinity degree of the oxide semiconductor layer of one embodiment of the present invention can be evaluated with the use of crystal orientation, for example.

The CAAC structure in oxide semiconductor layer can be evaluated from a map showing crystal orientation in some cases. In a region having the CAAC structure, for example, a state where a crystal has c-axis alignment is observed.

The map showing crystal orientation can be obtained by, for example, obtaining a cross-sectional TEM image, performing FFT processing on each region in the cross-sectional TEM image to form an FFT pattern, and calculating the crystal axis direction in each region. Specifically, two spots with high intensity are observed in the FFT pattern of the region including a layered crystal part. The crystal axis direction in the region can be obtained from the angle of a line segment connecting the two spots. The FFT pattern reflects reciprocal lattice space information like an electron diffraction pattern.

By calculating the proportion of regions having c-axis alignment from the map indicating the crystal orientation, the c-axis alignment proportion can be calculated.

In the oxide semiconductor layer of one embodiment of the present invention, the c-axis orientation rate can be calculated with use of, for example, cross-sectional or plan-view TEM observation of the oxide semiconductor layer and the above map indicating the crystal orientation. The region where the FFT is performed (also referred to as an FFT window) can be a circle with a diameter of 1.0 nm, for example. Note that the region where the FFT is performed is not limited to a circle.

In the case where analysis is performed using a cross-sectional TEM image, the cross-sectional TEM image observation range is preferably, for example, a region having a width of 100 nm in the horizontal direction with the direction perpendicular to the formation surface regarded as the vertical direction. Note that the observation range is not limited to this.

When the proportion of a region where a difference between the orientation and the c-axis is less than or equal to 20° is calculated as the c-axis alignment proportion in the oxide semiconductor layer of one embodiment of the present invention, for example, the c-axis alignment proportion is preferably higher than or equal to 50%, further preferably higher than or equal to 60%, still further preferably higher than or equal to 70%, yet still further preferably higher than or equal to 80%, yet still further preferably higher than or equal to 90%, yet still further preferably higher than or equal to 95%.

The c-axis alignment proportions of a region formed as the oxide semiconductor layer 30a, a region formed as the oxide semiconductor layer 30b, and a region formed as the oxide semiconductor layer 30c are Rc1. Rc2, and Rc3, respectively. Here, the c-axis alignment proportion is preferably calculated as the proportion of regions where the orientation is deviated from the c-axis by less than or equal to 20°, for example. Rc2 is preferably higher than or equal to 50%, further preferably higher than or equal to 60%, still further preferably higher than or equal to 70%, yet still further preferably higher than or equal to 80%, yet still further preferably higher than or equal to 90%, yet still further preferably higher than or equal to 95%. Furthermore, Rc3 is preferably higher than or equal to 50%, further preferably higher than or equal to 60%, still further preferably higher than or equal to 70%, yet still further preferably higher than or equal to 80%, yet still further preferably higher than or equal to 90%, yet still further preferably higher than or equal to 95%. Rc3/Rc1 is preferably greater than one. Furthermore, Rc2/Rc1 is preferably greater than one.

### [Composition of Oxide Semiconductor Layer]

The oxide semiconductor layer 30a preferably has a composition different from that of the oxide semiconductor layer 30b. The oxide semiconductor layer 30c preferably has a composition different from that of the oxide semiconductor layer 30b. The oxide semiconductor layer 30a can have the same composition as the oxide semiconductor layer 30c. Alternatively, the oxide semiconductor layers 30a and 30c can have different compositions.

The oxide semiconductor layer 30b preferably has a composition suitable for forming the CAAC structure. The oxide semiconductor layer 30b preferably contains zinc, for example. The oxide semiconductor layer 30b containing zinc can be a metal oxide having high crystallinity. The oxide semiconductor layer 30b preferably contains the element M in addition to zinc. When the oxide semiconductor layer 30b contains the element M, formation of oxygen vacancies in the metal oxide can be inhibited, for example. For the oxide semiconductor layer 30b, a metal oxide with a composition of In:M:Zn=1:1:1 [atomic ratio] or in the neighborhood thereof, a metal oxide with a composition of In:M:Zn=1:1:1.2 [atomic ratio] or in the neighborhood thereof, a composition of In:M:Zn=1:1:0.5 [atomic ratio] or in the neighborhood thereof, a metal oxide with a composition of In:M:Zn=1:1:2 [atomic ratio] or in the neighborhood thereof, a metal oxide with a composition of In:M:Zn=4:2:3 [atomic ratio] or in the neighborhood thereof, a metal oxide with a composition of In:M:Zn=1:3:2 [atomic ratio] or in the neighborhood thereof, or a metal oxide with a composition of In:M:Zn=1:3:4 [atomic ratio] or in the neighborhood thereof is specifically used. Note that the neighborhood of the atomic ratio includes ±30% of an intended atomic ratio. It is preferable to use one or more of gallium, tin, yttrium, and aluminum as the element M.

The oxide semiconductor layer 30b may have a structure not containing the element M. For example, an In—Zn oxide may be used. Specifically, a composition of In:Zn=1:1 [atomic ratio] or in the neighborhood thereof, a composition of In:Zn=2:1 [atomic ratio] or in the neighborhood thereof, or a composition of In:Zn=4:1 [atomic ratio] or in the neighborhood thereof can be used. Alternatively, an indium oxide may be used. A structure containing a slight amount of the element M may be employed. Examples of the composition include a composition of In:Ga:Zn=4:0.1:1 [atomic ratio] or in the neighborhood thereof and a composition of In:Ga:Zn=2:0.1:1 [atomic ratio] or in the neighborhood thereof. Other examples include a composition of In:Sn:Zn=4:0.1:1 [atomic ratio] or in the neighborhood thereof and a composition of In:Sn:Zn=2:0.1:1 [atomic ratio] or in the neighborhood thereof.

The oxide semiconductor layers 30a and 30c can be metal oxides with a high proportion of In. In particular, the oxide semiconductor layers 30a and 30c are each preferably a metal oxide having a higher proportion of In than that of the oxide semiconductor layer 30b. The oxide semiconductor layers 30a and 30c can each be formed by an ALD method, for example. In particular, a metal oxide in which the proportion of In is higher than that of the element M is preferably used. With the use of a metal oxide having a high proportion of In, the on-state current can be increased and the frequency characteristics can be enhanced in a transistor using an oxide semiconductor layer.

An oxide semiconductor with a high In content tends to be polycrystallized. The use of a metal oxide having a polycrystalline structure for a transistor adversely affects the initial characteristics or reliability of the transistor. In the oxide semiconductor layer of one embodiment of the present invention, the crystal orientation of the oxide semiconductor layer 30b can be reflected in the oxide semiconductor layers 30a and 30c each having a high In content. Thus, polycrystallization can be inhibited even in the case where a metal oxide with a high In content is used for each of the oxide semiconductor layers 30a and 30c.

Alternatively, the oxide semiconductor layers 30a and 30c may each have a structure not containing the element M. For example, an In—Zn oxide may be used. Specifically, a composition of In:Zn=1:1 [atomic ratio] or in the neighborhood thereof, a composition of In:Zn=2:1 [atomic ratio] or in the neighborhood thereof, or a composition of In:Zn=4:1 [atomic ratio] or in the neighborhood thereof can be used. Alternatively, an indium oxide may be used. A structure containing a slight amount of the element M may be employed for the oxide semiconductor layers 30a and 30c. Specific examples of the composition include a composition of In:Ga:Zn=4:0.1:1 [atomic ratio] or in the neighborhood thereof, a composition of In:Ga:Zn=2:0.1:1 [atomic ratio] or in the neighborhood thereof, a composition of In:Sn:Zn=4:0.1:1 [atomic ratio] or in the neighborhood thereof, and a composition of In:Sn:Zn=2:0.1:1 [atomic ratio] or in the neighborhood thereof.

A metal oxide with a large proportion of Ga can be used for each of the oxide semiconductor layers 30a and 30c. For example, for each of the oxide semiconductor layers 30a and 30c, a metal oxide having a Ga proportion higher than that of the oxide semiconductor layer 30b can be used. For each of the oxide semiconductor layers 30a and 30c, it is preferable to use a metal oxide with a composition of In:Ga:Zn=1:1:1 [atomic ratio] or in the neighborhood thereof, a metal oxide with a composition of In:Ga:Zn=1:3:2 [atomic ratio] or in the neighborhood thereof, or a metal oxide with a composition of In:Ga:Zn=1:3:4 [atomic ratio] or in the neighborhood thereof. When the proportion of Ga is increased, the band gap of each of the oxide semiconductor layers 30a and 30c can be larger than that of the oxide semiconductor layer 30b in some cases. Thus, the oxide semiconductor layer 30b is sandwiched between the oxide semiconductor layers 30a and 30c each having a wide band gap, so that the oxide semiconductor layer 30b can mainly function as a current path (channel). Furthermore, trap states at the interfaces with the oxide semiconductor layer 30b and the vicinity thereof can be reduced. Accordingly, a buried-channel transistor where a channel is away from the interface with an insulating layer can be achieved, whereby the field-effect mobility can be increased. Furthermore, the influence of interface states that may be formed on the back channel side is reduced, so that light deterioration (e.g., light negative bias deterioration) of the transistor can be inhibited and the reliability of the transistor can be increased.

Alternatively, one of the oxide semiconductor layers 30a and 30c can be a metal oxide with a higher In proportion than the oxide semiconductor layer 30b, and the other can be a metal oxide with a higher Ga proportion than the oxide semiconductor layer 30b.

The oxide semiconductor layers 30a, 30b, and 30c may each include a stack of layers having the above compositions. For example, the oxide semiconductor layer 30c may have a structure in which a metal oxide with a high Ga proportion is stacked over a metal oxide with a high In proportion.

A metal oxide having the same composition as the oxide semiconductor layer 30b may be used for each of the oxide semiconductor layers 30a and 30c. By using the same composition, the oxide semiconductors each easily have the CAAC structure after heat treatment in some cases.

In the oxide semiconductor layer of one embodiment of the present invention, even in the case where a composition in which the CAAC structure is less likely to be formed in the formation of a single layer is used for the oxide semiconductor layers 30a and 30c, crystal growth occurs with the oxide semiconductor layer 30b as a nucleus, so that the entire oxide semiconductor layer including the oxide semiconductor layers 30a and 30c can have the CAAC structure. Alternatively, the CAAC structure can be formed in a region that includes the oxide semiconductor layer 30b and at least part of each of the oxide semiconductor layers 30a and 30c.

Analysis of the composition of the metal oxide used for the oxide semiconductor layer 30 can be performed by EDX, XPS, inductively coupled plasma-mass spectrometry (ICP-MS), or inductively coupled plasma-atomic emission spectrometry (ICP-AES). Alternatively, these methods may be combined as appropriate for the analysis. As for an element whose content is low, the actual content may be different from the content obtained by analysis because of the influence of the analysis accuracy. In the case where the content of the element M is low, for example, the content of the element M obtained by analysis may be lower than the actual content.

### [Impurities in Oxide Semiconductor]

The influence of impurities in the oxide semiconductor will be described. The impurities contained in the oxide semiconductor can be quantified by XPS, SIMS, EDX, ICP-MS, ICP-AES, or the like.

It is preferable that the channel formation region of the transistor including an oxide semiconductor in the semiconductor layer contain less oxygen vacancies or have a lower concentration of impurities such as hydrogen, nitrogen, and a metal element than the source region and the drain region. When oxygen vacancies (Vo) and impurities are in a channel formation region of an oxide semiconductor in a transistor, electrical characteristics of the transistor may easily vary and the reliability thereof may worsen. In some cases, hydrogen in the vicinity of oxygen vacancies forms VoH and generates an electron serving as a carrier. Thus, if the channel formation region in the oxide semiconductor includes oxygen vacancies, the transistor tends to have normally-on characteristics. Therefore, VoH in the channel formation region is also preferably reduced. Thus, the channel formation region of the transistor is a high-resistance region having a low carrier concentration. Accordingly, the channel formation region of the transistor can be regarded as an i-type (intrinsic) or substantially i-type region.

In order to obtain stable electrical characteristics of the transistor, reducing the impurity concentration in the oxide semiconductor is effective. Examples of the impurity include hydrogen, carbon, and nitrogen. Note that an impurity in an oxide semiconductor refers to, for example, elements other than the main components of the oxide semiconductor. For example, an element with a concentration of lower than 1 atomic % or lower than 0.1 atomic % is an impurity.

When an oxide semiconductor contains silicon or carbon, which is a Group 14 element, defect states are formed in the oxide semiconductor. Thus, the carbon concentration in the channel formation region in the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³. The silicon concentration in the channel formation region in the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³.

Furthermore, when the oxide semiconductor contains nitrogen, the oxide semiconductor easily becomes n-type by generation of electrons serving as carriers and an increase in carrier concentration. As a result, a transistor including, as a semiconductor, an oxide semiconductor that contains nitrogen tends to have normally-on characteristics. When nitrogen is contained in the oxide semiconductor, a trap state is sometimes formed. This may make the electrical characteristics of the transistor unstable. Thus, the nitrogen concentration in the channel formation region in the oxide semiconductor, which is measured by SIMS, is lower than or equal to 1×10²⁰ atoms/cm³, preferably lower than or equal to 5×10¹⁹ atoms/cm³, further preferably lower than or equal to 1×10¹⁹ atoms/cm³, further preferably lower than or equal to 5×10¹⁸ atoms/cm³, still further preferably lower than or equal to 1×10¹⁸ atoms/cm³, yet still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom generates an electron serving as a carrier. Thus, a transistor including an oxide semiconductor that contains hydrogen tends to have normally-on characteristics. For this reason, hydrogen in the channel formation region in the oxide semiconductor is preferably reduced as much as possible. Specifically, the hydrogen concentration in the channel formation region in the oxide semiconductor, which is measured by SIMS, is lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, still further preferably lower than 1×10¹⁸ atoms/cm³, yet still further preferably lower than 1×10¹⁷ atoms/cm³.

When the oxide semiconductor contains an alkali metal or an alkaline earth metal, defect states are formed and carriers are generated in some cases. Accordingly, a transistor including an oxide semiconductor that contains an alkali metal or an alkaline earth metal tends to have normally-on characteristics. Thus, the concentration of an alkali metal or an alkaline earth metal in the channel formation region in the oxide semiconductor, which is measured by SIMS, is lower than or equal to 1×10¹⁸ atoms/cm³, preferably lower than or equal to 2×10¹⁶ atoms/cm³.

When an oxide semiconductor with sufficiently reduced impurities is used for a channel formation region of a transistor, the transistor can have stable electrical characteristics.

The average thickness of the oxide semiconductor layer 30 in the channel formation region is preferably less than or equal to 30 nm, further preferably less than or equal to 15 nm, still further preferably less than or equal to 10 nm.

The oxide semiconductor layer 30a is an oxide semiconductor layer formed on the formation surface. The thickness of the oxide semiconductor layer 30a is preferably greater than or equal to 0.5 nm and less than or equal to 3 nm.

In cross-sectional observation of the semiconductor layer 230 of the semiconductor device of one embodiment of the present invention, a state can sometimes be observed where metal atoms included in a metal oxide are arranged in a layered manner in a region having the CAAC structure. In this case, the metal atoms are arranged in a direction perpendicular or substantially perpendicular to the substrate surface, for example.

The metal atoms arranged in a layered manner in the region having the CAAC structure can be observed as arranged bright spots in a cross section of the oxide semiconductor layer observed with the TEM image. Thus, when a cross section of the semiconductor layer 230 is observed in the semiconductor device of one embodiment of the present invention, a state can sometimes be observed where bright spots are arranged in a direction perpendicular or substantially perpendicular to the substrate surface.

The oxide semiconductor layer 30, which is the AG CAAC, can be used as the semiconductor layer 230a of the transistor 200a. For example, as illustrated in FIG. 3B, the semiconductor layer 230a can include a semiconductor layer 230a1, a semiconductor layer 230a2 in contact with the semiconductor layer 230a1, and a semiconductor layer 230a3 in contact with the semiconductor layer 230a2. Here, the semiconductor layer 230a1, the semiconductor layer 230a2, and the semiconductor layer 230a3 correspond to the oxide semiconductor layer 30a, the oxide semiconductor layer 30b, and the oxide semiconductor layer 30c, respectively.

Here, the pillar described above (the insulating layer 223a described later) corresponds to the layer 29. That is, the formation surface of the semiconductor layer 230a is the pillar, and the pillar is removed in the transistor 200a. In the manufacturing process, one side surface of the semiconductor layer 230a1 is in contact with the pillar, and the other is in contact with the semiconductor layer 230a2. After the pillar is removed, the one side surface of the semiconductor layer 230a1 is in contact with the insulating layer 250a. One side surface of the semiconductor layer 230a2 is in contact with the semiconductor layer 230a1, and the other is in contact with the semiconductor layer 230a3. One side surface of the semiconductor layer 230a3 is in contact with the semiconductor layer 230a2, and the other is in contact with the insulating layer 250a. Since the pillar is formed so that its side surface is perpendicular or substantially perpendicular to a surface of the substrate (i.e., a surface of the insulating layer 222), the side surface of the semiconductor layer 230a (the semiconductor layers 230a1 to 230a3) is also perpendicular or substantially perpendicular to the surface of the substrate.

As described above, in the cross section of the semiconductor layer 230a (the semiconductor layers 230a1 to 230a3) observed using the TEM image, a state where metal atoms are arranged in a layered manner in a direction parallel or substantially parallel to the formation surface is observed. In other words, in the cross section of the semiconductor layer 230a (the semiconductor layers 230a1 to 230a3) observed using the TEM image, a state where metal atoms are arranged in a layered manner in a direction perpendicular or substantially perpendicular to the substrate surface is observed. In addition, the c-axis of the AG CAAC can be regarded as being substantially parallel to the normal direction of the side surface of the semiconductor layer 230a.

With the use of the semiconductor layer 230a, which is the AG CAAC, in the channel formation region of the transistor 200a in this manner, the transistor can have favorable on-state current, field-effect mobility, S-value, frequency characteristics, and reliability.

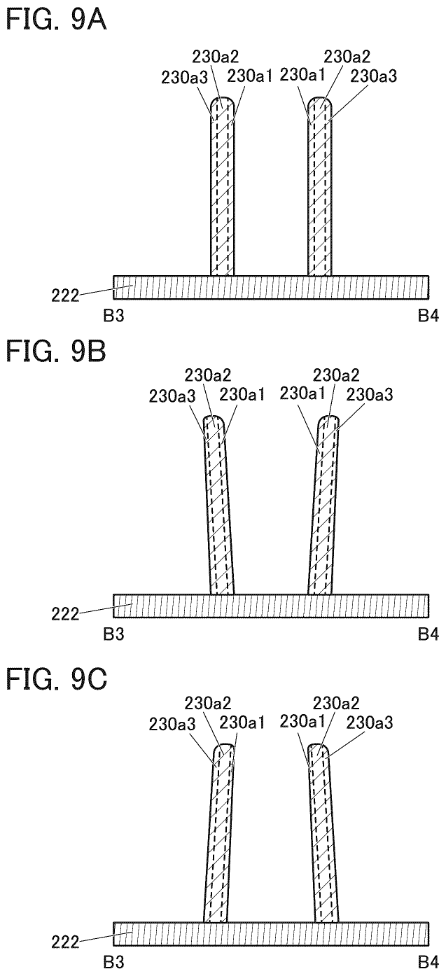

In the case where the semiconductor layer 230a has a three-layer structure of the semiconductor layers 230a1 to 230a3 as described above, the semiconductor layers 230a1, 230a2, and 230a3 are formed in this order as the semiconductor layer 230a around the region where the pillar is formed. Thus, as illustrated in FIG. 9A, the semiconductor layers 230a3, 230a2, 230a1, 230a1, 230a2, and 230a3 are arranged in this order to form a bilaterally symmetrical structure in the cross-sectional view in the channel width direction. That is, in order to form the bilaterally symmetrical structure of the semiconductor layers 230a in the cross-sectional view, the semiconductor layers 230a1 and 230a3 preferably have substantially the same compositions. Moreover, the semiconductor layers 230a1 and 230a3 preferably have substantially the same thicknesses. In the case where the angle θ in FIG. 3B is greater than or equal to 80° and less than 90°, that is, the side surface of the semiconductor layer 230a is slightly inclined, the semiconductor layers 230a are arranged to be inclined bilaterally symmetrically as illustrated in FIG. 9B. In the case where the semiconductor layer 230a is formed to be inclined, an upper portion might be thinner than a lower portion in the semiconductor layer 230a as illustrated in FIG. 9B. In the case where the angle θ in FIG. 3B is greater than 90° and less than or equal to 100°, that is, the side surface of the semiconductor layer 230a is slightly inclined, the semiconductor layers 230a are arranged to be inclined bilaterally symmetrically as illustrated in FIG. 9C. In the case where the semiconductor layer 230a is formed to be inclined, the upper portion might be thinner than the lower portion in the semiconductor layer 230a as illustrated in FIG. 9C.

In the semiconductor layer 230a, the channel formation region and the source and drain regions of the transistor 200a are formed. The channel formation region is sandwiched between the source and drain regions. At least a part of the channel formation region overlaps with the conductive layer 260a. The source region overlaps with the conductive layer 242a, and the drain region overlaps with the conductive layer 242b. Note that the source region and the drain region can be interchanged with each other.

The channel formation region has a smaller amount of oxygen vacancies or a lower impurity concentration than the source and drain regions, and thus has a low carrier concentration and a high resistance. Thus, the channel formation region can be regarded as an i-type (intrinsic) or substantially i-type region.

The source and drain regions have a large amount of oxygen vacancies or a high concentration of impurities such as hydrogen, nitrogen, and a metal element, and thus are low-resistance regions with a high carrier concentration. In other words, the source and drain regions are n-type regions (low-resistance regions) having a higher carrier concentration than the channel formation region.

Note that the carrier concentration in the channel formation region is preferably lower than or equal to 1×10¹⁸ cm⁻³, lower than 1×10¹⁷ cm⁻³, lower than 1×10¹⁶ cm⁻³, lower than 1×10¹⁵ cm⁻³, lower than 1×10¹⁴ cm⁻³, lower than 1×10¹³ cm⁻³, lower than 1×10¹² cm⁻³, lower than 1×10¹¹ cm⁻³, or lower than 1×10¹⁰ cm⁻³. The lower limit of the carrier concentration of the channel formation region is not particularly limited and can be, for example, 1×10⁻⁹ cm⁻³.

In order to reduce the carrier concentration of the semiconductor layer 230a, the impurity concentration in the semiconductor layer 230a is reduced so that the density of defect states is reduced. In this specification and the like, a state with a low impurity concentration and a low density of defect states is referred to as a highly purified intrinsic or substantially highly purified intrinsic state. Note that an oxide semiconductor (or a metal oxide) having a low carrier concentration may be referred to as a highly purified intrinsic or substantially highly purified intrinsic oxide semiconductor (or metal oxide).

To obtain stable electrical characteristics of the transistor 200a, it is effective to reduce the concentration of impurities in the channel formation region in the semiconductor layer 230a. In order to reduce the concentration of impurities in the semiconductor layer 230a, the concentration of impurities also in a film adjacent to the semiconductor layer 230a is preferably reduced. Examples of impurities include hydrogen, nitrogen, an alkali metal, an alkaline earth metal, iron, nickel, and silicon. Note that an impurity in the semiconductor layer 230a refers to, for example, elements other than the main components of the semiconductor layer 230a.

In the semiconductor layer 230a, the boundaries between the regions are difficult to clearly observe in some cases. The concentration of a metal element and an impurity element such as hydrogen or nitrogen, which is detected in each region, may be gradually changed not only between the regions but also in each region. That is, the region closer to the channel formation region may have a lower concentration of a metal element and an impurity element such as hydrogen or nitrogen.

The conductive layer 240a is formed in the opening in the insulating layers 275, 280, 282, 283, and 285. The bottom surface of the conductive layer 240a is in contact with the top surface of the conductive layer 242a2. Here, the top surface of the conductive layer 240a is substantially level with the top surface of the insulating layer 285.

A conductive material containing tungsten, copper, or aluminum as its main component is preferably used for the conductive layer 240a. The conductive layer 240a may have a stacked-layer structure in which a first conductive layer is provided in contact with the side surface of the insulating layer 241 and a second conductive layer is provided on the inner side of the first conductive layer. In this case, the above-described conductive material can be used for the second conductive layer.

In the case where the conductive layer 240a has a stacked-layer structure, a conductive material having a function of inhibiting transmission of impurities such as water and hydrogen is preferably used for a first conductive layer positioned in the vicinity of the insulating layers 285, 283, 282, 280, and 275. For example, tantalum, tantalum nitride, titanium, titanium nitride, ruthenium, or ruthenium oxide is preferably used. The conductive material having a function of inhibiting transmission of impurities such as water and hydrogen can be used as a single layer or stacked layers. With such a structure, impurities such as water and hydrogen contained in the components above the insulating layer 283 can be inhibited from entering the semiconductor layer 230a through the conductive layer 240a.

Although the conductive layer 240a has a two-layer structure in the above, the present invention is not limited thereto. For example, the conductive layer 240a may have a single-layer structure or a stacked-layer structure of three or more layers.

The insulating layer 241a is formed in contact with the inner wall of the opening in the insulating layers 275, 280, 282, 283, and 285. The inner side surface of the insulating layer 241a is in contact with the conductive layer 240a.

The insulating layer 241a is formed using the barrier insulating film that can be used as the insulating layer 275 or the like. For the insulating layer 241a, for example, an insulator such as silicon nitride, aluminum oxide, or silicon nitride oxide is used. With the insulating layer 241a, impurities such as water and hydrogen contained in the insulating layer 280 or the like can be inhibited from entering the semiconductor layer 230a through the conductive layer 240a. Silicon nitride is particularly preferable because of its high blocking property against hydrogen. Moreover, oxygen contained in the insulating layer 280 can be inhibited from being absorbed into the conductive layer 240a.

Although the insulating layer 241a has a single-layer structure in the above, the present invention is not limited thereto. For example, the insulating layer 241a may have a stacked-layer structure of two or more layers.

When the insulating layer 241a has a two-layer structure, for example, a first insulating layer in contact with the inner wall of the opening formed in the insulating layer 280 and the like and a second insulating layer located inward from the first insulating layer are preferably formed using a combination of a barrier insulating film against oxygen and a barrier insulating film against hydrogen.

For example, aluminum oxide formed by a thermal ALD method is used as the first insulating layer, and silicon nitride formed by a PEALD method is used as the second insulating layer. With this structure, oxidation of the conductive layer 240a can be inhibited, and hydrogen can be inhibited from entering the conductive layer 240a.

As illustrated in FIG. 3C, for example, the conductive layer 240a may cover the semiconductor layer 230a and the conductive layer 242a that is folded in half while sandwiching the semiconductor layer 230a. Thus, the upper portion, side surface on the B3 side, and side surface on the B4 side of the conductive layer 242a are in contact with the conductive layer 240a in the cross-sectional view in the channel width direction. Therefore, the contact area between the conductive layers 240a and 242a is larger by the height H of each of the side surfaces on the B3 side and the B4 side of the semiconductor layer 230a than that in the case of forming a flat-plate semiconductor layer 230a. Furthermore, when the conductive layer 240a covers the plurality of fin-shaped semiconductor layers 230a as illustrated in FIG. 1A, the contact area between the conductive layers 240a and 242a can be further increased.

The increase in the contact area between the conductive layers 240a and 242a can reduce the contact resistance between the conductive layers 240a and 242a. Thus, the transistor 200a can have favorable on-state current, frequency characteristics, and the like without a very large occupied area. Accordingly, a semiconductor device that operates at high speed can be provided. In addition, a memory device including the semiconductor device can operate at high speed. Moreover, miniaturization or high integration of the semiconductor device can be achieved. Furthermore, a memory device including the semiconductor device can have large memory capacity.

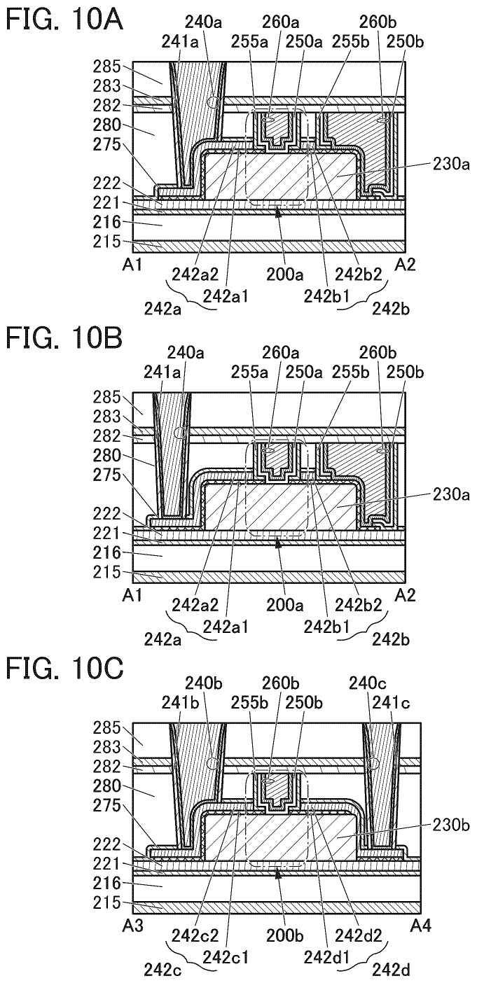

In the above, the opening provided with the conductive layer 240a and the insulating layer 241a has a quadrangular shape in the top view as illustrated in FIG. 1A; however, one embodiment of the present invention is not limited thereto. For example, the opening in the top view may have a circular shape, a substantially circular shape such as an elliptical shape, a polygonal shape such as a quadrangular shape, or a polygonal shape such as a quadrangular shape with rounded corners. Although the opening is formed to overlap with the plurality of fin-shaped semiconductor layers 230a as illustrated in FIG. 1C, one embodiment of the present invention is not limited thereto; the opening is formed to overlap with at least the conductive layer 242a. As illustrated in FIG. 10A, for example, a structure can be employed in which part of the opening (also referred to as part of the conductive layer 240a) overlaps with the semiconductor layer 230a, and another part of the opening (also referred to another part of the conductive layer 240a) does not overlap with the semiconductor layer 230a. Such a structure in which part of the conductive layer 240a overlaps with the semiconductor layer 230a can increase a margin where the conductive layer 240a is positioned. For another example, as illustrated in FIG. 10B, the opening and the conductive layer 240a can be provided in a region not overlapping with the semiconductor layer 230a.

[Transistor 200b]

The transistor 200b can have a structure similar to that of the transistor 200a described above. The description of the structure of the transistor 200a can be referred to for the description of the structure of the transistor 200b by replacing the transistor 200a, the semiconductor layer 230a, the conductive layer 242a (the conductive layers 242a1 and 242a2), the conductive layer 242b (the conductive layers 242b 1 and 242b2), the insulating layer 255a, the insulating layer 250a, the conductive layer 260a, the opening 291a, and the opening 292a with the transistor 200b, the semiconductor layer 230b, the conductive layer 242c (the conductive layers 242c1 and 242c2), the conductive layer 242d (the conductive layers 242d1 and 242d2), the insulating layer 255b, the insulating layer 250b, the conductive layer 260b, the opening 291b, and the opening 292b, respectively, and appropriately replacing words or sentences as necessary.

The description of the structure of the conductive layer 240a and the insulating layer 241a can be referred to for the description of the structure of the conductive layer 240b and the insulating layer 241b, respectively, by replacing the conductive layer 240a, the insulating layer 241a, the semiconductor layer 230a, and the conductive layer 242a (the conductive layers 242a1 and 242a2) with the conductive layer 240b, the insulating layer 241b, the semiconductor layer 230b, and the conductive layer 242c (the conductive layers 242c1 and 242c2), respectively, and appropriately replacing words or sentences as necessary. Similarly, the description of the structure of the conductive layer 240a and the insulating layer 241a can be referred to for the description of the structure of the conductive layer 240c and the insulating layer 241c, respectively, by replacing the conductive layer 240a, the insulating layer 241a, the semiconductor layer 230a, and the conductive layer 242a (the conductive layers 242a1 and 242a2) with the conductive layer 240c, the insulating layer 241c, the semiconductor layer 230b, and the conductive layer 242d (the conductive layers 242d1 and 242d2), respectively, and appropriately replacing words or sentences as necessary.

Although the conductive layers 240b and 240c in FIG. 1C are positioned bilaterally symmetrically with the conductive layer 260b as the center, the present invention is not limited thereto. For example, the conductive layers 240b and 240c may be positioned as illustrated in FIG. 10C so that the conductive layer 240b partly overlaps with the semiconductor layer 230b and the conductive layer 240c does not overlap with the semiconductor layer 230b in the cross-sectional view in the channel length direction.

The above is the description of the structure example of the transistor 200b.

Although FIGS. 1A to 1D illustrate the structure in which the channel length directions of the transistors 200a and 200b are parallel or substantially parallel to each other, the present invention is not limited thereto. For example, the channel length directions of the transistors 200a and 200b may intersect with each other. Specifically, the channel length directions of the transistors 200a and 200b may be orthogonal or substantially orthogonal to each other or obliquely intersect with each other.

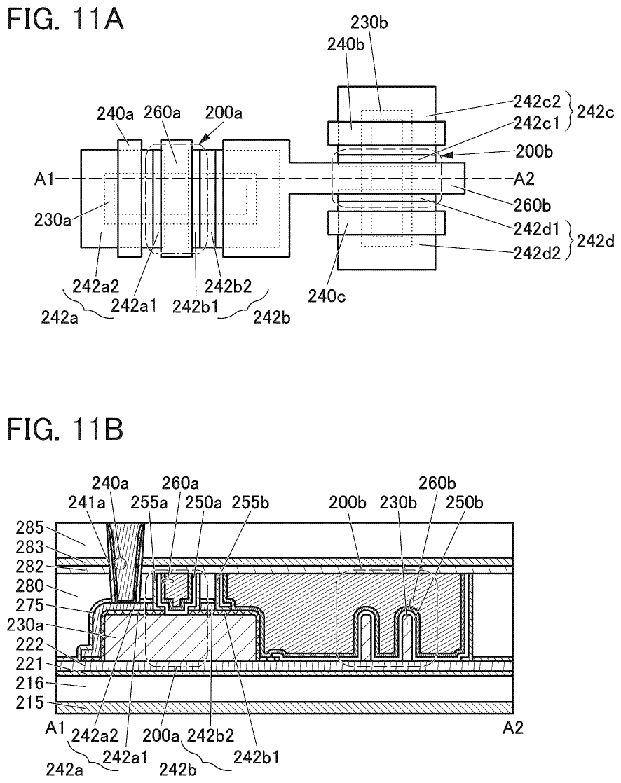

As illustrated in FIGS. 11A and 11B, the transistors 200a and 200b can be arranged such that their channel length directions are orthogonal to each other, for example. With such a structure, the conductive layer 260a can be provided to extend and function as a wiring. Thus, higher integration of the semiconductor device can be achieved. Furthermore, the degree of freedom of circuit design of the semiconductor device can be increased.

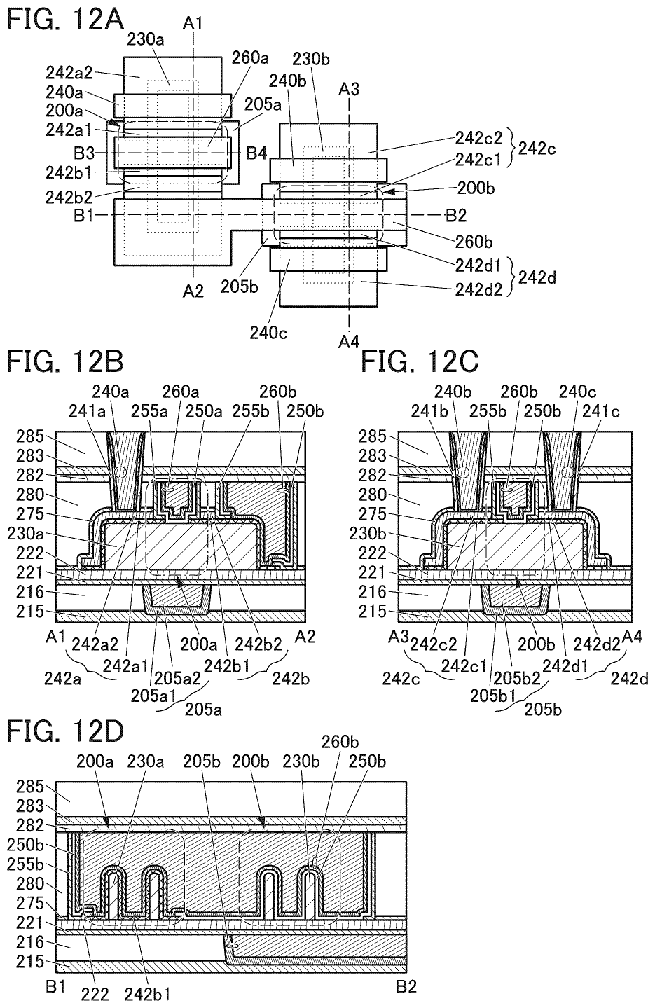

As illustrated in FIGS. 12A to 12D, a conductive layer 205a and a conductive layer 205b may be provided below the insulating layer 221 in the semiconductor device of this embodiment. The conductive layer 205a and the conductive layer 205b include regions functioning as second gate electrodes (lower gate electrodes) of the transistor 200a and the transistor 200b, respectively. The insulating layers 222 and 221 each include a region functioning as a second gate insulating layer of the transistor 200a and a region functioning as a second gate insulating layer of the transistor 200b. Note that the components above the insulating layer 221 in the semiconductor device illustrated in FIGS. 12A to 12D correspond to those in the semiconductor device illustrated in FIGS. 1A to 1D; thus, the above description can be referred to for the detailed structure.

In the transistor 200a, the conductive layer 205a is positioned to overlap with the semiconductor layer 230a and the conductive layer 260a. Here, the conductive layer 205a is preferably provided to fill an opening formed in the insulating layer 216. The conductive layer 205a can be provided to extend in the channel width direction. With such a structure, the conductive layer 205a functions as a wiring when a plurality of transistors are provided.

As illustrated in FIG. 12B, the conductive layer 205a preferably includes the conductive layers 205a1 and 205a2. The conductive layer 205a1 is provided in contact with the bottom surface and the sidewall of the opening. The conductive layer 205a2 is provided to fill a depressed portion formed by the conductive layer 205a1 formed along the opening. Here, the top surface of the conductive layer 205a is level or substantially level with the top surface of the insulating layer 216.

Here, the conductive layer 205a1 preferably includes a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom. Alternatively, the conductive layer 205a1 preferably includes a conductive material having a function of inhibiting diffusion of oxygen (e.g., at least one of an oxygen atom and an oxygen molecule).

When the conductive layer 205a1 is formed using a conductive material having a function of inhibiting diffusion of hydrogen, impurities such as hydrogen contained in the conductive layer 205a2 can be prevented from being diffused into the semiconductor layer 230a through the insulating layer 216 and the like. When a conductive material having a function of inhibiting oxygen diffusion is used for the conductive layer 205a1, a reduction in conductivity of the conductive layer 205a2 due to oxidation of the conductive layer 205a2 can be inhibited. Examples of the conductive material having a function of inhibiting diffusion of oxygen include titanium, titanium nitride, tantalum, tantalum nitride, ruthenium, and ruthenium oxide. The conductive layer 205a1 can have a single-layer structure or a stacked-layer structure of the above conductive material. For example, the conductive layer 205a1 preferably contains titanium nitride.

A conductive material containing tungsten, copper, or aluminum as its main component is preferably used for the conductive layer 205a2. For example, the conductive layer 205a2 preferably contains tungsten.

The conductive layer 205a can function as the second gate electrode. In that case, by changing a potential applied to the conductive layer 205a independently of a potential applied to the conductive layer 260a, the threshold voltage (Vth) of the transistor 200a can be controlled. In particular, by applying a negative potential (a potential lower than a source potential) to the conductive layer 205a, Vth of the transistor 200a can be higher, and its off-state current can be reduced. Thus, a drain current at the time when a potential applied to the conductive layer 260a is 0 V can be lower in the case where a negative potential is applied to the conductive layer 205a than in the case where the negative potential is not applied to the conductive layer 205a.

The electrical resistivity of the conductive layer 205a is designed in consideration of the potential applied to the conductive layer 205a, and the thickness of the conductive layer 205a is determined in accordance with the electrical resistivity. The thickness of the insulating layer 216 is substantially equal to that of the conductive layer 205a. The conductive layer 205a and the insulating layer 216 are preferably as thin as possible in the allowable range of the design of the conductive layer 205a. The insulating layer 216 with a reduced thickness contains a smaller absolute amount of impurities such as hydrogen, inhibiting the diffusion of the impurity into the semiconductor layer 230a.

Although the stacked-layer structure of the conductive layer 205a1 and the conductive layer 205a2 is described above, the present invention is not limited to this structure. The conductive layer 205a may have a single-layer structure or a stacked-layer structure of three or more layers. For example, in the case where the conductive layer 205a has a three-layer structure, a conductor that contains the same material as the conductive layer 205a1 can be further provided over the conductive layer 205a2 of the above-described stacked-layer structure of the conductive layers 205a1 and 205a2. In this case, the top surface of the conductive layer 205a2 is positioned lower than an uppermost portion of the conductive layer 205a1, and the conductor may be formed to fill the depressed portion formed by the conductive layers 205a1 and 205a2.

The description of the structure of the conductive layer 205a can be referred to for the description of the structure of the conductive layer 205b by replacing the conductive layer 205a (the conductive layers 205a1 and 205a2), the semiconductor layer 230a, and the conductive layer 260a with the conductive layer 205b (conductive layers 205b1 and 205b2), the semiconductor layer 230b, and the conductive layer 260b, respectively, and appropriately replacing words or sentences as necessary.

### <Structure Example 2 of Semiconductor Device>

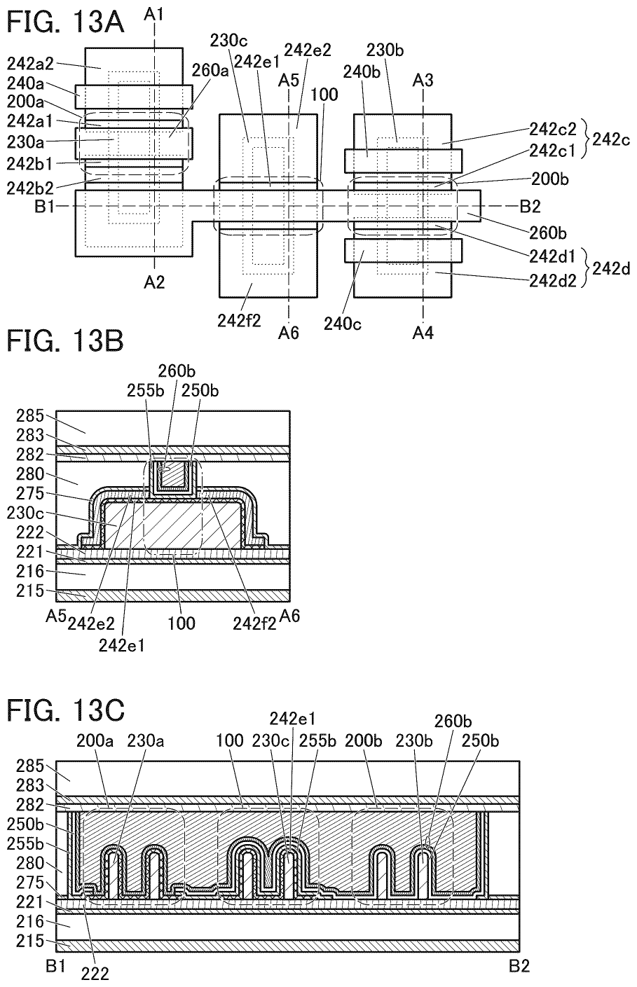

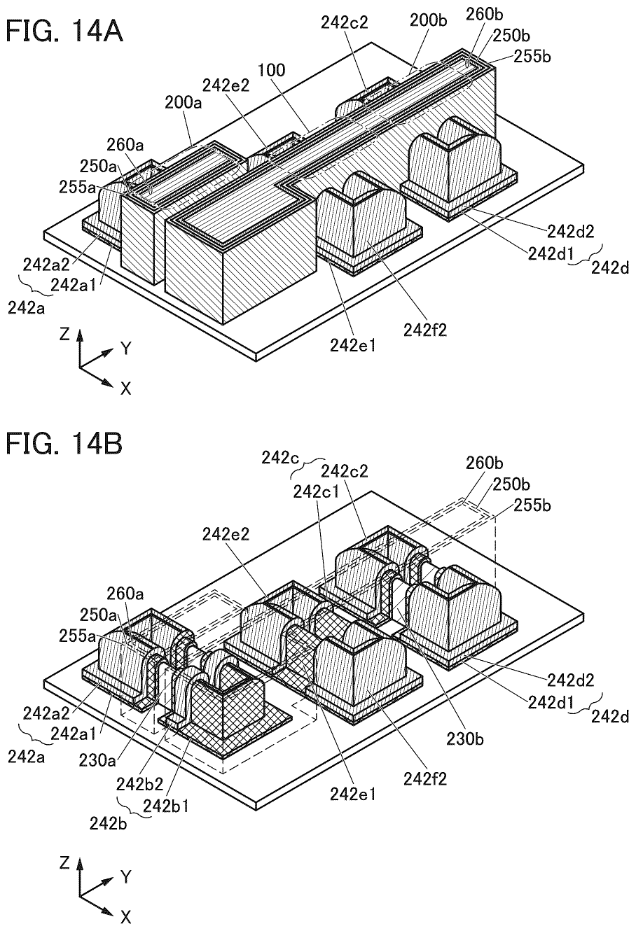

Another structure example of a semiconductor device is described with reference to FIGS. 13A to 13C and FIGS. 14A and 14B. FIGS. 13A to 13C are a plan view and cross-sectional views of a semiconductor device including a transistor over a substrate (not illustrated).

FIG. 13A is the plan view of the semiconductor device. FIGS. 13B and 13C are the cross-sectional views of the semiconductor device. Here, FIG. 13B is the cross-sectional view taken along the dashed-dotted line A1-A2 in FIG. 13A. FIG. 13C is the cross-sectional view taken along the dashed-dotted line B1-B2 in FIG. 13A. Here, the dashed-dotted line B1-B2 is orthogonal to the dashed-dotted line A1-A2. Note that for simplification, in the plan view in FIG. 13A, some components are not illustrated and some components are illustrated in a see-through manner.

FIGS. 14A and 14B are perspective views of the semiconductor device illustrated in FIGS. 13A to 13C. Note that for simplification, some components are not illustrated in the perspective views in FIGS. 14A and 14B. The X direction and the Y direction shown in FIGS. 14A and 14B are respectively parallel to the A1-A2 direction and the B1-B2 direction shown in FIGS. 13A to 13C. In FIG. 14B, the conductive layers 260a and 260b and the insulating layers 250a, 250b, 255a, and 255b are denoted by dashed lines.

The semiconductor device illustrated in FIGS. 13A to 13C includes a capacitor 100 in addition to the transistors 200a and 200b. The semiconductor device illustrated in FIGS. 13A to 13C is different from the semiconductor device illustrated in FIGS. 1A to 1D mainly in including the capacitor 100. Portions different from the description with reference to FIGS. 1A to 1D and the like are mainly described below, and common portions, for which the description is referred to, are not described in some cases.

The semiconductor device illustrated in FIGS. 13A to 13C includes the insulating layer 216 over a substrate (not illustrated); the insulating layer 221 over the insulating layer 216; the insulating layer 222 over the insulating layer 221; the transistor 200a, the transistor 200b, and a semiconductor layer 230c over the insulating layer 222; the capacitor 100 over the semiconductor layer 230c; the insulating layer 275; and the insulating layer 280. For the transistor 200a and the transistor 200b, the description of the transistor 200a and the transistor 200b illustrated in FIGS. 1A to 1D can be referred to.

The capacitor 100 includes a conductive layer 242e1 covering the semiconductor layer 230c, the insulating layer 255b over the conductive layer 242e1, the insulating layer 250b over the insulating layer 255b, and the conductive layer 260b over the insulating layer 250b. As illustrated in FIGS. 13A and 13B, the semiconductor layer 230c has a structure similar to those of the semiconductor layers 230a and 230b, and can be formed through the same process as those of the semiconductor layers 230a and 230b. The conductive layer 242e1 has a structure similar to those of a conductive layer (a conductive layer 242Q1 described later) to be the conductive layers 242a1 and 242b1 and a conductive layer (a conductive layer 242R1 described later) to be the conductive layers 242c1 and 242d1, and can be formed through the same process as those of the conductive layers. The insulating layers 255b and 250b are shared by the capacitor 100 and the transistor 200b, and the conductive layer 260b is shared by the capacitor 100 and the transistors 200a and 200b.

Here, the capacitor 100 includes the conductive layer 242e1 functioning as a first electrode (also referred to as a lower electrode), the conductive layer 260b functioning as a second electrode (also referred to as an upper electrode), and the insulating layers 255b and 250b functioning as dielectrics. That is, the capacitor 100 is a metal-insulator-metal (MIM) capacitor.

The capacitor 100 has a structure similar to that of the transistor 200b, and the capacitor 100 and the transistor 200b can be arranged in parallel in one layer.

As illustrated in FIG. 13B, the semiconductor layer 230c has a high aspect ratio like the semiconductor layers 230a and 230b, and a plurality of semiconductor layers can be provided. Thus, as in the semiconductor layers 230a and 230b, the height is larger than the width in the semiconductor layer 230c in the cross-sectional view in the channel width direction. In addition, like the semiconductor layers 230a and 230b, the semiconductor layer 230c overlaps with the conductive layer 260b in two or more regions in the top view. This structure can increase the area where the conductive layer 242e1 provided along the top and side surfaces of the semiconductor layer 230c faces the conductive layer 260b with the insulating layers 255b and 250b therebetween. Thus, the capacitor 100 can have large capacitance without very large occupied area.

With the above structure, the other of the source and the drain of the transistor 200a, one terminal of the capacitor 100, and the gate of the transistor 200b can be electrically connected to each other, whereby a memory cell formed of two transistors and one capacitor (also referred to as a 2TIC memory cell) can be formed. By not providing the transistor 200b, a memory cell formed of one transistor and one capacitor (also referred to as a 1TIC memory cell) can be formed.

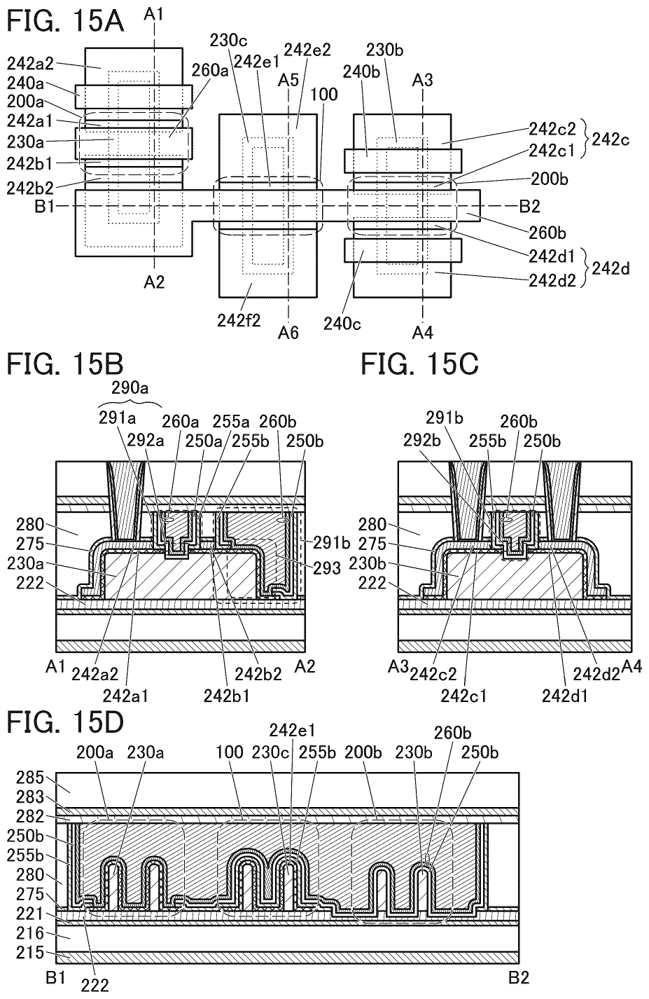

Note that in the semiconductor device of this embodiment, as illustrated in FIGS. 15A to 15D, the insulating layer 222 can be thin in a region not overlapping with the insulating layer 255a and the semiconductor layer 230a in the opening 291a and a region not overlapping with the insulating layer 255b and the semiconductor layer 230b in the opening 291b. In each of the above two regions, the insulating layer 222 of the semiconductor device of this embodiment can have a groove portion or an opening. With such a structure, the bottom surface of the conductive layer 260a can be positioned below the bottom surface of the semiconductor layer 230a in the groove portion or the opening in the insulating layer 222 in the region not overlapping with the insulating layer 255a and the semiconductor layer 230a in the opening 291a. Moreover, the bottom surface of the conductive layer 260b can be positioned below the bottom surface of the semiconductor layer 230b in the groove portion or the opening in the insulating layer 222 in the region not overlapping with the insulating layer 255b and the semiconductor layer 230b in the opening 291b.

The bottom surface of the conductive layer 260a is positioned below the bottom surface of the semiconductor layer 230a, whereby a gate electric field can be sufficiently applied from the upper end portion to the lower end portion of the semiconductor layer 230a. In other words, the entire semiconductor layer 230a can be electrically surrounded by the electric field of the conductive layer 260a in the opening in the insulating layer 280 and the like, and can function as a channel formation region. Such a structure prevents the lower end portion of the semiconductor layer 230a from functioning as a parasitic channel, leading to a reduction in leakage current between the source and drain electrodes. Furthermore, the transistor can be inhibited from having poor characteristics such as normally-on characteristics due to the parasitic channel. That is, the transistor 200a can have favorable electric characteristics.

When a region from the upper end portion to the lower end portion of the semiconductor layer 230a functions as a channel formation region as described above, the channel width can be increased. Accordingly, the transistor 200a can have favorable on-state current, mutual conductance, frequency characteristics, and the like.

Note that in this specification and the like, a transistor structure in which a channel formation region is electrically surrounded by the electric field of the gate electrode as described above is referred to as a surrounded channel (S-channel) structure. In the S-channel structure, a gate electrode is positioned to cover at least two surfaces (specifically, two surfaces, three surfaces, four surfaces, or the like) of a channel. With the use of the S-channel structure, a transistor with high resistance to a short-channel effect, i.e., a transistor in which a short-channel effect is less likely to occur, can be obtained.

Since the S-channel structure is a structure with the electrically surrounded channel formation region, the S-channel structure is, in a sense, equivalent to a gate all around (GAA) structure or a lateral gate all around (LGAA) structure. When the transistor 200a has any of the S-channel structure, the GAA structure, and the LGAA structure, the channel formation region formed at the interface between the semiconductor layer 230a and the gate insulator or in the vicinity thereof can correspond to the entire bulk in the semiconductor layer 230a. Consequently, the density of current flowing in the transistor can be improved, so that the on-state current or the field-effect mobility of the transistor can be expected to be increased. In one embodiment of the present invention, the semiconductor layer 230a has the CAAC structure and the fin-shaped structure. With such structures, the source-drain current path in the transistor and the a-b plane of the crystal axis can be parallel to each other. In other words, an oxide semiconductor having the CAAC structure and the fin-shaped structure seems to have a conduction path equivalent to that of a two-dimensional semiconductor material. Furthermore, with the use of such an oxide semiconductor, a device having two-dimensional conduction can be fabricated.

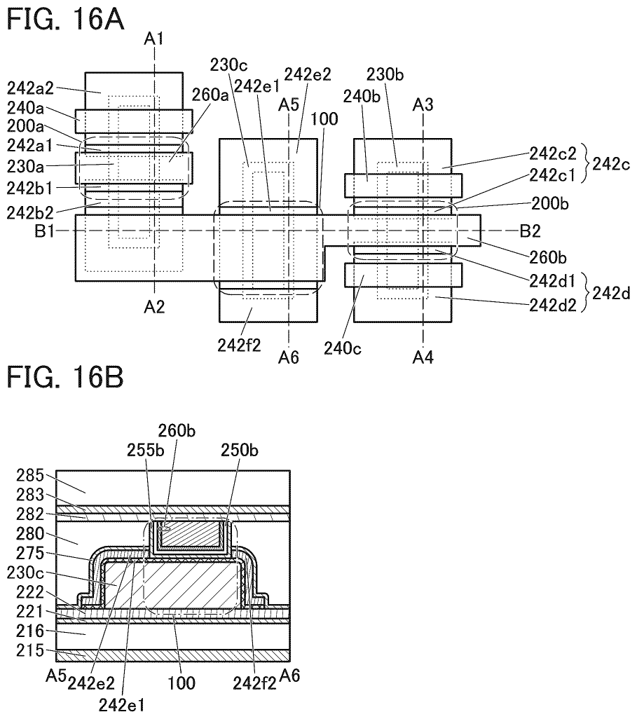

Although FIG. 13A illustrates the conductive layer 260b in which the width in the A5-A6 direction in a portion indicated by the dashed-dotted line A5-A6 is equal or substantially equal to the width in the A3-A4 direction in a portion indicated by the dashed-dotted line A3-A4, the present invention is not limited thereto. For example, as illustrated in FIG. 16A, the width of the conductive layer 260b may be larger in the A5-A6 direction in the portion indicated by the dashed-dotted line A5-A6 than in the A3-A4 direction in the portion indicated by the dashed-dotted line A3-A4. In the conductive layer 260b in FIGS. 16A and 16B, the width in the A5-A6 direction in the portion indicated by the dashed-dotted line A5-A6 is equal or substantially equal to the width in the A1-A2 direction in the portion indicated by the dashed-dotted line A1-A2. Such a structure can increase the area of a portion where the conductive layer 242e1 functioning as the first electrode of the capacitor 100 overlaps with the conductive layer 260b functioning as the second electrode of the capacitor 100 with the insulating layers 255b and 250b therebetween. Thus, the capacitor 100 can have large capacitance without very large occupied area.

### <Structure Example 3 of Semiconductor Device>

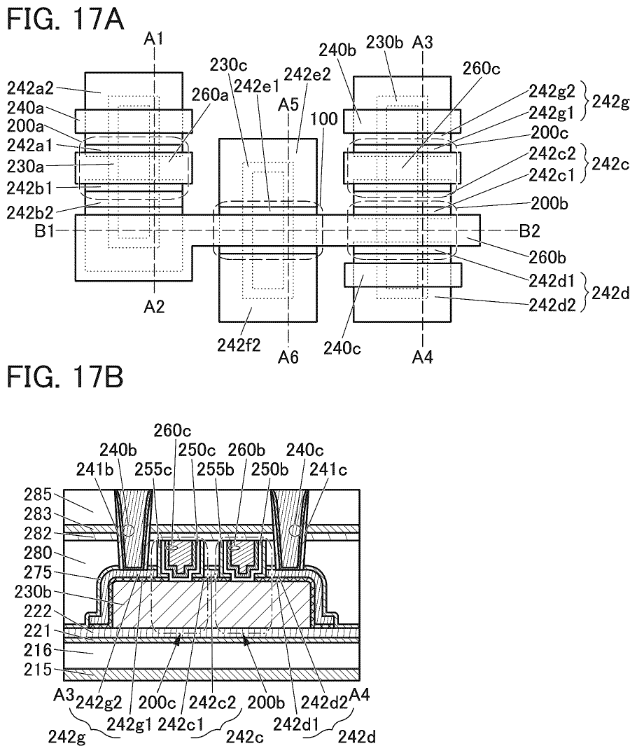

Another structure example of a semiconductor device is described with reference to FIGS. 17A and 17B. FIGS. 17A and 17B are a plan view and a cross-sectional view of a semiconductor device including a transistor over a substrate (not illustrated).

FIG. 17A is the plan view of the semiconductor device. FIG. 17B is the cross-sectional view of the semiconductor device. Here, FIG. 17B is the cross-sectional view taken along the dashed-dotted line A3-A4 in FIG. 17A. For simplification, in the plan view in FIG. 17A, some components are not illustrated and some components are illustrated in a see-through manner.

The semiconductor device illustrated in FIGS. 17A and 17B includes a transistor 200c in addition to the transistors 200a and 200b and the capacitor 100. The semiconductor device illustrated in FIGS. 17A and 17B is different from the semiconductor device illustrated in FIGS. 13A to 13C mainly in including the transistor 200c. In addition, the semiconductor device illustrated in FIGS. 17A and 17B is different from the semiconductor device illustrated in FIGS. 1A to 1D mainly in including the capacitor 100 and the transistor 200c. Portions different from the description with reference to FIGS. 1A to 1D, FIGS. 13A to 13C, and the like are mainly described below, and common portions, for which the description is referred to, are not described in some cases.

The semiconductor device illustrated in FIGS. 17A and 17B includes the insulating layer 216 over a substrate (not illustrated); the insulating layer 221 over the insulating layer 216; the insulating layer 222 over the insulating layer 221; the transistor 200a, the transistor 200b, the transistor 200c, and the semiconductor layer 230c over the insulating layer 222; the capacitor 100 over the semiconductor layer 230c; the insulating layer 275; and the insulating layer 280. For the transistor 200a and the transistor 200b, the description of the transistor 200a and the transistor 200b illustrated in FIGS. 1A to 1D can be referred to. For the capacitor 100, the description of the capacitor 100 illustrated in FIGS. 13A to 13C can be referred to.

The transistor 200c includes the semiconductor layer 230b, the conductive layer 242c and a conductive layer 242g over the semiconductor layer 230b and the insulating layer 222, an insulating layer 255c over the conductive layers 242c and 242g, an insulating layer 250c over the semiconductor layer 230b and the insulating layer 255c, and a conductive layer 260c over the insulating layer 250c. The conductive layer 242g includes a conductive layer 242g1 and a conductive layer 242g2 over the conductive layer 242g1. In FIG. 17B, the conductive layer 260c has a two-layer structure.

The semiconductor layer 230b includes a region functioning as a channel formation region of the transistor 200c. The conductive layer 260c includes a region functioning as a first gate electrode (an upper gate electrode) of the transistor 200c. The insulating layer 250c includes a region functioning as a first gate insulating layer of the transistor 200c. The conductive layer 242c includes a region functioning as one of a source electrode and a drain electrode of the transistor 200c. The conductive layer 242g includes a region functioning as the other of the source electrode and the drain electrode of the transistor 200c. FIG. 17B can also be referred to as a cross-sectional view of the transistor 200c in the channel length direction.

The transistors 200b and 200c are adjacent to each other and share the semiconductor layer 230b and the conductive layer 242c. Thus, two transistors (the transistors 200b and 200c) can be formed in an area smaller than the area of two transistors (e.g., the area of 1.5 transistors). Accordingly, transistors can be arranged at higher density than in the case where the transistors 200b and 200c do not share the semiconductor layer 230b and the conductive layer 242c, and thus the semiconductor device can be highly integrated.

With the above structure, the other of the source and the drain of the transistor 200a, one terminal of the capacitor 100, and the gate of the transistor 200b can be electrically connected to each other, and one of the source and the drain of the transistor 200b and one of the source and the drain of the transistor 200c are electrically connected to each other, whereby a memory cell formed of three transistors and one capacitor (also referred to as a 3TIC memory cell) can be formed.

### <Materials for Semiconductor Device>

Materials that can be used for the semiconductor device are described below. Note that the layers included in the semiconductor device may each have a single-layer structure or a stacked-layer structure.

### <<Substrate>>

As a substrate where the transistor is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon or germanium and a compound semiconductor substrate of silicon carbide, silicon germanium, gallium arsenide, indium phosphide, zinc oxide, or gallium oxide. Another example is a semiconductor substrate in which an insulator region is provided in the above semiconductor substrate, such as a silicon on insulator (SOI) substrate. Examples of the conductor substrate include a graphite substrate, a metal substrate, an alloy substrate, and a conductive resin substrate. Examples of the substrate include a substrate including a metal nitride, a substrate including a metal oxide, an insulator substrate provided with a conductor or a semiconductor, a semiconductor substrate provided with a conductor or an insulator, and a conductor substrate provided with a semiconductor or an insulator. Alternatively, these substrates provided with one or more kinds of elements may be used. Examples of the element provided over the substrate include a capacitor, a resistor, a switching element, a light-emitting element, and a memory element.

### <<Insulator>>

Examples of an insulator that can be used for each of the insulating layers (the insulating layers 215, 216, 221, 222, 223, 275, 280, 250, 255, 241, 282, 283, 285, and the like and insulating layers 287, 289, and the like described later) include an insulating oxide, an insulating nitride, an insulating oxynitride, an insulating nitride oxide, an insulating metal oxide, an insulating metal oxynitride, and an insulating metal nitride oxide.

With miniaturization and high integration of a transistor, for example, a problem such as generation of leakage current may arise because of a thin gate insulator. When a high-k material is used for the insulator functioning as a gate insulator, the voltage at the time of operation of the transistor can be reduced while the physical thickness is maintained. By contrast, when a material with a low dielectric constant is used for the insulator functioning as an interlayer film, parasitic capacitance generated between wirings can be reduced. Thus, a material can be selected depending on the function of an insulator.

Examples of the insulator having a high dielectric constant (also referred to as a high permittivity material or a high-k material) include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator having a low dielectric constant include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

A transistor including a metal oxide can have stable electrical characteristics when surrounded by an insulator having a function of inhibiting transmission of oxygen and impurities such as hydrogen. The insulator having a function of inhibiting transmission of oxygen and impurities such as hydrogen can have, for example, a single-layer structure or a stacked-layer structure including one or more of an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum. Specifically, as the insulator having a function of inhibiting transmission of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide or a metal nitride such as aluminum nitride, silicon nitride oxide, or silicon nitride can be used.

The insulator functioning as a gate insulator preferably includes a region containing oxygen that is released by heating. For example, silicon oxide or silicon oxynitride that includes a region containing oxygen that is released by heating is provided in contact with the semiconductor layer 230 to compensate for the oxygen vacancies in the semiconductor layer 230.

### <<Conductor>>

For the conductor that can be used for each of the conductive layers (the conductive layers 242, 260, 240, 205, and the like and a conductive layer 245 and the like described later), it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. Examples of the conductor include tantalum nitride, titanium nitride, tungsten, a nitride containing titanium and aluminum, a nitride containing tantalum and aluminum, ruthenium oxide, ruthenium nitride, an oxide containing strontium and ruthenium, and an oxide containing lanthanum and nickel. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even when absorbing oxygen. Alternatively, a semiconductor having high conductivity, typified by polycrystalline silicon containing an impurity element such as phosphorus, or silicide such as nickel silicide may be used.

In the case where a stacked-layer structure of conductors is used, for example, a stacked-layer structure combining a material containing any of the metal elements and a conductive material containing oxygen, a stacked-layer structure combining a material containing any of the metal elements and a conductive material containing nitrogen, or a stacked-layer structure combining a material containing any of the metal elements, a conductive material containing oxygen, and a conductive material containing nitrogen may be employed.

When an oxide is used for the channel formation region of the transistor, the conductor functioning as the gate electrode preferably has a stacked-layer structure combining a material containing any of the above metal elements and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in a metal oxide in which the channel is formed. A conductive material containing any of the above metal elements and nitrogen may also be used. For example, a conductive material containing nitrogen, such as titanium nitride or tantalum nitride, may be used. One or more of an indium tin oxide, an indium oxide containing tungsten oxide, an indium zinc oxide containing tungsten oxide, an indium oxide containing titanium oxide, an indium tin oxide containing titanium oxide, an indium zinc oxide, and an indium tin oxide to which silicon is added may be used. An indium gallium zinc oxide containing nitrogen may be used. With use of such a material, hydrogen contained in the metal oxide in which the channel is formed can be captured in some cases. Hydrogen entered from a surrounding insulator or the like can also be captured in some cases.

### <Example of Method for Manufacturing Semiconductor Device>

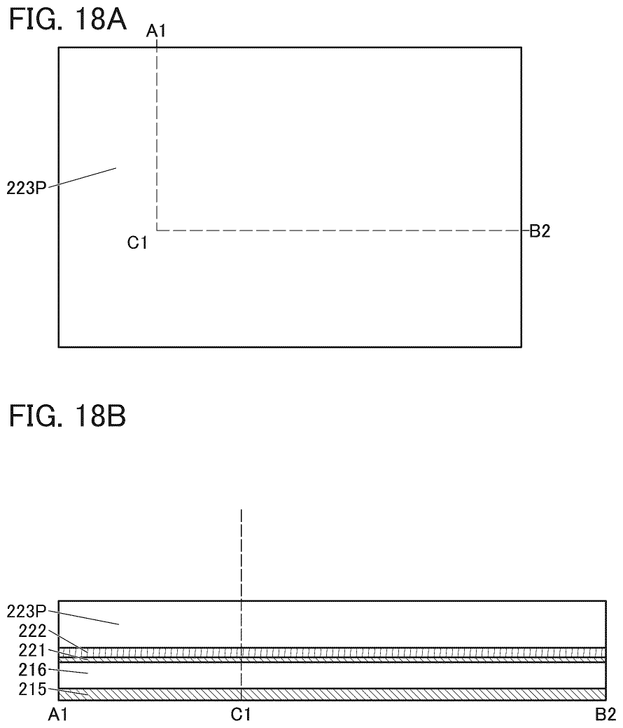

An example of a method for manufacturing the semiconductor device of one embodiment of the present invention is described with reference to FIGS. 18A and 18B to FIGS. 34A and 34B. Here, the case of manufacturing the semiconductor device illustrated in FIGS. 13A to 13C is described as an example.

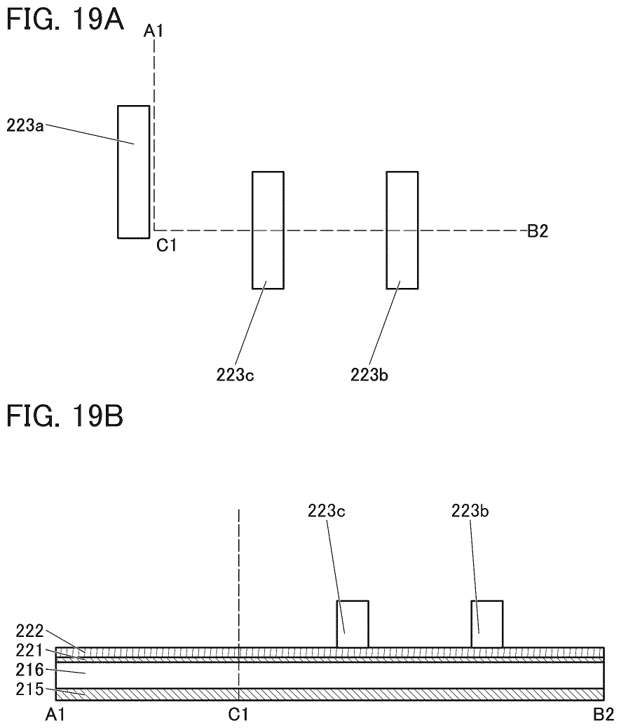

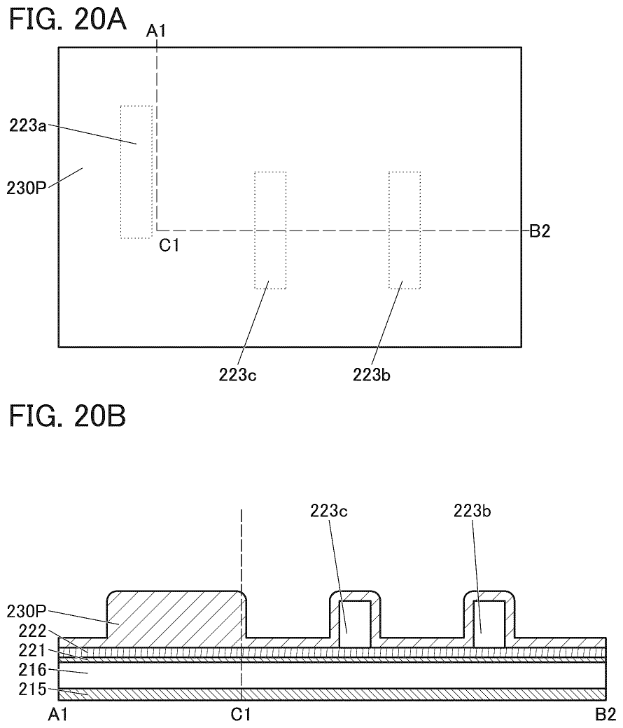

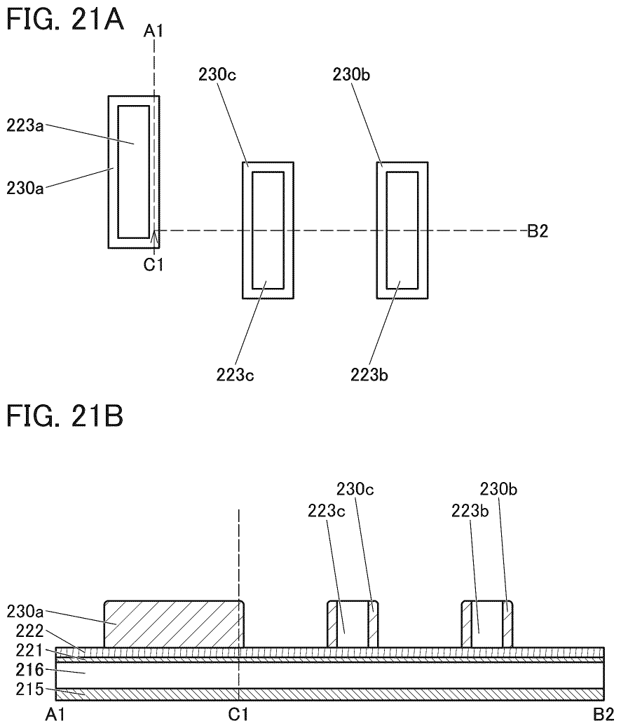

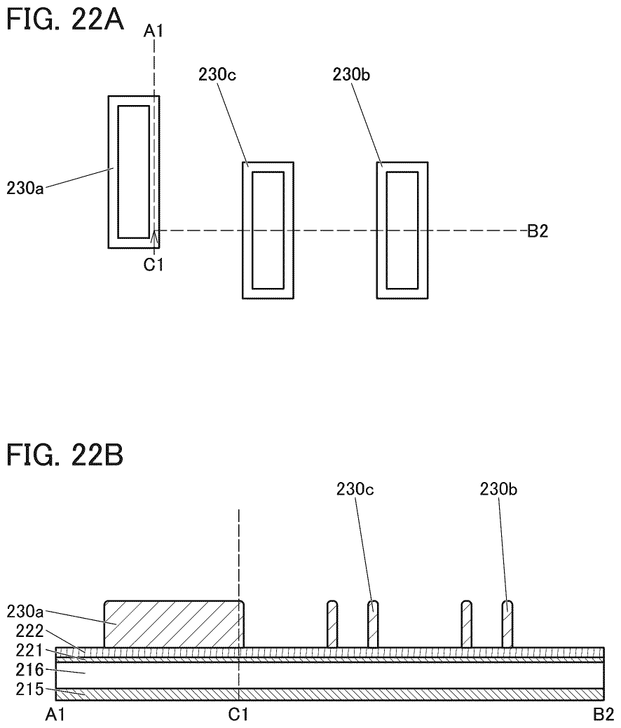

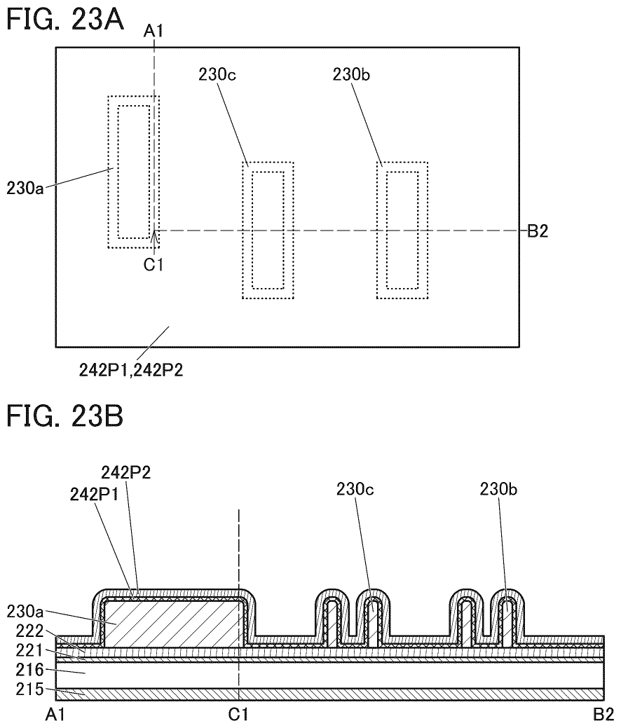

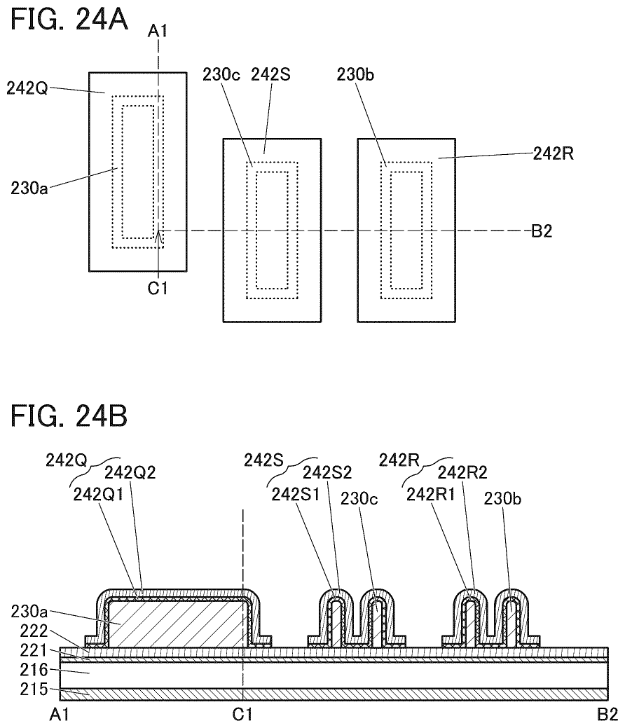

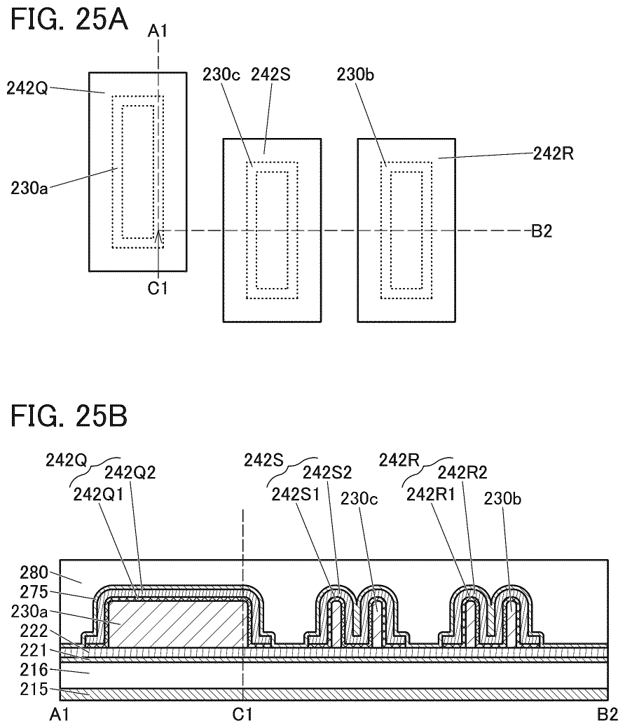

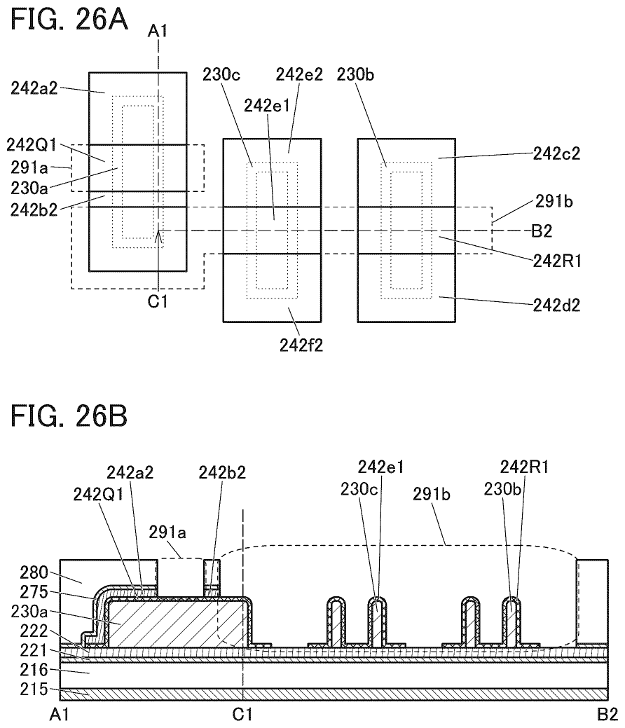

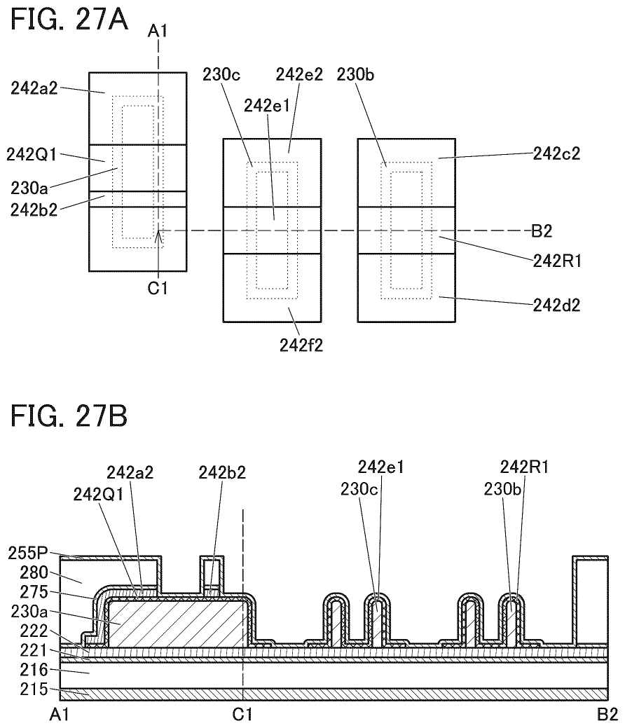

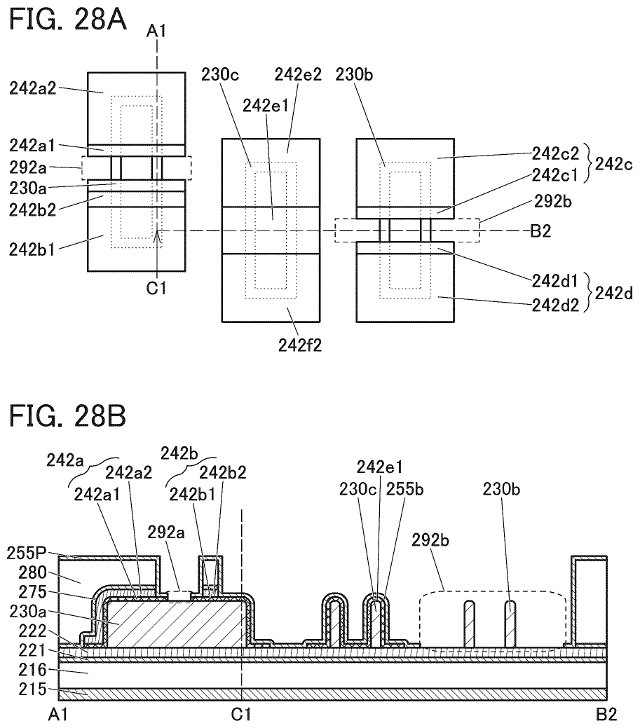

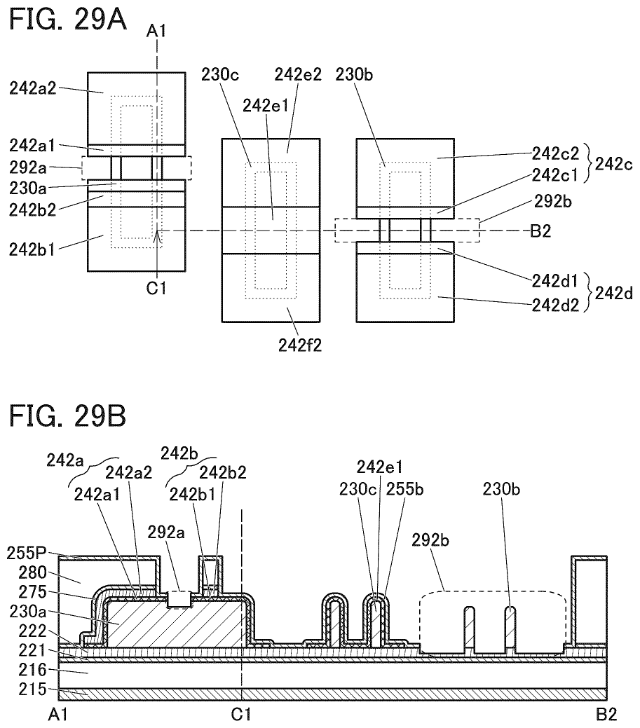

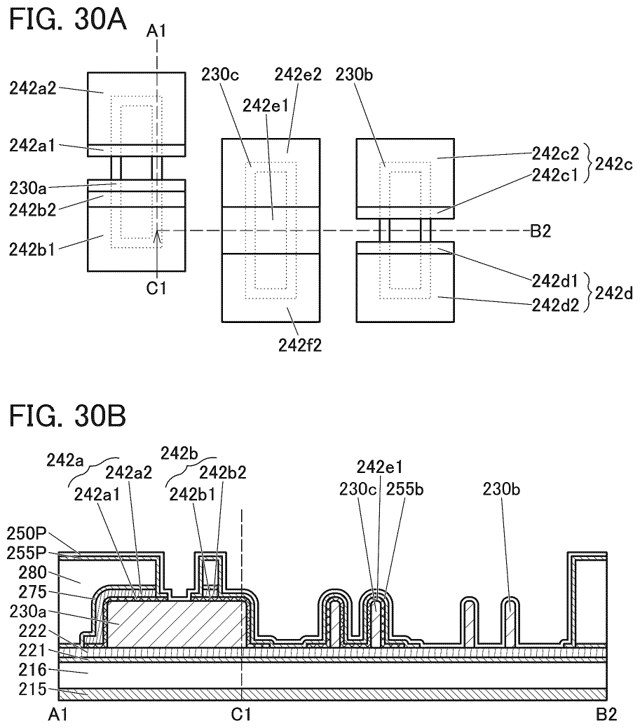

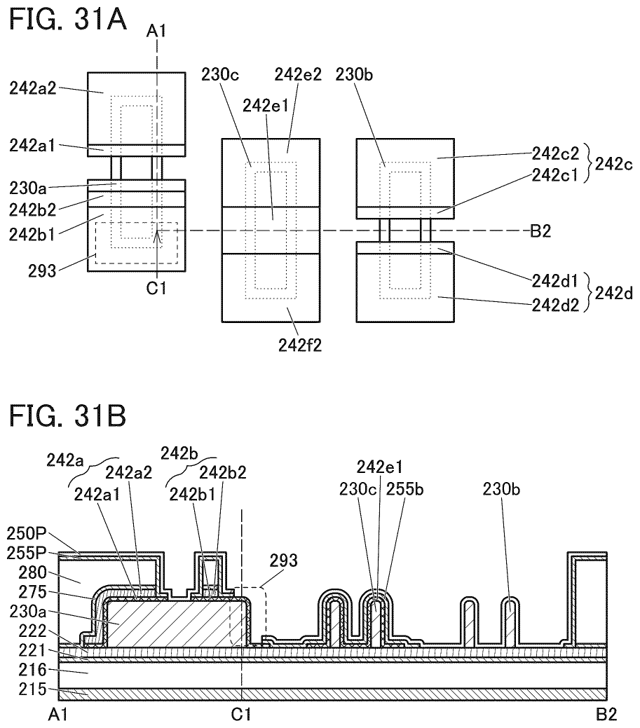

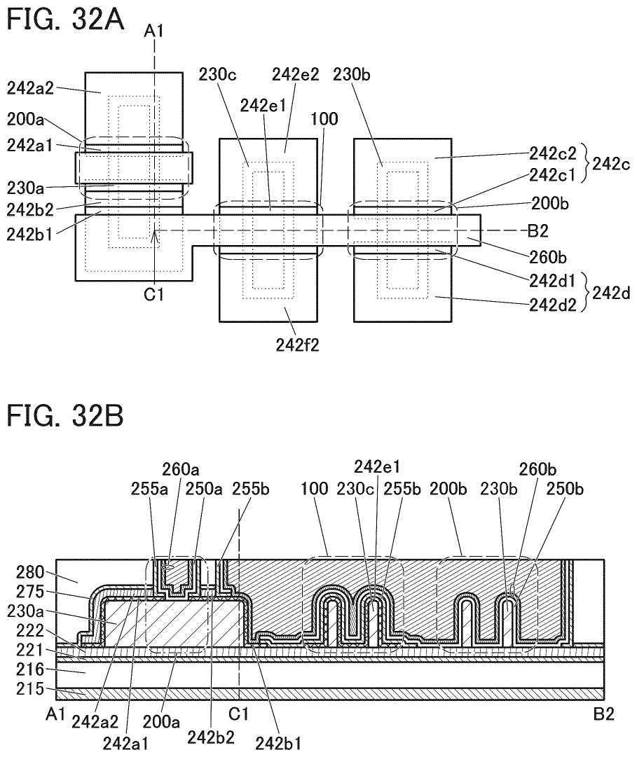

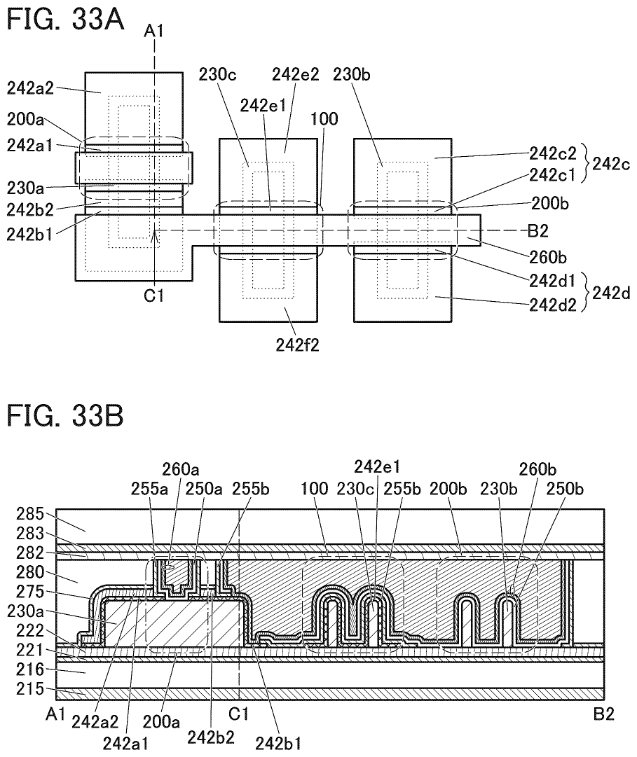

FIG. 18A, FIG. 19A, FIG. 20A, FIG. 21A, FIG. 22A, FIG. 23A, FIG. 24A, FIG. 25A, FIG. 26A, FIG. 27A, FIG. 28A, FIG. 29A, FIG. 30A, FIG. 31A, FIG. 32A, and FIG. 33A are plan views. FIG. 18B, FIG. 19B, FIG. 20B, FIG. 21B, FIG. 22B, FIG. 23B, FIG. 24B, FIG. 25B, FIG. 26B, FIG. 27B, FIG. 28B, FIG. 29B, FIG. 30B, FIG. 31B, FIG. 32B, and FIG. 33B are cross-sectional views taken along the dashed-dotted lines A1-C1-B2 in FIG. 18A, FIG. 19A, FIG. 20A,

FIG. 21A, FIG. 22A, FIG. 23A, FIG. 24A, FIG. 25A, FIG. 26A, FIG. 27A, FIG. 28A, FIG. 29A, FIG. 30A, FIG. 31A, FIG. 32A, and FIG. 33A. For simplification, some components are not illustrated in the plan views in FIG. 18A, FIG. 19A, FIG. 20A, FIG. 21A, FIG. 22A, FIG. 23A, FIG. 24A, FIG. 25A, FIG. 26A, FIG. 27A, FIG. 28A, FIG. 29A, FIG. 30A, FIG. 31A, FIG. 32A, and FIG. 33A.

In the following steps, an insulating material for forming an insulating layer, a conductive material for forming a conductive layer, or a semiconductor material for forming a semiconductor layer can be formed by a sputtering method, a CVD method, an MBE method, a PLD method, an ALD method, or the like as appropriate.

Examples of the sputtering method include an RF sputtering method using a high-frequency power source for a sputtering power source, a DC sputtering method using a DC power source, and a pulsed DC sputtering method in which a voltage applied to an electrode is changed in a pulsed manner. The RF sputtering method is mainly used for forming an insulating film, and the DC sputtering method is mainly used for forming a metal conductive film. The pulsed DC sputtering method is mainly used for forming a compound such as an oxide, a nitride, or a carbide by a reactive sputtering method.

Note that CVD methods can be classified into a PECVD method, a TCVD method, a photo CVD method, and the like. Moreover, CVD methods can be classified into a metal CVD (MCVD) method and an MOCVD method according to a source gas.

A high-quality film can be obtained at a relatively low temperature through a PECVD method. A TCVD method does not use plasma and thus causes less plasma damage to an object. For example, a wiring, an electrode, an element (e.g., a transistor or a capacitor), or the like included in a semiconductor device may be charged up by receiving charge from plasma. In that case, accumulated charge may break the wiring, electrode, element, or the like included in the semiconductor device. A TCVD method, which does not use plasma, does not cause such plasma damage, and thus can increase the yield of the semiconductor device. A TCVD method yields a film with few defects because of no plasma damage during film formation.

As the ALD method, a thermal ALD method, in which a precursor and a reactant react with each other only by a thermal energy, a PEALD method, in which a reactant excited by plasma is used, and the like can be used.

Methods of CVD and ALD differ from a sputtering method by which particles ejected from a target or the like are deposited. Thus, a CVD method and an ALD method can provide good step coverage, almost regardless of the shape of an object. In particular, an ALD method allows excellent step coverage and excellent thickness uniformity and can be suitably used to cover a surface of an opening with a high aspect ratio, for example. Note that an ALD method has a relatively low film formation rate; hence, in some cases, an ALD method is preferably combined with another film formation method with a high film formation rate, such as a CVD method.

By a CVD method, a film with a desired composition can be formed by adjusting the flow rate ratio of the source gases. For example, a CVD method enables a film with a gradually-changed composition to be formed by changing the flow rate ratio of the source gases during film formation. In the case where a film is formed while the flow rate ratio of the source gases is changed, as compared to the case where a film is formed using a plurality of film formation chambers, the time taken for the film formation can be shortened because the time taken for transfer and pressure adjustment is omitted. Hence, the productivity of the semiconductor device can be improved in some cases.

An ALD method, with which a plurality of different kinds of precursors are introduced at a time, enables formation of a film with desired composition. In the case where a plurality of different kinds of precursors are introduced, the cycle number of precursor deposition is controlled, whereby a film with desired composition can be formed.

First, a substrate (not illustrated) is prepared, and the insulating layer 215 is formed over the substrate (see FIGS. 18A and 18B). As described above, the insulating layer 215 can be formed with the same insulating layer as either the insulating layer 282 or the insulating layer 283 or a stacked film including both of them. The insulating layer 215 can be formed, for example, by a sputtering method, a CVD method, an MBE method, a PLD method, or an ALD method. A sputtering method which does not need to use a molecule containing hydrogen as a film formation gas is preferably used, in which case the hydrogen concentration in the insulating layer 215 can be reduced.

Next, the insulating layer 216 is formed over the insulating layer 215. The insulating layer 216 is preferably formed by a sputtering method. Since a molecule containing hydrogen is not used as a film formation gas in the sputtering method, the concentration of hydrogen in the insulating layer 216 can be reduced. Note that the insulating layer 216 can be formed by a CVD method, an MBE method, a PLD method, an ALD method, or the like as well as the sputtering method. In this embodiment, silicon oxide is formed as the insulating layer 216 by a sputtering method.

The insulating layers 215 and 216 are preferably formed successively without exposure to the air. For example, a multi-chamber film formation apparatus is used. As a result, the amount of hydrogen in the formed insulating layers 215 and 216 can be reduced, and furthermore, entry of hydrogen in the films between film formation steps can be inhibited.

Here, by forming a first opening and a second opening, which reach the insulating layer 215, in the insulating layer 216 and forming the conductive layer 205a and the conductive layer 205b in the first opening and the second opening, respectively, the transistor 200a and the transistor 200b illustrated in FIGS. 12A to 12D can be formed. The conductive layers 205a and 205b are formed in such a manner that a conductive film that can be used as the conductive layers 205a and 205b is formed to fill the first and second openings, and the conductive film is partly removed by CMP treatment.

Next, the insulating layer 221 is formed over the insulating layer 216 (see FIGS. 18A and 18B).

An insulator having a barrier property against oxygen, hydrogen, and water is used for the insulating layer 221. The insulating layer 221 can be formed by a sputtering method, a CVD method, an MBE method, a PLD method, or an ALD method, for example. In this embodiment, silicon nitride is formed as the insulating layer 221 by a PEALD method.

Next, the insulating layer 222 is formed over the insulating layer 221 (see FIGS. 18A and 18B).

As the insulating layer 222, an insulator containing an oxide of one or both of aluminum and hafnium is preferably formed. Note that as the insulator containing an oxide of one or both of aluminum and hafnium, aluminum oxide, hafnium oxide, or an oxide containing aluminum and hafnium (hafnium aluminate) is preferably used, for example. Alternatively, a hafnium zirconium oxide is preferably used. The insulator containing an oxide of one or both of aluminum and hafnium has a barrier property against oxygen, hydrogen, and water. When the insulating layer 222 has a barrier property against hydrogen and water, diffusion of hydrogen and water contained in a structure body provided around the transistor into the transistor through the insulating layer 222 is inhibited, and accordingly oxygen vacancies are less likely to be generated in the semiconductor layer 230.

The insulating layer 222 can be formed by, for example, a sputtering method, a CVD method, an MBE method, a PLD method, or an ALD method. In this embodiment, hafnium oxide is formed as the insulating layer 222 by a thermal ALD method.

In this embodiment, silicon nitride is formed as the insulating layer 221 by a PEALD method, and hafnium oxide is formed as the insulating layer 222 by a thermal ALD method. When silicon nitride having a function of inhibiting diffusion of hydrogen is used for the insulating layer 221 in this manner, diffusion of hydrogen from a layer below the transistor 200a, the transistor 200b, and the like can be inhibited. Furthermore, when hafnium oxide having a function of capturing or fixing hydrogen is used for the insulating layer 222, hydrogen contained in the semiconductor layer 230 can be captured or fixed by the insulating layer 222. This can reduce the hydrogen concentration in the semiconductor layer 230 and in the vicinity thereof.

Next, an insulating film 223P is formed over the insulating layer 222 (FIGS. 18A and 18B). For the insulating film 223P, an insulator that can be used for the insulating layer 216 is used, for example. The insulating film 223P can be formed by a sputtering method, a CVD method, an MBE method, a PLD method, or an ALD method, for example. In this embodiment, silicon oxide is formed as the insulating film 223P by a sputtering method.

Next, the insulating film 223P is etched to form the insulating layer 223a, an insulating layer 223b, and an insulating layer 223c (see FIGS. 19A and 19B). The insulating layers 223a to 223c function as a template for forming the semiconductor layer 230.

In this specification and the like, when a plurality of components denoted by the same reference numerals need to be distinguished from each other, identification signs such as “_1”, “[n]”, and “[m,n]” are sometimes added to the reference numerals. In this specification and the like, when a plurality of components do not need to be distinguished from each other, no identification sign is added in some cases. For example, when the insulating layers 223a to 223c do not need to be distinguished from each other, they are simply referred to as an “insulating layer 223” in some cases. In this specification and the like, an identification sign is not used for describing a given component in some cases. For example, a given insulating layer 223 is simply referred to as an “insulating layer 223” in some cases. The same applies to the transistor 200, the semiconductor layer 230, the insulating layers 241, 250, and 255, the conductive layers 205, 240, 242, 245, and 260, the openings 290, 291, and 292, and the like.

The insulating layer 223 can be processed into an island shape by a lithography method. The processing can be performed by a dry etching method or a wet etching method. A dry etching method is suitable for microfabrication. In this embodiment, as illustrated in FIGS. 19A and 19B, three pillar-shaped insulating layers 223 (the insulating layers 223a to 223c) are formed to be arranged in the C1-B2 direction.

As illustrated in FIG. 19B, the insulating layer 223 may have a side surface that is perpendicular or substantially perpendicular to the top surface of the insulating layer 222. With such a structure, a plurality of transistors can be provided with high density in a small area.

Next, a semiconductor film 230P is formed to cover the insulating layer 223 (see FIGS. 20A and 20B). The semiconductor film 230P is a metal oxide film to be the semiconductor layer 230 in a later step, and the above metal oxide film can be used. The semiconductor film 230P can be formed by a sputtering method, a CVD method, an MBE method, a PLD method, or an ALD method.

The semiconductor film 230P preferably has good coverage because the semiconductor film 230P is formed along the insulating layer 223. Accordingly, the semiconductor film 230P is preferably formed by an ALD method or the like, which provides good coverage. Since the semiconductor layer 230 preferably has a high aspect ratio, the semiconductor film 230P is preferably thin. Thus, the semiconductor film 230P is preferably formed by an ALD method enabling adjustment of a small thickness. The semiconductor film 230P formed in such a manner is in contact with the top and side surfaces of the insulating layer 223.

Here, the semiconductor film 230P is preferably formed by the same method as the oxide semiconductor layer 30 described in [Formation method of oxide semiconductor layer]. When the semiconductor film 230P is formed in this manner, the semiconductor film 230P is formed parallel or substantially parallel to the formation surface.

In the case where the semiconductor layer 230a has a three-layer structure of the semiconductor layers 230a1 to 230a3 as illustrated in FIG. 3B and the like, for example, a film to be the semiconductor layer 230a1 and a film to be the semiconductor layer 230a3 can be formed by an ALD method, and a film to be the semiconductor layer 230a2 can be formed by a sputtering method. Specifically, the film to be the semiconductor layer 230a1 can be formed to have a composition of In:Zn=2:1 [atomic ratio] or in the neighborhood thereof. Alternatively, indium oxide may be used for the film to be the semiconductor layer 230a1. The film to be the semiconductor layer 230a2 can be formed using an oxide target having a composition of In:Sn:Zn=4:0.1:1 [atomic ratio] or in the neighborhood thereof. The film to be the semiconductor layer 230a3 can be formed to have a composition of In:Zn=2:1 [atomic ratio] or in the neighborhood thereof. Alternatively, indium oxide may be used for the film to be the semiconductor layer 230a3.

Next, heat treatment is preferably performed. The heat treatment is preferably performed in a temperature range where the semiconductor film 230P does not become polycrystal. The heat treatment for the semiconductor film 230P is performed by the same method as the heat treatment for the oxide semiconductor layer 30 described in [Formation method of oxide semiconductor layer].

For example, heat treatment can be performed at 450° C. for one hour at a flow rate ratio of a nitrogen gas to an oxygen gas of 4:1.

When the semiconductor film 230P is formed by the above-described method and heat treatment is performed, the semiconductor film 230P to be the semiconductor layer 230 can be the AG CAAC. Accordingly, the on-state current, the S value, the field-effect mobility, the frequency characteristics, and the like of the transistor 200 can be improved, so that a semiconductor device having favorable electrical characteristics can be provided. Moreover, a highly reliable semiconductor device can be provided.

The heat treatment is preferably performed in a nitrogen gas atmosphere, an inert gas atmosphere, or an atmosphere containing an oxidizing gas at 10 ppm or more, 1% or more, or 10% or more. The heat treatment may be performed under a reduced pressure. Alternatively, the heat treatment may be performed in such a manner that heat treatment is performed in an atmosphere of a nitrogen gas or an inert gas, and then another heat treatment is performed in an atmosphere containing an oxidizing gas at 10 ppm or more, 1% or more, or 10% or more in order to compensate for released oxygen.

The gas used in the above heat treatment is preferably highly purified. The amount of moisture contained in the gas used in the above heat treatment is preferably 1 ppb or less, further preferably 0.1 ppb or less, still further preferably 0.05 ppb or less. The heat treatment using a highly purified gas can prevent entry of moisture or the like into the semiconductor film 230P and the like as much as possible. Note that a highly purified gas can also be used in heat treatment before this step and heat treatment after this step.

With the heat treatment using the above-described oxygen gas, impurities such as carbon, hydrogen, and water in the semiconductor film 230P can be reduced. Impurities in the film are reduced in the above manner, whereby the crystallinity of the semiconductor film 230P can be improved and a dense structure can be obtained. Accordingly, the crystal region in the semiconductor film 230P can be increased, and in-plane variation in a crystal region in the semiconductor film 230P can be reduced. Thus, in-plane variation in electrical characteristics of the transistor can be reduced.

The heat treatment can supply oxygen to the semiconductor film 230P to reduce oxygen vacancies in the semiconductor film 230P. Thus, the reliability of the transistor 200 can be improved.

By the heat treatment, hydrogen contained in the semiconductor film 230P is transferred to the insulating layer 222 and is absorbed thereinto. In other words, hydrogen contained in the semiconductor film 230P is diffused into the insulating layer 222. Accordingly, the hydrogen concentration in the insulating layer 222 increases, whereas the hydrogen concentration in the semiconductor film 230P decreases. Note that the insulating layer 221 is provided in contact with the bottom surface of the insulating layer 222, whereby entry of moisture or impurities such as hydrogen from the component below the insulating layer 221, which is caused by the heat treatment, can be prevented.

Specifically, the semiconductor film 230P (to be the semiconductor layers 230a and 230b later) functions as the channel formation regions of the transistors 200a and 200b. The transistors 200a and 200b formed using the semiconductor film 230P with a reduced hydrogen concentration are preferable because of their favorable reliability.

Note that treatment for increasing the crystallinity of the semiconductor film 230P is preferably performed during or after the formation of the semiconductor film 230P. Examples of the treatment for increasing the crystallinity of the semiconductor film 230P include heat treatment, plasma treatment, microwave (typically, 2.45 GHZ) treatment, microwave plasma treatment, and light (e.g., ultraviolet light) irradiation treatment. Some of these treatments may be performed concurrently or sequentially. For example, heat treatment and microwave plasma treatment can be performed concurrently. Alternatively, microwave plasma treatment can be performed after heat treatment.

It is further preferable that the treatment for increasing the crystallinity of the semiconductor film 230P be performed a plurality of times during the formation of the semiconductor film 230P. For example, in the case where the semiconductor film 230P is formed by an ALD method, microwave plasma treatment is preferably performed every time an atomic layer is formed. Alternatively, the treatment for increasing crystallinity is preferably performed every time the semiconductor film 230P with a thickness in a predetermined range is formed, in which case the productivity can be increased. Specifically, the semiconductor film 230P is preferably formed in such a manner that a first oxide semiconductor film with a thickness greater than or equal to 1 nm and less than or equal to 10 nm is formed, first microwave plasma treatment is performed, a second oxide semiconductor film with a thickness greater than or equal to 1 nm and less than or equal to 10 nm is formed, and then second microwave plasma treatment is performed. Note that methods for forming the first oxide semiconductor film and the second oxide semiconductor film are not particularly limited, and are each an ALD method or a sputtering method. It is particularly preferable to form the first oxide semiconductor film by an ALD method, in which case entry (also referred to as mixing) of an element of a formation surface of the first oxide semiconductor film to the first and second oxide semiconductor films can be prevented. Forming the first oxide semiconductor film by an ALD method is particularly preferable in the case where the element contained in a formation surface of the first oxide semiconductor film is formed hinders crystallization of an oxide semiconductor (e.g., the case where silicon, carbon, or the like is contained in the layer). The first oxide semiconductor film and the second oxide semiconductor film may have different compositions. Although the stacked-layer structure of the first oxide semiconductor film and the second oxide semiconductor film is exemplified here, one embodiment of the present invention is not limited thereto. Treatment similar to the above can be performed on the semiconductor film 230P having a single-layer structure or a stacked-layer structure of three or more layers.

The treatment for increasing the crystallinity of the semiconductor film 230P may be performed after the formation of the semiconductor film 230P. Specifically, after the formation of the semiconductor film 230P, the treatment may be performed directly on the semiconductor film 230P, or may be performed on the semiconductor film 230P through another film such as an insulating film formed over the semiconductor film 230P. For example, microwave plasma treatment may be performed directly on the semiconductor film 230P after the formation of the semiconductor film 230P; alternatively, an insulating film (e.g., a silicon nitride film, a silicon oxide film, or an aluminum oxide film) may be formed after the formation of the semiconductor film 230P, and then heat treatment or microwave plasma treatment may be performed on the semiconductor film 230P through the insulating film.

Note that the treatment for increasing the crystallinity of the semiconductor film 230P can also serve as treatment for removing impurities contained in the semiconductor film 230P. For example, carbon, hydrogen, nitrogen, and the like contained in the semiconductor film 230P can be favorably removed. Alternatively, by performing the treatment for increasing the crystallinity of the semiconductor film 230P in an oxygen gas atmosphere, oxygen vacancies in the semiconductor film 230P can be reduced.

During the treatment for increasing the crystallinity of the semiconductor film 230P, the substrate temperature is preferably higher than or equal to room temperature (e.g., higher than or equal to 25° C.), higher than or equal to 100° C. and lower than or equal to 600° C., or higher than or equal to 300° C. and lower than or equal to 450° C. The temperature of the heat treatment is preferably higher than or equal to 100° C. and lower than or equal to 700° C., or higher than or equal to 300° C. and lower than or equal to 450° C.

By increasing the crystallinity of the semiconductor film 230P, a highly reliable transistor can be obtained.

Next, the semiconductor film 230P is partly removed by anisotropic etching, whereby the semiconductor layers 230a to 230c are formed (see FIGS. 21A and 21B). A portion of the semiconductor film 230P that is parallel to the substrate surface is mainly etched, so that the sidewall-shaped semiconductor layer 230 is formed in contact with the side surface of the insulating layer 223. Although FIG. 22B illustrates the structure in which both the A1 side and the B2 side of the upper portion of the semiconductor layer 230 are curved, one embodiment of the present invention is not limited thereto. Only the side of the semiconductor layer 230 that is not in contact with the insulating layer 223 may be curved. Note that when the semiconductor film 230P is partly removed by anisotropic etching, part of the semiconductor film 230P may be provided with an insulator to be a hard mask. For the insulating film, silicon oxide, silicon nitride, silicon oxynitride, silicon nitride oxide, or the like can be suitably used.

By the anisotropic etching, the semiconductor layer 230 having a high aspect ratio can be formed. With the semiconductor layer 230, the transistor 200 can have a large channel width without a large occupied area, and thus can have favorable on-state current and frequency characteristics. Moreover, the contact area between the semiconductor layer 230 and the conductive layer 242 can be increased without increasing the area occupied by the transistor 200, and thus the transistor 200 can have favorable on-state current and frequency characteristics. When the semiconductor layer 230 is formed in this manner, the semiconductor layer 230 is formed parallel or substantially parallel to the formation surface.

The anisotropic etching of the semiconductor film 230P is preferably performed by a dry etching method.

An etching gas containing halogen can be used as a dry etching gas; specifically, an etching gas containing one or more of fluorine, chlorine, and bromine can be used. For example, as the etching gas, a C₄F₆ gas, a C₅F₆ gas, a C₄F₈ gas, a CF₄ gas, a SF₆ gas, a CHF₃ gas, a CH₂F₂ gas, a Cl₂ gas, a BCl₃ gas, a SiCl₄ gas, a BBr₃ gas, or the like can be used alone or in combination. To the above etching gas, an oxygen gas, a carbon dioxide gas, a nitrogen gas, a helium gas, an argon gas, a hydrogen gas, a hydrocarbon gas, or the like can be added as appropriate. Depending on an object to be subjected to the dry etching, a gas containing a hydrocarbon gas or a hydrogen gas and not containing a halogen gas can be used as the etching gas. As the hydrocarbon used for the etching gas, one or more of methane (CH₄), ethane (C₂H₆), propane (C₃H₈), butane (C₄H₁₀), ethylene (C₂H₄), propylene (C₃H₆), acetylene (C₂H₂), and propyne (C₃H₄) can be used. The etching conditions can be set as appropriate depending on an object to be etched.

As a dry etching apparatus, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, high-frequency voltages with the same frequency may be applied to the parallel plate electrodes. Further alternatively, high-frequency voltages with different frequencies may be applied to the parallel plate electrodes. Such a CCP etching apparatus is referred to as a dual frequency capacitively coupled plasma (DF-CCP) etching apparatus. In the DF-CCP etching apparatus, high-frequency voltages with different frequencies can be applied to the parallel plate electrodes. Still further alternatively, high-frequency voltages with different frequencies may be applied to one of the parallel plate electrodes. A dry etching apparatus including a high-density plasma source can be used. As the dry etching apparatus including a high-density plasma source, an inductively coupled plasma (ICP) etching apparatus can be used, for example. The etching apparatus can be set as appropriate depending on an object to be etched. Note that in the above dry etching apparatus, a high-frequency voltage is applied to the electrode on the substrate side to generate a self-bias potential, whereby reactive ion etching can be performed. In reactive ion etching, ion species in plasma are accelerated to collide with an object to be processed, whereby etching with high anisotropy can be performed.

Next, the insulating layer 223 is removed (see FIGS. 22A and 22B). The insulating layer 223 can be removed by a dry etching method or a wet etching method. For example, the insulating layer 223 is preferably removed by a wet etching method.

The insulating layer 222 formed using a hard-to-etch material such as hafnium oxide can function as an etching stopper in the etching treatment of the semiconductor film 230P and the insulating layer 223.

The top surface of the semiconductor layer 230a has an enclosing shape where both edges are aligned with each other as illustrated in FIG. 22A. The semiconductor layer 230a after the removal of the insulating layer 223a can also be regarded as having an opening in its center portion. In the case where the semiconductor layer 230a has a three-layer structure of the semiconductor layers 230a1 to 230a3 as described above, the semiconductor layers 230a1, 230a2, and 230a3 are formed in this order as the enclosing-shaped semiconductor layer 230a around the region where the insulating layer 223a is formed. Thus, as illustrated in FIG. 9A, the semiconductor layers 230a3, 230a2, 230a1, 230a1, 230a2, and 230a3 are arranged in this order to form a bilaterally symmetrical structure in the cross-sectional view in the channel width direction.

Note that although the structure in which three enclosing-shaped semiconductor layers 230 are provided is described above, the present invention is not limited thereto. One, two, or four or more enclosing-shaped semiconductor layers 230 may be provided, for example. Alternatively, enclosing-shaped semiconductor layers 230 may be connected to form the semiconductor layer 230 having a plurality of openings. For example, as illustrated in FIG. 4B, the semiconductor layer 230 can be formed to have three openings arranged in the B3-B4 direction in the top view. In this case, three insulating layers 223 are formed adjacent to each other at small intervals in the step illustrated in FIGS. 19A and 19B. For another example, as illustrated in FIG. 4C, the semiconductor layer 230 can be formed to have a lattice shape in the top view. In this case, a lattice-shaped trench is formed in the insulating layer 223 in the step illustrated in FIGS. 19A and 19B.

Although the semiconductor layer 230 has an enclosing-shaped structure in the top view in FIG. 22A, the semiconductor layer 230 may be partly removed by additional etching treatment. For example, the semiconductor layer 230 in the structure illustrated in FIG. 22A can be partly removed to have a rectangular shape extending in the A5-A6 direction in the top view.

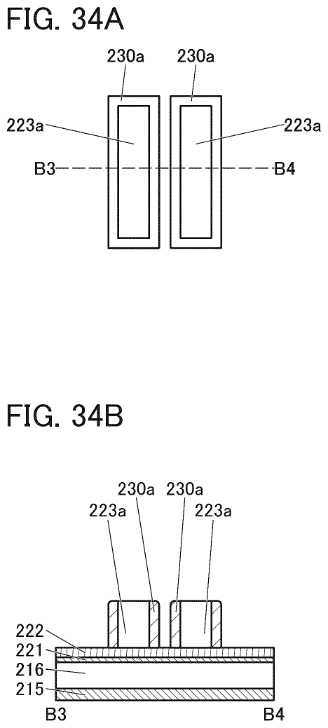

Although each transistor 200a includes one insulating layer 223a and one semiconductor layer 230a in FIGS. 21A and 21B, the present invention is not limited thereto. As illustrated in FIGS. 34A and 34B, each transistor 200a may include two insulating layers 223a and two semiconductor layers 230a. In this case, the transistor illustrated in FIG. 4A can be formed.

Next, a conductive film 242P1 is formed over the insulating layer 222 and the semiconductor layer 230, and a conductive film 242P2 is formed over the conductive film 242P1 (see FIGS. 23A and 23B). For the conductive film 242P1, a conductor corresponding to the conductive layers 242a1, 242b1, 242c1, 242d1, and 242e1 is used. For the conductive film 242P2, a conductor corresponding to the conductive layers 242a2, 242b2, 242c2, and 242d2 is used.

The conductive films 242P1 and 242P2 can each be formed by a sputtering method, a CVD method, an MBE method, a PLD method, or an ALD method, for example. For example, tantalum nitride can be formed as the conductive film 242P1 by a sputtering method. Alternatively, titanium nitride can be formed as the conductive film 242P1 by a CVD method. Tungsten can be formed as the conductive film 242P2 by a sputtering method or a CVD method. By forming the conductive film 242P1 to cover the semiconductor layer 230, the contact area between the semiconductor layer 230 and the conductive layer 242 can be increased without increasing the area occupied by the transistor 200. Accordingly, the on-state current and frequency characteristics of the transistor 200 can be improved.

Next, the conductive films 242P1 and 242P2 are processed into island shapes by a lithography method to form the conductive layer 242Q (the conductive layer 242Q1 and a conductive layer 242Q2), the conductive layer 242R (the conductive layer 242R1 and a conductive layer 242R2), and a conductive layer 242S (a conductive layer 242S1 and a conductive layer 242S2) (see FIGS. 24A and 24B). The conductive layers 242Q1, 242R1, and 242S1 are formed by processing the conductive film 242P1, and the conductive layers 242Q2, 242R2, and 242S2 are formed by processing the conductive film 242P2. Here, the conductive layer 242Q, the conductive layer 242R, and the conductive layer 242S are preferably formed to cover the semiconductor layer 230a, the semiconductor layer 230b, and the semiconductor layer 230c, respectively. The insulating layer 222 is exposed in a region overlapping with none of the conductive layers 242Q to 242S.

The above processing can be performed by a dry etching method or a wet etching method. A dry etching method is suitable for microfabrication. Note that the above description can be referred to for the conditions and an apparatus for the dry etching method.

The conductive layers 242Q to 242S may have side surfaces that are perpendicular or substantially perpendicular to the top surface of the insulating layer 222. With such a structure, a plurality of transistors can be provided with high density in a small area.

Not being limited to the above, the side surfaces of the semiconductor layer 230 and the conductive layers 242Q to 242S may each have a tapered shape. The taper angle of the side surfaces of the semiconductor layer 230 and the conductive layers 242Q to 242S may be, for example, greater than or equal to 60° and less than 90°. With such tapered side surfaces, the coverage with the insulating layer 275 and the like can be improved in a later step, so that the number of defects such as voids can be reduced.

In the lithography method, first, a resist is exposed to light through a mask. Next, a region exposed to light is removed or left using a developing solution, so that a resist mask is formed. Then, etching treatment is conducted with the resist mask, whereby a conductive layer, a semiconductor layer, an insulating layer, or the like can be processed into a desired shape. The resist mask can be formed, for example, by exposing the resist to KrF excimer laser light, ArF excimer laser light, or extreme ultraviolet (EUV) light. A liquid immersion technique may be employed in which a portion between a substrate and a projection lens is filled with a liquid (e.g., water) to perform light exposure. An electron beam or an ion beam may be used instead of the above-mentioned light. Note that a mask is unnecessary in the case of using an electron beam or an ion beam in some cases.

To remove the resist mask which is no longer needed after the processing, dry etching treatment such as ashing using oxygen plasma (hereinafter referred to as oxygen plasma treatment in some cases) or wet etching treatment may be performed. Alternatively, wet etching treatment may be performed after dry etching treatment, or dry etching treatment may be performed after wet etching treatment.

A hard mask formed of an insulating layer or a conductive layer may be used under the resist mask. In the case of using a hard mask, a hard mask with a desired shape can be formed in the following manner: an insulating layer or a conductive layer that is the material of the hard mask is formed over the conductive film 242P2, a resist mask is formed thereover, and then the hard mask material is etched. The etching of the conductive film 242P2 and the like may be performed after or without removal of the resist mask. In the latter case, the resist mask sometimes disappears during the etching. The hard mask may be removed by etching after the etching of the conductive film 242P1 or the conductive film 242P2. The hard mask does not need to be removed when the hard mask material does not affect the following process or can be utilized in the following process.

A spin on carbon (SOC) film and a spin on glass (SOG) film may be formed between an object to be processed and the resist mask. Using the SOC film and the SOG film as masks can improve the durability of a mask pattern. For example, the SOC film, the SOG film, and the resist mask are formed in this order over the object to be processed and lithography can be performed.

Next, the insulating layer 275 is formed to cover the conductive layers 242Q to 242S, and the insulating layer 280 is formed over the insulating layer 275 (see FIGS. 25A and 25B). The above-described insulators are used for the insulating layers 275 and 280.

Here, the insulating layer 275 is preferably in contact with the top surface of the insulating layer 222.

The insulating layers 275 and 280 can each be formed by a sputtering method, a CVD method, an MBE method, a PLD method, or an ALD method, for example.

As the insulating layer 280, an insulating layer having a flat top surface is preferably formed in the following manner: an insulating film to be the insulating layer 280 is formed and then the insulating film is subjected to CMP treatment. Note that a silicon nitride film may be formed over the insulating layer 280 by a sputtering method, for example, and then subjected to CMP treatment until the insulating layer 280 is exposed.

The insulating layer 275 is preferably formed using an insulator having a function of inhibiting transmission of oxygen. For example, silicon nitride is preferably formed by a PEALD method as the insulating layer 275. Alternatively, as the insulating layer 275, it is preferable that aluminum oxide be formed by a sputtering method and silicon nitride be formed thereover by a PEALD method. When the insulating layer 275 has such a structure, the function of inhibiting diffusion of oxygen and impurities such as water and hydrogen can be improved.

In this manner, the semiconductor layer 230 and the conductive layers 242Q to 242S can be covered with the insulating layer 275 having a function of inhibiting diffusion of oxygen. This structure can suppress direct diffusion of oxygen from the insulating layer 280 or the like into the semiconductor layer 230 and the conductive layers 242Q to 242S in a later step.

Silicon oxide is preferably formed by a sputtering method as the insulating layer 280. When an insulating film to be the insulating layer 280 is formed by a sputtering method in an oxygen-containing atmosphere, the insulating layer 280 containing excess oxygen can be formed. Since a molecule containing hydrogen is not used as a film formation gas in the sputtering method, the concentration of hydrogen in the insulating layer 280 can be reduced. Note that heat treatment may be performed before the formation of the insulating film. The heat treatment may be performed under a reduced pressure, and the insulating film may be successively formed without exposure to the air. Such treatment can remove moisture and hydrogen adsorbed on the surface of the insulating layer 275 and the like and reduce the moisture concentration and the hydrogen concentration in the semiconductor layer 230. The heat treatment can be performed with the above-described heat treatment conditions.

Next, the conductive layers 242Q2, 242R2, and 242S2 and the insulating layers 275 and 280 are processed by a lithography method to form the opening 291a reaching the conductive layer 242Q1 and the insulating layer 222 and the opening 291b reaching the conductive layers 242Q1, 242R1, and 242S1 and the insulating layer 222 (see FIGS. 26A and 26B). Here, the conductive layer 242Q2 is divided into the conductive layers 242a2 and 242b2, the conductive layer 242R2 is divided into the conductive layers 242c2 and 242d2, and the conductive layer 242S2 is divided into conductive layers 242e2 and 242f2. In the cross-sectional view of the transistor 200a in the channel length direction, the width of the opening 291a corresponds to the shortest distance between the conductive layers 242a2 and 242b2. The opening 291a is formed in a region overlapping with the semiconductor layer 230a, and the opening 291b is formed in a region overlapping with the semiconductor layer 230b and a region overlapping with the semiconductor layer 230c. Note that since the conductive layer 242S1 corresponds to the conductive layer 242e1 illustrated in FIGS. 13A to 13C, the conductive layer 242S1 is illustrated as the conductive layer 242e1 in FIGS. 26A and 26B and the following figures.

The above-described method can be used as appropriate as the lithography method. In order to process the openings 291a and 291b finely, an electron beam or short-wavelength light such as EUV light is preferably used for the lithography method.

The processing is preferably performed by a dry etching method. A dry etching method makes anisotropic etching possible and thus is suitable for forming an opening having a high aspect ratio. Note that the above description can be referred to for the conditions and an apparatus for the dry etching method.

Next, an insulating film 255P is formed to cover the conductive layers 242Q1, 242R1, and 242e1 and the insulating layers 222 and 280 (see FIGS. 27A and 27B). The insulating film 255P is an insulating film to be the insulating layers 255a and 255b in a later step, and the insulating layer described above can be used. The insulating film 255P can be formed by a sputtering method, a CVD method, an MBE method, a PLD method, or an ALD method, for example.

The insulating film 255P preferably has good coverage because the insulating film 255P is formed along the openings 291a and 291b. Accordingly, the insulating film 255P is preferably formed by an ALD method or the like, which provides good coverage. As the insulating film 255P, for example, silicon nitride is preferably formed by a PEALD method.

Next, by a lithography method, the conductive layer 242Q1 and the insulating film 255P are processed in the opening 291a to form the opening 292a reaching the semiconductor layer 230a, and the conductive layer 242R1 and the insulating film 255P are processed in the opening 291b to form the opening 292b reaching the semiconductor layer 230b (see FIGS. 28A and 28B). Here, the conductive layer 242Q1 is divided into the conductive layers 242a1 and 242b1 and the conductive layer 242R1 is divided into the conductive layers 242c1 and 242d1. In the cross-sectional view of the transistor 200a in the channel length direction, the width of the opening 292a corresponds to the shortest distance between the conductive layers 242a1 and 242b1. Since the opening 292a is formed inside the opening 291a, the shortest distance between the conductive layers 242a1 and 242b1 is smaller than the shortest distance between the conductive layers 242a2 and 242b2.

The above-described method can be used as appropriate as the lithography method. In order to process the openings 292a and 292b finely, an electron beam or short-wavelength light such as EUV light is preferably used for the lithography method.

Here, as illustrated in FIGS. 29A and 29B, a groove portion or an opening is formed in the insulating layer 222 in each of a region not overlapping with the semiconductor layer 230a in the opening 292a and a region not overlapping with the semiconductor layer 230b in the opening 292b, whereby the transistors 200a and 200b illustrated in FIGS. 15A to 15D can be formed. Note that in the formation of the groove portion or the opening, the thickness of the semiconductor layer 230a in a region overlapping with the opening 292a and the thickness of the semiconductor layer 230b in a region overlapping with the opening 292b are reduced in some cases.

Note that ashing treatment using oxygen plasma may be performed after the processing of the conductive layers 242Q1 and 242R1. Such oxygen plasma treatment can remove impurities generated by the etching treatment and diffused into the semiconductor layer 230 or the like. The impurities are generated by a component of the object processed by the above etching treatment and a component contained in a gas or the like used for the etching. Examples of the impurities include chlorine, fluorine, tantalum, silicon, and hafnium. In particular, when a chlorine gas is used in the processing of the conductive layers 242Q1 and 242R1 as in the above-described etching treatment, the semiconductor layer 230 is exposed to the atmosphere containing the chlorine gas, in which case chlorine attached to the semiconductor layer 230 is preferably removed. Removal of impurities attached to the semiconductor layer 230 in this manner can improve the electrical characteristics and reliability of the transistor.

In order to remove the impurities or the like attached onto the surface of the semiconductor layer 230 in the etching step, cleaning treatment may be performed. Examples of the cleaning method include wet cleaning using a cleaning solution (also can be referred to as wet etching treatment), plasma treatment using plasma, and cleaning by heat treatment, and these cleanings may be performed in combination as appropriate. The cleaning treatment sometimes makes the groove portion deeper.

The wet cleaning may be performed using an aqueous solution in which one or more of ammonia water, oxalic acid, phosphoric acid, and hydrofluoric acid are diluted with carbonated water or pure water; pure water; or carbonated water, for example. Alternatively, ultrasonic cleaning using such an aqueous solution, pure water, or carbonated water may be performed. Further alternatively, these cleanings may be performed in combination as appropriate.

Note that in this specification and the like, in some cases, an aqueous solution in which hydrofluoric acid is diluted with pure water is referred to as diluted hydrofluoric acid, and an aqueous solution in which ammonia water is diluted with pure water is referred to as diluted ammonia water. The concentration, temperature, and the like of the aqueous solution are adjusted as appropriate in accordance with an impurity to be removed, the structure of a semiconductor device to be cleaned, or the like. The concentration of ammonia in the diluted ammonia water is preferably higher than or equal to 0.01% and lower than or equal to 5%, further preferably higher than or equal to 0.1% and lower than or equal to 0.5%. The concentration of hydrogen fluoride in the diluted hydrofluoric acid is preferably higher than or equal to 0.01 ppm and lower than or equal to 100 ppm, further preferably higher than or equal to 0.1 ppm and lower than or equal to 10 ppm.

A frequency greater than or equal to 200 kHz is preferably used for the ultrasonic cleaning, and a frequency greater than or equal to 900 kHz is further preferably used. Damage to the semiconductor layer 230 and the like can be reduced with this frequency.

The cleaning treatment may be performed plural times, and the cleaning solution may be changed in every cleaning treatment. For example, first cleaning treatment may use diluted hydrofluoric acid or diluted ammonia water and second cleaning treatment may use pure water or carbonated water.

In this embodiment, as the cleaning treatment, wet cleaning is performed with use of diluted ammonia water. The cleaning treatment allows removing impurities that are attached onto or diffused into the surface of the semiconductor layer 230 or the like. Furthermore, the crystallinity of the semiconductor layer 230 can be improved.

After the etching or the cleaning, heat treatment is preferably performed. The temperature of the heat treatment is higher than or equal to 100° C. and lower than or equal to 650° C., preferably higher than or equal to 250° C. and lower than or equal to 600° C., still further preferably higher than or equal to 300° C. and lower than or equal to 550° C., yet still further preferably higher than or equal to 350° C. and lower than or equal to 400° C. The heat treatment is performed in a nitrogen gas atmosphere, an inert gas atmosphere, or an atmosphere containing an oxidizing gas at 10 ppm or more, 1% or more, or 10% or more. The heat treatment is preferably performed in an oxygen-containing atmosphere. For example, it is preferable that the flow rate ratio of a nitrogen gas to an oxygen gas be 4:1 and the heat treatment be performed at a temperature of 350° C. for one hour. This supplies oxygen to the semiconductor layer 230, and reduces oxygen vacancies. In addition, the crystallinity of the semiconductor layer 230 can be improved by the heat treatment. Furthermore, hydrogen remaining in the semiconductor layer 230 reacts with supplied oxygen, so that the hydrogen can be removed as H₂O (dehydration). This can inhibit recombination of hydrogen remaining in the semiconductor layer 230 with oxygen vacancies and formation of VoH. Accordingly, a transistor including the semiconductor layer 230 can have favorable electrical characteristics and high reliability. In addition, variations in electrical characteristics of transistors formed over the same substrate can be reduced. The heat treatment may be performed under a reduced pressure. Alternatively, the heat treatment may be performed in such a manner that heat treatment is performed in an oxygen atmosphere, and then another heat treatment is successively performed in a nitrogen atmosphere without exposure to the air. The heat treatment can also serve as the heat treatment described in Embodiment 1. Thus, the heat treatment sometimes makes the crystal region of the semiconductor layer 230 grow.

In the case where heat treatment is performed in a state where the semiconductor layer 230a is in contact with the conductive layers 242a and 242b, the sheet resistance is sometimes reduced in each of a region of the semiconductor layer 230a which overlaps with the conductive layer 242a and a region of the semiconductor layer 230a which overlaps with the conductive layer 242b. The carrier concentration is sometimes increased. Thus, the resistance of each of the region of the semiconductor layer 230a which overlaps with the conductive layer 242a and the region of the semiconductor layer 230a which overlaps with the conductive layer 242b can be lowered in a self-aligned manner. Note that the same applies to the semiconductor layer 230b.

Here, as described above, the insulating layer 255, which includes an inorganic insulator that is less likely to be oxidized, is in contact with the side surfaces of the conductive layers 242a2, 242b2, 242c2, and 242d2. This can prevent the conductive layers 242a2, 242b2, 242c2, and 242d2 from being excessively oxidized by the heat treatment even when a tungsten film or the like that is relatively easily oxidized is used for the conductive layers 242a2, 242b2, 242c2, and 242d2.

Next, the insulating film 250P to be the insulating layer 250 is formed over the insulating film 255P, the semiconductor layer 230, and the insulating layer 222 (see FIGS. 30A and 30B). Here, the insulating film 250P is provided in contact with the insulating film 255P, the conductive layer 242a1, the conductive layer 242b1, the semiconductor layer 230, and the insulating layer 222 in the opening 292a, and in contact with the insulating film 255P, the conductive layer 242c1, the conductive layer 242d1, the semiconductor layer 230, and the insulating layer 222 in the opening 292b.

The insulating film 250P can be formed by a sputtering method, a CVD method, an MBE method, a PLD method, or an ALD method. For example, the insulating film 250P is preferably formed by an ALD method. Like the above-described insulating layer 250, the insulating film 250P is preferably formed to have a small thickness, and a variation in the thickness needs to be reduced. In the ALD method, a precursor and a reactant (such as oxidizer) are alternately introduced to form a film, and the film thickness can be adjusted by the number of repetition times of the sequence of the introduction; thus, accurate adjustment of the film thickness is possible. In addition, the insulating film 250P needs to be formed on the bottom surfaces and the side surfaces of the openings 291 and 292 so as to have good coverage. One atomic layer can be deposited at a time on the bottom and side surfaces of each of the openings 291 and 292 by the ALD method, whereby the insulating film 250P can be formed in the openings 291 and 292 with good coverage.

When the insulating film 250P is formed by an ALD method, ozone (O₃), oxygen (O₂), water (H₂O), or the like can be used as the oxidizer. When an oxidizer without hydrogen, such as ozone (O₃) or oxygen (O₂), is used, the amount of hydrogen diffused into the semiconductor layer 230 can be reduced.

The insulating layer 250 can have a stacked-layer structure as illustrated in FIG. 3A and the like. For example, as illustrated in FIG. 3A, the insulating layer 250 can have a stacked-layer structure of the insulating layers 250a1 to 250a4. In this case, aluminum oxide is formed as the insulating layer 250a1 by a thermal ALD method, silicon oxide is formed as the insulating layer 250a2 by a PEALD method, hafnium oxide is formed as the insulating layer 250a3 by a thermal ALD method, and silicon nitride is formed as the insulating layer 250a4 by a PEALD method.

Microwave plasma treatment is preferably performed in an oxygen-containing atmosphere after the formation of the insulating film 250P or any of the insulators included in the insulating film 250P.

The microwave plasma treatment is preferably performed with a microwave plasma treatment apparatus including a power source for generating high-density plasma using microwaves, for example. Here, the frequency of the microwave plasma treatment apparatus is preferably set to greater than or equal to 300 MHz and less than or equal to 300 GHz, further preferably greater than or equal to 2.4 GHz and less than or equal to 2.5 GHZ, for example, 2.45 GHz. Oxygen radicals at high density can be generated with high-density plasma. The electric power of the power source that applies microwaves of the microwave plasma treatment apparatus is preferably set to higher than or equal to 1000 W and lower than or equal to 10000 W, further preferably higher than or equal to 2000 W and lower than or equal to 5000 W. A power source may be provided for the microwave plasma treatment apparatus to apply RF to the substrate side. Furthermore, application of RF to the substrate side allows oxygen ions generated by the high-density plasma to be efficiently introduced into the semiconductor layer 230.

The microwave plasma treatment is preferably performed under a reduced pressure, and the pressure is preferably higher than or equal to 10 Pa and lower than or equal to 1000 Pa, further preferably higher than or equal to 300 Pa and lower than or equal to 700 Pa. The treatment temperature is preferably lower than or equal to 750° C., further preferably lower than or equal to 500° C., and can be approximately 250° C., for example. The oxygen plasma treatment may be followed successively by heat treatment without exposure to the air. The temperature of the heat treatment is preferably, for example, higher than or equal to 100° C. and lower than or equal to 750° C., further preferably higher than or equal to 300° C. and lower than or equal to 500° C.

Furthermore, the microwave plasma treatment can be performed using an oxygen gas and an argon gas, for example. Here, the oxygen flow rate ratio (O₂/O₂+Ar) is preferably higher than 0% and lower than or equal to 100%, further preferably higher than 0% and lower than or equal to 50%, still further preferably higher than or equal to 10% and lower than or equal to 40%, yet still further preferably higher than or equal to 10% and lower than or equal to 30%. The carrier concentration in the semiconductor layer 230 can be reduced by thus performing the microwave plasma treatment in an oxygen-containing atmosphere. In addition, the carrier concentrations in the semiconductor layer 230 can be prevented from being excessively reduced by preventing an excessive amount of oxygen from being introduced into the chamber in the microwave plasma treatment.

The microwave plasma treatment in an oxygen-containing atmosphere converts an oxygen gas into plasma using a high-frequency wave such as microwave or RF, and applies the oxygen plasma to a region of the semiconductor layer 230 that is between the conductive layer 242a and the conductive layer 242b. By the effects of plasma, microwave, and the like, VoH in the region can be divided into oxygen vacancies and hydrogen, and hydrogen can be removed from the region. Here, in the case of the structure illustrated in FIG. 3A and the like, an insulating film (e.g., aluminum oxide) having a function of capturing or fixing hydrogen is preferably used as the insulating layer 250a1. With such a structure, hydrogen generated by the microwave plasma treatment can be captured or fixed in the insulating film 250P. In this manner, the amount of VoH contained in the channel formation region can be reduced. As a result, oxygen vacancies and VoH in the channel formation region can be reduced to lower the carrier concentration. In addition, oxygen radicals generated by the oxygen plasma can be supplied to oxygen vacancies formed in the channel formation region, thereby further reducing oxygen vacancies and lowering the carrier concentration in the channel formation region.

Oxygen injected into the channel formation region has a variety of forms such as an oxygen atom, an oxygen molecule, an oxygen ion, and an oxygen radical (also referred to as O radical which is an atom, a molecule, or an ion having an unpaired electron). The oxygen injected into the channel formation region preferably has one or more of the above forms. An oxygen radical is particularly preferable. In addition, the insulating layer 250 can have improved film quality, which increases the reliability of the transistor.

Furthermore, the microwave plasma treatment can remove impurities such as carbon in the semiconductor layer 230. By removing carbon, which is an impurity in the semiconductor layer 230, the crystallinity of the semiconductor layer 230 can be increased. Accordingly, the semiconductor layer 230 can be a c-axis aligned crystalline oxide semiconductor (CAAC-OS). Particularly in the case where the semiconductor layer 230 is formed by an ALD method, carbon contained in a precursor is sometimes taken into the semiconductor layer 230; thus, carbon is preferably removed by the microwave plasma treatment.

Meanwhile, the semiconductor layer 230 includes a region overlapping with the conductive layer 242a or 242b. The region can function as a source region or a drain region. Here, the conductive layers 242a and 242b preferably function as a blocking film preventing the effect of the microwave, the high-frequency wave such as RF, the oxygen plasma, or the like in the microwave plasma treatment in an oxygen-containing atmosphere. Therefore, the conductive layers 242a and 242b preferably have a function of blocking an electromagnetic wave greater than or equal to 300 MHz and less than or equal to 300 GHz, for example, greater than or equal to 2.4 GHz and less than or equal to 2.5 GHZ.

Since the conductive layers 242a and 242b prevent the effect of the microwave, the high-frequency wave such as RF, the oxygen plasma, or the like, the effect does not reach the region of the semiconductor layer 230 which overlaps with the conductive layer 242a or 242b. Hence, a reduction in VoH and supply of an excessive amount of oxygen due to the microwave plasma treatment do not occur in the source and drain regions, preventing a decrease in carrier concentration.

In the above manner, oxygen vacancies and VoH can be selectively removed from the channel formation region in the oxide semiconductor, whereby the channel formation region can be an i-type or substantially i-type region. Furthermore, supply of an excess amount of oxygen to the regions functioning as the source region and the drain region can be inhibited and the conductivity (low-resistance regions) before the microwave plasma treatment can be maintained. As a result, a change in the electrical characteristics of the transistor can be inhibited, and thus variation in the electrical characteristics of the transistors in the substrate plane can be inhibited.

The microwave plasma treatment improves the film quality of the insulating layer 250, thereby inhibiting diffusion of hydrogen, water, impurities, and the like. Accordingly, hydrogen, water, impurities, and the like can be inhibited from being diffused into the semiconductor layer 230 and the like through the insulating layer 250 in the following step such as formation of a conductive film to be the conductive layer 260 or the following treatment such as heat treatment. By improving the film quality of the insulating layer 250 as described above, the reliability of the transistor can be improved.

In the case where the insulating layer 250 has a stacked-layer structure of the insulating layers 250a1 to 250a4, microwave plasma treatment is preferably performed after the formation of the insulating layer 250a2. Furthermore, microwave plasma treatment may be performed again after the formation of the insulating layer 250a3. As described above, the microwave plasma treatment in an oxygen-containing atmosphere may be performed multiple times (at least two or more times). In some cases, the microwave plasma treatment can also serve as the heat treatment described in Embodiment 1. Thus, the microwave plasma treatment sometimes makes the crystal region of the semiconductor layer 230 grow.

After the microwave plasma treatment, heat treatment may be performed with the reduced pressure being maintained. Such treatment enables hydrogen in the insulating film and the semiconductor layer 230 to be removed efficiently. Alternatively, the step of performing microwave plasma treatment and then performing heat treatment with the reduced pressure being maintained may be repeated a plurality of cycles. The repetition of the heat treatment enables hydrogen in the insulating film and the semiconductor layer 230 to be removed more efficiently. Note that the temperature of the heat treatment is preferably higher than or equal to 300° C. and lower than or equal to 500° C. The heat treatment can also serve as the heat treatment described in Embodiment 1. Thus, the heat treatment sometimes makes the crystal region of the semiconductor layer 230 grow.

Next, the insulating films 250P and 255P are processed by a lithography method in the opening 291b to form the opening 293 reaching the conductive layer 242b1 (see FIGS. 31A and 31B). The opening 293 preferably overlaps with the conductive layer 242b1. In other words, the outer periphery of the opening 293 is preferably positioned inside the conductive layer 242b1 in the plan view. Such a structure can inhibit formation of a groove portion in a region of the insulating layer 222 that does not overlap with the conductive layer 242b1, thereby inhibiting part of the conductive film to be the conductive layer 260b from remaining in the groove portion.

The above-described method can be used as appropriate as the lithography method. In order to process the openings 292a and 292b finely, an electron beam or short-wavelength light such as EUV light is preferably used for the lithography method.

Next, a first conductive film to be the conductive layers 260a1 and 260b1 and a second conductive film to be the conductive layers 260a2 and 260b2 are formed in this order (see FIGS. 32A and 32B). The first and second conductive films can each be formed by a sputtering method, a CVD method, an MBE method, a PLD method, a plating method, or an ALD method, for example. In this embodiment, titanium nitride is formed by a CVD method as the first conductive film, and tungsten is formed by a CVD method as the second conductive film. Note that the first and second conductive films may be formed while the substrate is being heated. The substrate heating can serve as the heat treatment described above. Thus, the substrate heating sometimes makes the crystal region of the semiconductor layer 230 grow.

Then, the insulating film 255P, the insulating film 250P, the first conductive film, and the second conductive film are polished by CMP treatment until the insulating layer 280 is exposed. That is, portions of the insulating film 255P, the insulating film 250P, the first conductive film, and the second conductive film that are exposed in the openings 290, 291, and 292 are removed. Accordingly, the insulating layer 255a, the insulating layer 250a, and the conductive layer 260a (the conductive layers 260a1 and 260a2) are formed in the openings 291a and 292a, and the insulating layer 255b, the insulating layer 250b, and the conductive layer 260b (the conductive layers 260b1 and 260b2) are formed in the openings 291b, 292b, and 293 (see FIGS. 32A and 32B).

In the above-described manner, the insulating layer 255a is provided in contact with the insulating layer 280, the insulating layer 275, the conductive layer 242a, the conductive layer 242b, the semiconductor layer 230a, and the insulating layer 222 in the openings 291a and 292a. The insulating layer 250a is provided in contact with the insulating layer 255, the conductive layer 242a1, the conductive layer 242b1, the semiconductor layer 230a, and the insulating layer 222 in the openings 291a and 292a. The conductive layer 260a is positioned to fill the openings 291a and 292a with the insulating layer 250 therebetween. In this manner, the transistor 200a is formed.

The insulating layer 255b is provided in contact with the insulating layer 280, the insulating layer 275, the conductive layer 242b, the conductive layer 242c, the conductive layer 242d, the conductive layer 242e1, the conductive layer 242e2, the conductive layer 242f2, the semiconductor layer 230b, and the insulating layer 222 in the openings 291b, 292b, and 293. The insulating layer 250b is provided in contact with the insulating layer 255b, the conductive layer 242b1, the conductive layer 242cl, the conductive layer 242d1, the conductive layer 242e1, the semiconductor layer 230b, and the insulating layer 222 in the openings 291b, 292b, and 293. The conductive layer 260b is positioned to fill the openings 291b, 292b, and 293 with the insulating layer 250b therebetween. In this manner, the transistor 200b and the capacitor 100 are formed.

Next, the insulating layer 282 is formed over the insulating layer 255, the insulating layer 250, the conductive layer 260, and the insulating layer 280 (see FIGS. 33A and 33B). The insulating layer 282 can be formed by a sputtering method, a CVD method, an MBE method, a PLD method, or an ALD method, for example. The insulating layer 282 is preferably formed by a sputtering method. The insulating layer 282 may be formed by forming a first layer by an ALD method and forming a second layer over the first layer by a sputtering method.

Forming the insulating layer 282 in an oxygen-containing atmosphere by a sputtering method can provide oxygen to the insulating layer 280 during the formation. Thus, excess oxygen can be contained in the insulating layer 280. The formation of the insulating layer 282 is preferably performed while the substrate is heated. By forming the insulating layer 282 in such a manner, a suitable amount of oxygen can be supplied from the insulating layer 280 to the semiconductor layer 230 through the insulating layer 250. Provision of the insulating layer 250a1 in the insulating layer 250 can prevent an excess amount of oxygen from being supplied to the insulating layer 250, whereby the conductive layers 242a and 242b in the vicinity of the insulating layer 250 can be prevented from being excessively oxidized.

Aluminum oxide is formed using an aluminum target in an atmosphere containing an oxygen gas. The amount of oxygen injected into the insulating layer 280 can be controlled depending on the amount of the bias power applied to the substrate in a sputtering method. For example, the amount of oxygen injected into the insulating layer 280 is smaller as the bias power is lower, and the amount of oxygen is easily saturated even when the insulating layer 282 has a small thickness. Furthermore, the amount of oxygen injected into the insulating layer 280 is larger as the bias power is higher. With low bias power, the amount of oxygen injected into the insulating layer 280 can be reduced. Note that in the case where the substrate bias is applied by an RF power source, the RF frequency is preferably 10 MHz or higher. The typical frequency is 13.56 MHz. The higher the RF frequency is, the less damage to the substrate can be.

Over the first layer formed by an ALD method, the second layer is formed by a sputtering method, whereby the upper end portion of the insulating layer 250 and the top surface of the conductive layer 260 can be protected from an impact of ion collision due to sputtering film formation.

Note that heat treatment may be performed before the formation of the insulating layer 282. The heat treatment may be performed under a reduced pressure, and the insulating layer 282 may be successively formed without exposure to the air. Such treatment can remove moisture and hydrogen adsorbed on the surface of the insulating layer 280 and reduce the moisture concentration and the hydrogen concentration in the insulating layer 280. The temperature of the heat treatment is preferably higher than or equal to 100° C. and lower than or equal to 400° C. In this embodiment, the temperature of the heat treatment is 250° C.

Next, the insulating layer 283 is formed over the insulating layer 282 (see FIGS. 33A and 33B). The insulating layer 283 can be formed by a sputtering method, a CVD method, an MBE method, a PLD method, or an ALD method, for example. The insulating layer 283 is preferably formed by a sputtering method. Since a molecule containing hydrogen is not used as a film formation gas in the sputtering method, the concentration of hydrogen in the insulating layer 283 can be reduced. In this embodiment, silicon nitride is formed as the insulating layer 283 by a sputtering method.

Here, it is preferable to form the insulating layers 282 and 283 successively without exposure to the air. Film formation without exposure to the air can prevent attachment of impurities or moisture from the air onto the insulating layers 282 and 283, so that an interface between the insulating layers 282 and 283 and the vicinity thereof can be kept clean.

In this embodiment, silicon nitride is formed as the insulating layer 283, and aluminum oxide is formed as the insulating layer 282. When silicon nitride having a function of inhibiting diffusion of hydrogen is used for the insulating layer 283 in this manner, diffusion of hydrogen from a layer above the transistor 200 can be inhibited. Furthermore, when aluminum oxide having a function of capturing or fixing hydrogen is used for the insulating layer 282, hydrogen contained in the insulating layer 280 or the like can be captured or fixed by the insulating layer 282. This can reduce the hydrogen concentration in the semiconductor layer 230 and in the vicinity thereof.

Next, the insulating layer 285 is formed over the insulating layer 283 (see FIGS. 33A and 33B). The insulating layer 285 can be formed by a sputtering method, a CVD method, an MBE method, a PLD method, or an ALD method, for example. The insulating layer 285 is preferably formed by a sputtering method. Since a molecule containing hydrogen is not used as a film formation gas in the sputtering method, the concentration of hydrogen in the insulating layer 285 can be reduced. In this embodiment, silicon oxide is formed as the insulating layer 285 by a sputtering method.

Next, an opening reaching the conductive layer 242a2, an opening reaching the conductive layer 242c2, and an opening reaching the conductive layer 242d2 are formed in the insulating layers 275, 280, 282, 283, and 285 (see FIGS. 1B and 1C and FIG. 13A). The openings are formed by a lithography method. In the formation of the openings, the object to be processed is preferably processed by a dry etching method. A dry etching method makes anisotropic etching possible and thus is suitable for forming an opening having a high aspect ratio. In the case of performing anisotropic etching, reactive ion etching is preferably performed, for example. Note that the above description can be referred to for the conditions and an apparatus for the dry etching. Although the openings in the top view in FIG. 13A each have a quadrangular shape, the shapes of the openings are not limited thereto. For example, the openings in the top view may each have a circular shape, a substantially circular shape such as an elliptical shape, a polygonal shape such as a quadrangular shape, or a polygonal shape such as a quadrangular shape with rounded corners.

Next, heat treatment may be performed after the formation of the openings. The temperature of the heat treatment is higher than or equal to 100° C. and lower than or equal to 600° C., preferably higher than or equal to 250° C. and lower than or equal to 550° C., further preferably higher than or equal to 350° C. and lower than or equal to 450° C. Note that the heat treatment is preferably performed in a nitrogen gas or inert gas atmosphere. The heat treatment is performed in a state where the conductive layers 242a2, 242c2, and 242d2 are exposed, and thus the heat treatment is preferably performed in an atmosphere not containing an oxidizing gas or an oxygen gas. For example, heat treatment is preferably performed at 400° C. in a nitrogen gas atmosphere for one hour. The heat treatment may be performed under a reduced pressure. By the above heat treatment, oxygen contained in the insulating layer 280 can be supplied to the semiconductor layer 230 through the insulating layer 250. Thus, oxygen vacancies in the channel formation region in the semiconductor layer 230 can be reduced. The heat treatment can also serve as the heat treatment described above. Thus, the heat treatment sometimes makes the crystal region of the semiconductor layer 230 grow.

Here, because the side surface of the insulating layer 280 is exposed in the opening, oxygen contained in the insulating layer 280 is diffused outwardly by the heat treatment, so that the amount of oxygen contained in the insulating layer 280 can be controlled. Meanwhile, since the insulating layers 282 and 283 each having a barrier property against oxygen are provided over the insulating layer 280, oxygen is not diffused outwardly from the top surface of the insulating layer 280. Accordingly, oxygen can be prevented from being excessively diffused from the insulating layer 280 outwardly and thus, oxygen vacancies can be prevented from being formed in the insulating layer 280. The semiconductor layer 230 and the conductive layers 242a and 242b are covered with the insulating layers 275 and 255. This can prevent direct diffusion of an excess amount of oxygen from the insulating layer 280 into the semiconductor layer 230 and the conductive layers 242a and 242b in the above heat treatment.

In the above-described manner, the amount of oxygen in the insulating layer 280 can be adjusted more suitably, and a suitable amount of oxygen can be supplied to the semiconductor layer 230. Accordingly, oxygen vacancies in the semiconductor layer 230 can be reduced, and an excess amount of oxygen can be prevented from being supplied to the semiconductor layer 230. Thus, the electrical characteristics and reliability of the transistor 200 can be improved. Furthermore, a step of exposing the side surface of the insulating layer 280 can also serve as a step of forming an opening in which the conductive layers 240a to 240c are embedded; thus, the manufacturing process of the semiconductor device can be simplified.

Next, an insulating film to be the insulating layers 241a to 241c is formed and then subjected to anisotropic etching, so that the insulating layer 241a, the insulating layer 241b, and the insulating layer 241c are formed in the opening reaching the conductive layer 242a, the opening reaching the conductive layer 242c, and the opening reaching the conductive layer 242d, respectively (see FIGS. 1B and 1C). The insulating film can be formed by a sputtering method, a CVD method, an MBE method, a PLD method, an ALD method, or the like. The insulating film preferably has a function of inhibiting transmission of oxygen. For example, silicon nitride is preferably formed by a PEALD method. Silicon nitride is preferable because of its high hydrogen blocking property.

For the anisotropic etching of the insulating film, for example, a dry etching method is employed. Providing the insulating layer 241 on the sidewall portions of the openings can inhibit transmission of oxygen from the outside and oxidation of the conductive layers 240a to 240c formed in the next step. Furthermore, diffusion of impurities such as water and hydrogen contained in the insulating layer 280 or the like into the conductive layers 240a to 240c can be prevented. Note that a depressed portion is sometimes formed on part of the top surfaces of the conductive layers 242a2, 242c2, and 242d2 by the anisotropic etching.

Next, a conductive film to be the conductive layers 240a to 240c is formed. The conductive film desirably has a stacked-layer structure including a conductor with a function of inhibiting transmission of impurities such as water and hydrogen. The conductive film, which can have a stacked-layer structure of tantalum nitride, titanium nitride, or the like and tungsten, molybdenum, copper, or the like, can be formed by a sputtering method, a CVD method, an MBE method, a PLD method, or an ALD method, for example.

Next, part of the conductive film is removed by CMP treatment to expose the top surface of the insulating layer 285. As a result, the conductive film remains only in the openings, whereby the conductive layers 240a to 240c having flat top surfaces can be formed (see FIGS. 1B and 1C and FIG. 13A). The CMP treatment may remove part of the top surface of the insulating layer 285.

By providing the conductive layer 240a in contact with the conductive layer 242a as described above, the conductive layer 242a functioning as one of the source and the drain of the transistor 200a can be electrically connected to a wiring. By providing the conductive layer 240b in contact with the conductive layer 242c as described above, the conductive layer 242c functioning as one of the source and the drain of the transistor 200b can be electrically connected to a wiring. By providing the conductive layer 240c in contact with the conductive layer 242d as described above, the conductive layer 242d functioning as the other of the source and the drain of the transistor 200b can be electrically connected to a wiring.

Note that a conductive layer functioning as a wiring or a conductive layer functioning as a plug can be formed over each of the conductive layers 240a to 240c.

Through the above steps, the semiconductor device illustrated in FIGS. 13A to 13C can be manufactured.

### <Structure Example 4 of Semiconductor Device>

The semiconductor device including the transistor 200a, the transistor 200b, and the capacitor 100 described in this embodiment can be used as a memory cell of a memory device. The transistor 200a is a transistor whose channel is formed in a semiconductor layer containing an oxide semiconductor. Since the transistor 200a has a low off-state current, a memory device including the transistor 200a can retain stored data for a long time. In other words, such a memory device does not require refresh operation or has an extremely low frequency of refresh operation, leading to a sufficient reduction in power consumption. The transistor 200a has high frequency characteristics and thus enables the memory device to perform reading and writing at high speed.

The memory cells are arranged in a matrix, whereby a memory cell array can be formed.

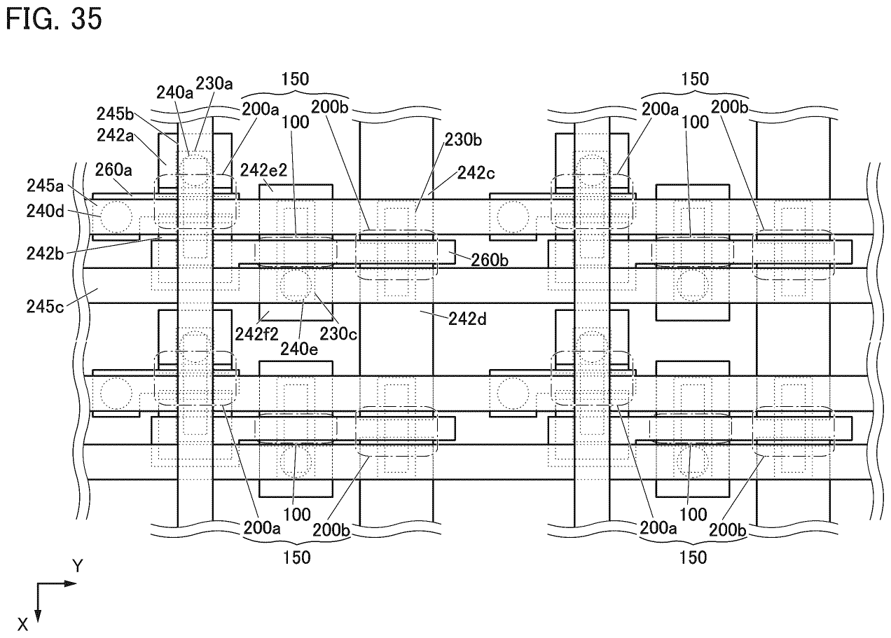

FIG. 35 is a plan view of a semiconductor device of one embodiment of the present invention. FIG. 35 illustrates an example in which 2×2 memory cells 150 are arranged in the X direction and the Y direction. The X direction and the Y direction shown in FIG. 35 are respectively parallel to the A1-A2 direction and the B1-B2 direction shown in FIG. 13A.

Here, the four memory cells 150 illustrated in FIG. 35 each include the transistor 200a, the transistor 200b, and the capacitor 100. That is, the four memory cells 150 illustrated in FIG. 35 each have a structure similar to that of the semiconductor device described in <Structure example 2 of semiconductor device>. Thus, in the semiconductor device illustrated in FIG. 35, components having the same functions as the components in the semiconductor device illustrated in FIGS. 13A to 13C are denoted by the same reference numerals. For the details of the memory cell 150, the description of the semiconductor device in <Structure example 2 of semiconductor device> can be referred to.

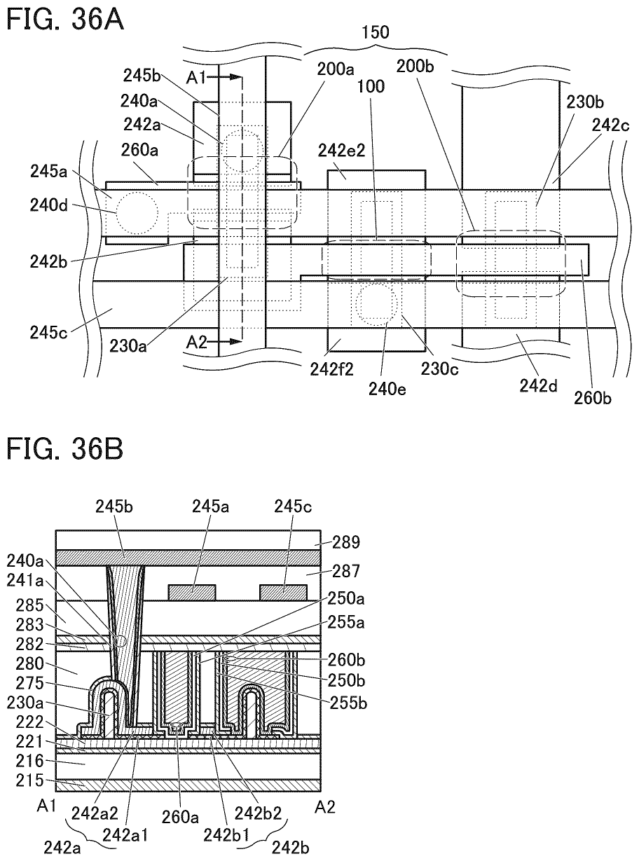

FIG. 36A and FIG. 36B are a plan view and a cross-sectional view, respectively, of the semiconductor device illustrated in FIG. 35. FIG. 36A is the plan view of the memory cell 150 included in the semiconductor device, and is also the plan view of a region including one memory cell 150 among the 2×2 memory cells 150 illustrated in FIG. 35. FIG. 36B is the cross-sectional view taken along the dashed-dotted line A1-A2 in FIG. 36A. Note that for simplification, in the plan view in FIG. 36A, some components are not illustrated and some components are illustrated in a see-through manner.

The semiconductor device illustrated in FIG. 35 includes conductive layers 240d, 240e, 245a, 245b, and 245c. The conductive layer 240a, the conductive layer 240d, and the conductive layer 240e function as plugs connected to the conductive layer 242a, the conductive layer 260a, and the conductive layer 242f2, respectively. The conductive layers 245a to 245c function as wirings.

The conductive layer 245a is electrically connected to the conductive layer 260a through the conductive layer 240d. That is, the conductive layer 245a is electrically connected to the gate electrode of the transistor 200a. The conductive layer 245b is electrically connected to the conductive layer 242a through the conductive layer 240a. That is, the conductive layer 245b is electrically connected to one of the source electrode and the drain electrode of the transistor 200a. The conductive layer 245c is electrically connected to the conductive layer 242e1 through the conductive layers 240e and 242f2. That is, the conductive layer 245c is electrically connected to the lower electrode of the capacitor 100.

In FIG. 35, the conductive layer 245a and the conductive layer 245b are provided to extend in the Y direction and the X direction, respectively. That is, the direction in which the conductive layer 245a extends is orthogonal or substantially orthogonal to the direction in which the conductive layer 245b extends. Note that the direction in which the conductive layer 245a extends and the direction in which the conductive layer 245b extends may intersect with each other, and may obliquely intersect with each other.

When a multilayer wiring structure in which an insulating layer and a conductive layer are stacked is employed as a wiring structure, a highly integrated semiconductor device can be obtained. Since the conductive layers 245a and 245b intersect with each other, the semiconductor device illustrated in FIG. 35 preferably has a multilayer wiring structure. For example, as illustrated in FIG. 36B, the conductive layer 245a can be provided over the insulating layer 285, the insulating layer 287 can be provided over the conductive layer 245a, and the conductive layer 245b can be provided over the insulating layer 287. The insulating layer 289 is provided over the conductive layer 245b. Although FIG. 36B exemplifies a structure in which the conductive layer 245b is provided above the conductive layer 245a, the present invention is not limited thereto; the conductive layer 245a may be provided above the conductive layer 245b.

In the semiconductor device illustrated in FIG. 35, the direction in which the conductive layer 245a extends is parallel or substantially parallel to the direction in which the conductive layer 245c extends. Thus, as illustrated in FIG. 36B, the conductive layers 245a and 245c can be provided over the insulating layer 285, for example. The conductive layers 245a and 245c in such a structure are formed through a step of processing one conductive film, whereby the manufacturing cost can be reduced.

In FIG. 35, the conductive layer 245c is provided to extend in the Y direction. That is, the direction in which the conductive layer 245c extends is orthogonal or substantially orthogonal to the channel length direction (X direction) of the transistor 200b. Note that the direction in which the conductive layer 245c extends and the channel length direction of the transistor 200b may intersect with each other, and may obliquely intersect with each other.

As illustrated in FIG. 35, the conductive layer 242d included in a first memory cell is not separated from the conductive layer 242c included in a second memory cell adjacent to the first memory cell in the X direction. That is, the other of the source electrode and the drain electrode of the transistor 200b of the first memory cell functions as one of the source electrode and the drain electrode of the transistor 200b of the second memory cell adjacent to the first memory cell in the X direction. In other words, the other of the source and the drain of the transistor 200b of the first memory cell is electrically connected to one of the source and the drain of the transistor 200b of the second memory cell adjacent to the first memory cell in the X direction. Thus, in the semiconductor device illustrated in FIG. 35, a plurality of transistors 200b are connected in series in a plurality of memory cells adjacent to each other in the X direction. With such a structure, the memory cells can be arranged at high density, and high integration of the semiconductor device can be achieved. Moreover, the manufacturing process of the semiconductor device can be simplified.

The conductive layers 240a, 240d, and 240e are circular in the top view in FIG. 35; however, one embodiment of the present invention is not limited thereto. For example, the conductive layers in the top view may each have a substantially circular shape such as an elliptical shape, a polygonal shape such as a quadrangular shape, or a polygonal shape such as a quadrangular shape with rounded corners.

Note that in the top view in FIG. 35, the semiconductor layers 230b each have an enclosing-shaped structure, and are separated from each other between the memory cells. Note that the present invention is not limited thereto. For example, the semiconductor layer 230b may be shared by the plurality of memory cells adjacent to each other in the X direction.

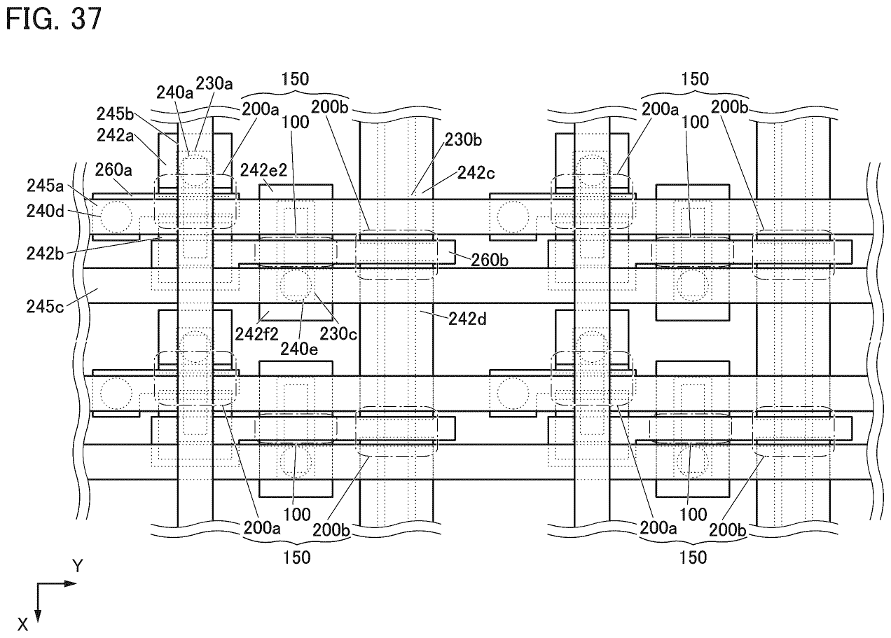

In the structure illustrated in FIG. 37, the semiconductor layer 230b of the first memory cell is not separated from the semiconductor layer 230b of the second memory cell adjacent to the first memory cell in the X direction. In other words, the semiconductor layer 230b of the transistor 200b is provided as a continuous layer across the plurality of memory cells adjacent to each other in the X direction. Moreover, the semiconductor layer 230b can be regarded as including a region extending in the X direction. When the plurality of memory cells arranged in the X direction share the semiconductor layer 230b as a continuous layer in such a manner, the memory cells can be arranged at high density, and high integration of the semiconductor device can be achieved. Moreover, the manufacturing process of the semiconductor device can be simplified.

The semiconductor device illustrated in FIG. 37 includes the first memory cell and the second memory cell adjacent to the first memory cell in the X direction. The semiconductor layer 230b of the transistor 200b of the first memory cell is provided to extend in the channel length direction of the transistor 200b of the first memory cell, and can be regarded as including a region overlapping with the conductive layer 260b functioning as the gate electrode of the transistor 200b of the second memory cell, with the insulating layer 250b functioning as the gate insulating layer of the transistor 200b of the second memory cell therebetween.

In each of the first and second memory cells, the conductive layer 260b functioning as the gate electrode of the transistor 200b can be regarded as including a region in contact with the conductive layer 242b1 functioning as one of the source electrode and the drain electrode of the transistor 200a, and a region overlapping with the conductive layer 242e1 functioning as the lower electrode of the capacitor 100, with the insulating layer 250b functioning as the gate insulating layer of the transistor 200b therebetween.

This embodiment can be combined with any of the other embodiments as appropriate. In this specification, in the case where a plurality of structure examples are shown in one embodiment, the structure examples can be combined as appropriate.

### Embodiment 2

In this embodiment, a semiconductor device 900 of one embodiment of the present invention will be described. The semiconductor device 900 can function as a memory device.

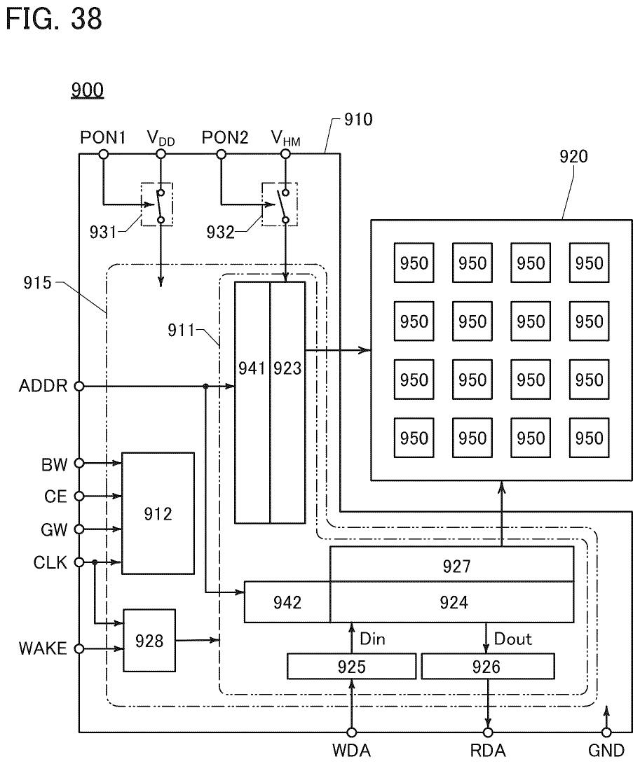

FIG. 38 is a block diagram illustrating a structure example of the semiconductor device 900. The semiconductor device 900 illustrated in FIG. 38 includes a driver circuit 910 and a memory array 920. The memory array 920 includes at least one memory cell 950. FIG. 38 illustrates an example in which the memory array 920 includes a plurality of memory cells 950 arranged in a matrix.

The transistor exemplified in Embodiment 1 can be used for the memory cell 950. With the use of the transistor, the operation speed of the memory device can be improved. This also enables further miniaturization and higher integration of the memory device. This also enables a larger capacity per area of the memory device.

The driver circuit 910 includes a power switch (PSW) 931, a PSW 932, and a peripheral circuit 915. The peripheral circuit 915 includes a peripheral circuit 911, a control circuit 912, and a voltage generator circuit 928.

In the semiconductor device 900, the circuits, signals, and voltages can be appropriately selected as needed. Another circuit or another signal may be added. Signals BW, CE, GW, CLK, WAKE, ADDR, WDA, PON1, and PON2 are signals input from the outside, and a signal RDA is a signal output to the outside. The signal CLK is a clock signal.

The signals BW, CE, and GW are control signals. The signal CE is a chip enable signal. The signal GW is a global write enable signal. The signal BW is a byte write enable signal. The signal ADDR is an address signal. The signal WDA is a write data signal, and the signal RDA is a read data signal. The signals PON1 and PON2 are power gating control signals. Note that the signals PON1 and PON2 may be generated in the control circuit 912.

The control circuit 912 is a logic circuit having a function of controlling the overall operation of the semiconductor device 900. For example, the control circuit 912 performs logical operation on the signals CE, GW, and BW to determine the operating mode (e.g., write operation or read operation) of the semiconductor device 900. The control circuit 912 generates a control signal for the peripheral circuit 911 so that the operating mode is executed.

The voltage generator circuit 928 has a function of generating a voltage. The signal WAKE has a function of controlling the input of the signal CLK to the voltage generator circuit 928. For example, when an H-level signal is supplied as the signal WAKE, the signal CLK is input to the voltage generator circuit 928, and the voltage generator circuit 928 generates a voltage.

The peripheral circuit 911 is a circuit for writing and reading data to/from the memory cell 950. The peripheral circuit 911 includes a row decoder 941, a column decoder 942, a row driver 923, a column driver 924, an input circuit 925, an output circuit 926, and a sense amplifier 927.

The row decoder 941 and the column decoder 942 have a function of decoding the signal ADDR. The row decoder 941 is a circuit for specifying a row to be accessed. The column decoder 942 is a circuit for specifying a column to be accessed. The row driver 923 has a function of selecting the row specified by the row decoder 941. The column driver 924 has a function of writing data to the memory cell 950, reading data from the memory cell 950, and retaining the read data, for example.

The input circuit 925 has a function of retaining the signal WDA. Data retained in the input circuit 925 is output to the column driver 924. Data output from the input circuit 925 is data (Din) written to the memory cell 950. Data (Dout) read from the memory cell 950 by the column driver 924 is output to the output circuit 926. The output circuit 926 has a function of retaining Dout. Moreover, the output circuit 926 has a function of outputting Dout to the outside of the semiconductor device 900. The data output from the output circuit 926 is the signal RDA.

The PSW 931 has a function of controlling the supply of V_{DD} to the peripheral circuit 915. The PSW 932 has a function of controlling the supply of V_{HM} to the row driver 923. Here, in the semiconductor device 900, a high power supply voltage is V_{DD} and a low power supply voltage is GND (ground potential). In addition, V_{HM} is a high power supply voltage used for setting a word line to high level, and is higher than V_{DD}. The on/off state of the PSW 931 is controlled by the signal PON1, and the on/off state of the PSW 932 is controlled by the signal PON2. The number of power domains to which V_{DD} is supplied is one in the peripheral circuit 915 in FIG. 38 but can be more than one. In that case, a power switch is provided for each power domain.

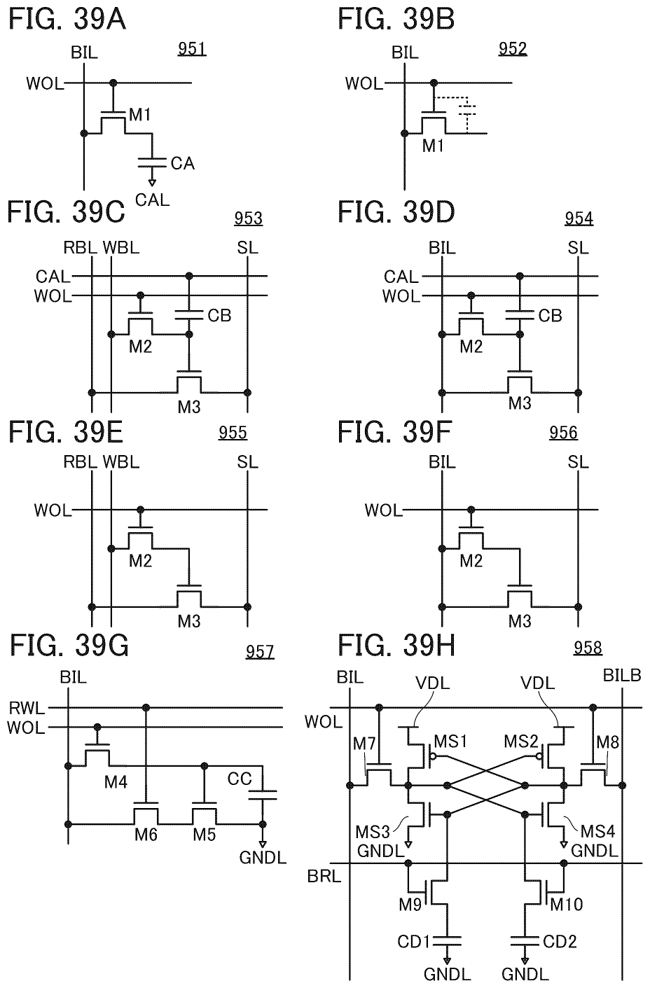

Structure examples of other memory cells each of which can be used as the memory cell 950 are described with reference to FIGS. 39A to 39H.

### [DOSRAM]

FIG. 39A illustrates a circuit configuration example of a memory cell for a DRAM. In this specification and the like, a DRAM using an OS transistor is referred to as a dynamic oxide semiconductor random access memory (DOSRAM). A memory cell 951 includes a transistor M1 and a capacitor CA.

Note that the transistor M1 may include a front gate (simply referred to as a gate in some cases) and a back gate. Here, the back gate may be connected to a wiring supplied with a constant potential or a signal, and the front gate and the back gate may be connected to each other.

A first terminal of the transistor M1 is connected to a first terminal of the capacitor CA. A second terminal of the transistor M1 is connected to a wiring BIL. The gate of the transistor M1 is connected to a wiring WOL. A second terminal of the capacitor CA is connected to a wiring CAL.

The wiring BIL functions as a bit line, and the wiring WOL functions as a word line. The wiring CAL functions as a wiring for applying a predetermined potential to the second terminal of the capacitor CA. At the time of data writing and reading, a low-level potential (referred to as a reference potential in some cases) is preferably applied to the wiring CAL.

Data writing and data reading are performed as follows: a high-level potential is applied to the wiring WOL to turn on the transistor M1, and thus the wiring BIL is connected to the first terminal of the capacitor CA.

The memory cell that can be used as the memory cell 950 is not limited to the memory cell 951, and the circuit configuration can be changed. For example, the configuration of a memory cell 952 illustrated in FIG. 39B may be employed. The memory cell 952 is an example including neither the capacitor CA nor the wiring CAL. The first terminal of the transistor M1 is in an electrically floating state.

In the memory cell 952, a potential written through the transistor M1 is retained in a capacitor (also referred to as parasitic capacitance) between the first terminal and the gate, which is shown by a dashed line. With such a structure, the structure of the memory cell can be greatly simplified.

Note that the OS transistor described in Embodiment 1 is preferably used as the transistor M1. For example, the transistor 200a and the capacitor 100 illustrated in FIGS. 13A to 13C can be used as the transistor M1 and the capacitor CA in the memory cell 951. With the use of the OS transistor described in Embodiment 1, the operation speed of the memory device can be improved. Furthermore, the area occupied by the memory cell can be reduced. An OS transistor has a characteristic of an extremely low off-state current. The use of an OS transistor as the transistor M1 enables an extremely low leakage current of the transistor M1. That is, with the use of the transistor M1, written data can be retained for a long time, and thus the frequency of refresh operation for the memory cell can be decreased. Alternatively, refresh operation for the memory cell can be omitted. In addition, owing to an extremely low leakage current, multilevel data or analog data can be retained in the memory cells 951 and 952.

### [NOSRAM]

FIG. 39C illustrates a circuit configuration example of a gain-cell memory cell including two transistors and one capacitor. A memory cell 953 includes a transistor M2, a transistor M3, and a capacitor CB. In this specification and the like, a memory device including a gain-cell memory cell using an OS transistor as the transistor M2 is referred to as a nonvolatile oxide semiconductor RAM (NOSRAM).

A first terminal of the transistor M2 is connected to a first terminal of the capacitor CB. A second terminal of the transistor M2 is connected to a wiring WBL. A gate of the transistor M2 is connected to the wiring WOL. A second terminal of the capacitor CB is connected to the wiring CAL. A first terminal of the transistor M3 is connected to a wiring RBL. A second terminal of the transistor M3 is connected to a wiring SL. A gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. In the time of data writing, data retention, and data reading, a low-level potential (referred to as a reference potential in some cases) is preferably applied to the wiring CAL.

Data writing is performed is performed as follows: a high-level potential is applied to the wiring WOL to turn on the transistor M2, and thus the wiring WBL is connected to the first terminal of the capacitor CB. Specifically, when the transistor M2 is on, a potential corresponding to data to be stored is applied to the wiring WBL, and the potential is written to the first terminal of the capacitor CB and the gate of the transistor M3. Then, a low-level potential is applied to the wiring WOL to turn off the transistor M2, whereby the potential of the first terminal of the capacitor CB and the potential of the gate of the transistor M3 are retained.

Data reading is performed by applying a predetermined potential to the wiring SL. A current flowing between the source and the drain of the transistor M3 and the potential of the first terminal of the transistor M3 are determined by the potential of the gate of the transistor M3 and the potential of the second terminal of the transistor M3. Accordingly, by reading a potential of the wiring RBL connected to the first terminal of the transistor M3, a potential retained in the first terminal of the capacitor CB (or the gate of the transistor M3) can be read. That is, data written to the memory cell can be read on the basis of the potential retained in the first terminal of the capacitor CB (or the gate of the transistor M3).

As another example, one wiring BIL may be provided instead of the wiring WBL and the wiring RBL. A circuit configuration example of the memory cell is illustrated in FIG. 39D. In a memory cell 954, one wiring BIL is provided instead of the wiring WBL and the wiring RBL in the memory cell 953, and the second terminal of the transistor M2 and the first terminal of the transistor M3 are connected to the wiring BIL. In other words, one wiring BIL operates as the write bit line and the read bit line in the memory cell 954.

A memory cell 955 illustrated in FIG. 39E is an example in which the capacitor CB and the wiring CAL in the memory cell 953 are omitted. A memory cell 956 illustrated in FIG. 39F is an example in which the capacitor CB and the wiring CAL in the memory cell 954 are omitted. Such structures enable high integration of the memory cell.

Note that the OS transistor described in Embodiment 1 is preferably used as at least the transistor M2, further preferably used as each of the transistors M2 and M3. For example, the transistor 200a, the transistor 200b, and the capacitor 100 illustrated in FIGS. 13A to 13C can be used as the transistor M2, the transistor M3, and the capacitor CB in the memory cells 953 and 954. For example, the transistor 200a and the transistor 200b illustrated in FIGS. 1A to 1D can be used as the transistor M2 and the transistor M3 in the memory cells 955 and 956. With the use of the OS transistor described in Embodiment 1, the operation speed of the memory device can be improved. Furthermore, the area occupied by the memory cell can be reduced.

Since the OS transistor has a characteristic of an extremely low off-state current, written data can be retained for a long time with the use of the transistor M2, and thus the frequency of refresh operation for the memory cell can be decreased. Alternatively, refresh operation for the memory cell can be omitted. In addition, owing to an extremely low leakage current, multilevel data or analog data can be retained in the memory cells 953, 954, 955, and 956.

The memory cells 953, 954, 955, and 956 each using the OS transistor as the transistor M2 are embodiments of a NOSRAM.

Note that a Si transistor may be used as the transistor M3. The Si transistor can have high field-effect mobility and can be formed as a p-channel transistor, so that the degree of freedom of circuit design can be increased.

When an OS transistor is used as the transistor M3, the memory cell can be configured with only n-channel transistors.

FIG. 39G illustrates a gain memory cell 957 including three transistors and one capacitor. The memory cell 957 includes transistors M4 to M6 and a capacitor CC.

A first terminal of the transistor M4 is connected to a first terminal of the capacitor CC. A second terminal of the transistor M4 is connected to the wiring BIL. A gate of the transistor M4 is connected to the wiring WOL. A second terminal of the capacitor CC is electrically connected to a first terminal of the transistor M5 and a wiring GNDL. A second terminal of the transistor M5 is connected to a first terminal of the transistor M6. A gate of the transistor M5 is connected to the first terminal of the capacitor CC. A second terminal of the transistor M6 is connected to the wiring BIL. A gate of the transistor M6 is connected to a wiring RWL.

The wiring BIL functions as a bit line. The wiring WOL functions as a write word line. The wiring RWL functions as a read word line. The wiring GNDL is a wiring for supplying a low-level potential.

Data writing is performed as follows: a high-level potential is applied to the wiring WOL to turn on the transistor M4, and thus the wiring BIL is connected to the first terminal of the capacitor CC. Specifically, when the transistor M4 is on, a potential corresponding to data to be stored is applied to the wiring BIL, and the potential is written to the first terminal of the capacitor CC and the gate of the transistor M5. Then, a low-level potential is applied to the wiring WOL to turn off the transistor M4, whereby the potential of the first terminal of the capacitor CC and the potential of the gate of the transistor M5 are retained.

Data reading is performed by precharging the wiring BIL to a predetermined potential, and then making the wiring BIL in an electrically floating state and applying a high-level potential to the wiring RWL. Since the wiring RWL has the high-level potential, the transistor M6 is turned on, so that the wiring BIL is electrically connected to the second terminal of the transistor M5. At this time, the potential of the wiring BIL is applied to the second terminal of the transistor M5; the potential of the second terminal of the transistor M5 and the potential of the wiring BIL change depending on the potential retained in the first terminal of the capacitor CC (or the gate of the transistor M5). Here, the potential retained in the first terminal of the capacitor CC (or the gate of the transistor M5) can be read by reading the potential of the wiring BIL. That is, data written to the memory cell can be read on the basis of the potential retained in the first terminal of the capacitor CC (or the gate of the transistor M5).

Note that the OS transistor described in Embodiment 1 is preferably used as at least the transistor M4. With the use of the OS transistor described in Embodiment 1, the area occupied by the memory cell can be reduced.

Note that Si transistors may be used as the transistors M5 and M6. As described above, a Si transistor may have higher field-effect mobility than an OS transistor depending on the crystal state of silicon used in a semiconductor layer, for example.

When OS transistors are used as the transistors M5 and M6, the memory cell can be configured with only n-channel transistors. For example, the transistor 200a, the transistor 200b, the transistor 200c, and the capacitor 100 illustrated in FIGS. 17A and 17B can be used as the transistor M4, the transistor M5, the transistor M6, and the capacitor CC of the memory cell 957.

### [OS-SRAM]

FIG. 39H illustrates an example of a static random access memory (SRAM) using an OS transistor. In this specification and the like, an SRAM using an OS transistor is referred to as an oxide semiconductor SRAM (OS-SRAM). A memory cell 958 illustrated in FIG. 39H is a memory cell of an SRAM capable of backup operation.

The memory cell 958 includes transistors M7 to M10, transistors MS1 to MS4, and capacitors CD1 and CD2. The transistors MS1 and MS2 are p-channel transistors, and the transistors MS3 and MS4 are n-channel transistors.

A first terminal of the transistor M7 is connected to the wiring BIL. A second terminal of the transistor M7 is connected to a first terminal of the transistor MS1, a first terminal of the transistor MS3, a gate of the transistor MS2, a gate of the transistor MS4, and a first terminal of the transistor M10. A gate of the transistor M7 is connected to the wiring WOL. A first terminal of the transistor M8 is connected to a wiring BILB. A second terminal of the transistor M8 is connected to a first terminal of the transistor MS2, a first terminal of the transistor MS4, a gate of the transistor MS1, a gate of the transistor MS3, and a first terminal of the transistor M9. A gate of the transistor M8 is connected to the wiring WOL.

A second terminal of the transistor MS1 is electrically connected to a wiring VDL. A second terminal of the transistor MS2 is electrically connected to the wiring VDL. A second terminal of the transistor MS3 is electrically connected to the wiring GNDL. A second terminal of the transistor MS4 is electrically connected to the wiring GNDL.

A second terminal of the transistor M9 is connected to a first terminal of the capacitor CD1. A gate of the transistor M9 is connected to a wiring BRL. A second terminal of the transistor M10 is connected to a first terminal of the capacitor CD2. A gate of the transistor M10 is connected to the wiring BRL.

A second terminal of the capacitor CD1 is connected to the wiring GNDL. A second terminal of the capacitor CD2 is connected to the wiring GNDL.

The wiring BIL and the wiring BILB function as bit lines. The wiring WOL functions as a word line. The wiring BRL controls the on/off states of the transistors M9 and M10.

The wiring VDL supplies a high-level potential. The wiring GNDL supplies a low-level potential.

Data writing is performed by applying a high-level potential to the wiring WOL and the wiring BRL. Specifically, when the transistor M10 is on, a potential corresponding to data to be stored is applied to the wiring BIL, and the potential is written to the second terminal side of the transistor M10.

In the memory cell 958, the transistors MS1 and MS2 form an inverter loop; hence, an inversion signal of a data signal corresponding to the potential is input to the second terminal side of the transistor M8. Since the transistor M8 is on, an inversion signal of the potential that has been applied to the wiring BIL (i.e., the signal that has been input to the wiring BIL) is output to the wiring BILB. Since the transistor M9 and the transistor M10 are on, the potential of the second terminal of the transistor M7 is retained in the first terminal of the capacitor CD2, and the potential of the second terminal of the transistor M8 is retained in the first terminal of the capacitor CD1. After that, a low-level potential is applied to the wiring WOL and the wiring BRL to turn off the transistors M7 to M10, whereby the potential of the first terminal of the capacitor CD1 and the potential of the first terminal of the capacitor CD2 are retained.

Data reading is performed in such a manner that the wiring BIL and the wiring BILB are precharged to a predetermined potential, and then a high-level potential is applied to the wiring WOL and the wiring BRL, whereby the potential of the first terminal of the capacitor CD1 is refreshed by the inverter loop in the memory cell 958 and output to the wiring BILB. Furthermore, the potential of the first terminal of the capacitor CD2 is refreshed by the inverter loop in the memory cell 958 and output to the wiring BIL. Since the potentials of the wiring BIL and the wiring BILB are changed from the precharged potentials to the potentials of the first terminal of the capacitor CD2 and the first terminal of the capacitor CD1, the potential retained in the memory cell can be read on the basis of the potentials of the wiring BIL and the wiring BILB.

Note that the transistors M7 to M10 are preferably OS transistors. In this case, with the use of the transistors M7 to M10, written data can be retained for a long time, and thus the frequency of refresh operation for the memory cell can be decreased. Alternatively, refresh operation for the memory cell can be omitted. When the OS transistor described in Embodiment 1 is used as each of the transistors M7 to M10, the operation speed of the memory device can be improved. Furthermore, the area occupied by the memory cell can be reduced.

Note that the transistors MS1 to MS4 may be Si transistors.

### [Circuit Configuration Example]

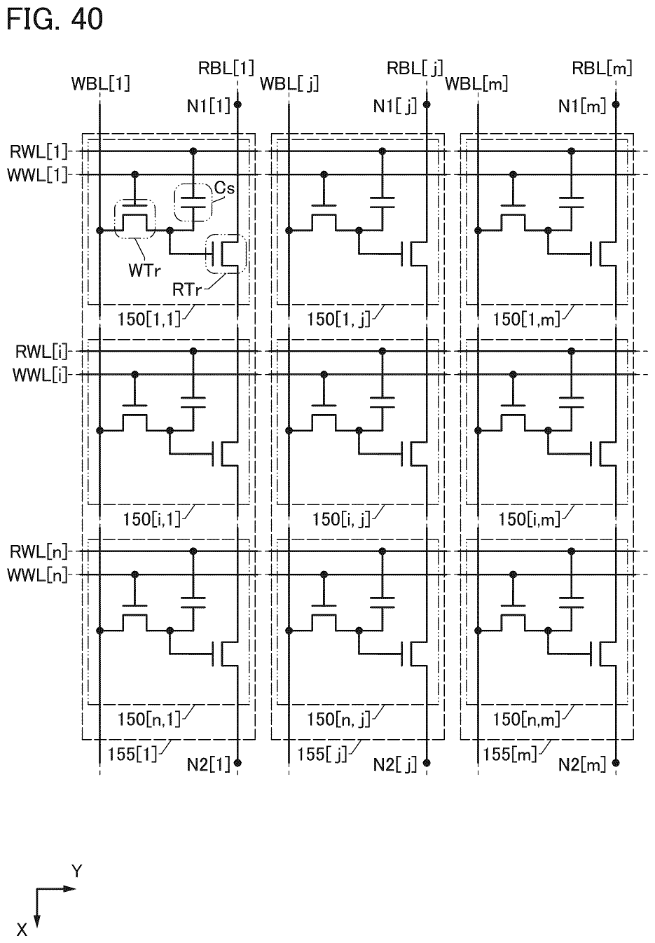

A circuit configuration example of the semiconductor device described in the above embodiment is described with reference to FIG. 40. The semiconductor device having a circuit configuration illustrated in FIG. 40 includes m memory strings 155 (m is an integer greater than or equal to 1). In this embodiment and the like, the first memory string 155 is denoted by a memory string 155[1], and the m-th memory string 155 is denoted by a memory string 155[m]. The j-th memory string 155 (j is an integer greater than or equal to 1 and less than or equal to m) is denoted by a memory string 155[j].

The memory string 155 includes n memory cells 150 (n is an integer greater than or equal to 1). In this embodiment and the like, the i-th memory cell 150 (i is an integer greater than or equal to 1 and less than or equal to n) included in the j-th memory string 155 is denoted as a memory cell 150[i,j]. Note that FIG. 35 and FIG. 37 are each also a plan view of a region including 2×2 memory cells 150 among the m×n memory cells 150 illustrated in FIG. 40.

The semiconductor device illustrated in FIG. 40 includes n wirings WWL, n wirings RWL, m wirings WBL, and m wirings RBL. In this embodiment and the like, the i-th wiring WWL and the i-th wiring RWL are denoted as a wiring WWL[i] and a wiring RWL[i]. The j-th wiring WBL and the j-th wiring RBL are denoted as a wiring WBL[j] and a wiring RBL[j].

A wiring WWL[1] is electrically connected to a gate of a transistor WTr included in each of memory cells 150[1,1] to 150[1,m]. The wiring WWL[i] is electrically connected to the gate of the transistor WTr included in each of memory cells 150[i,1] to 150[i,m]. A wiring WWL[n] is electrically connected to the gate of the transistor WTr included in each of memory cells 150[n,1] to 150[n,m]. The wiring WWL corresponds to the conductive layer 245a illustrated in FIG. 35 or FIG. 37.

A wiring RWL[1] is electrically connected to one of a pair of electrodes of a capacitor Cs included in each of the memory cells 150[1,1] to 150[1,m]. The wiring RWL[i] is electrically connected to one of the pair of electrodes of the capacitor Cs included in each of the memory cells 150[i,1] to 150[i,m]. A wiring RWL[n] is electrically connected to one of the pair of electrodes of the capacitor Cs included in each of the memory cells 150[n,1] to 150[n,m]. The wiring RWL is connected to a gate of a transistor RTr through the capacitor Cs. The wiring RWL corresponds to the conductive layer 245c illustrated in FIG. 35 or FIG. 37.

A wiring WBL[1] is electrically connected to one of a source and a drain of the transistor WTr included in each of the memory cells 150[1,1] to 150[n,1]. The wiring WBL[j] is electrically connected to one of the source and the drain of the transistor WTr included in each of the memory cells 150[1,j] to 150[n,j]. A wiring WBL[m] is electrically connected to one of the source and the drain of the transistor WTr included in each of the memory cells 150[1,m] to 150[n,m]. The wiring WBL corresponds to the conductive layer 245b illustrated in FIG. 35 or FIG. 37.

The memory string 155[1] has a structure in which n transistors RTr included in the memory string 155[1] are connected in series. A memory string 155[2] to the memory string 155[m] each have a structure similar to the above. That is, the memory string 155 is a NAND-like memory device.

A wiring RBL[1] is electrically connected to one of a source and a drain of the transistor RTr included in the memory cell 150[1,1]. The wiring RBL[j] is electrically connected to one of the source and the drain of the transistor RTr included in the memory cell 150[1,j]. A wiring RBL[m] is electrically connected to one of the source and the drain of the transistor RTr included in the memory cell 150[1,m]. The wiring RBL corresponds to the conductive layer 242c illustrated in FIG. 35, or the conductive layer 242c or the semiconductor layer 230b illustrated in FIG. 37.

The wiring WWL functions as a write word line, the wiring RWL functions as a read word line, the wiring WBL functions as a write bit line, and the wiring RBL functions as a read bit line.

In the memory string 155[1] illustrated in FIG. 40, a region electrically connected to one of the source and the drain of the transistor RTr included in the memory cell 150[1,1] is denoted as a node N1[1], and a region electrically connected to the other of the source and the drain of the transistor RTr in the memory cell 150[ₙ,1] is denoted as a node N2[1]. Similarly, a node N1 and a node N2 of the memory string 155[j] are denoted by a node N1[j] and a node N2[j], respectively, and the node N1 and the node N2 of the memory string 155[m] are denoted by a node N1[m] and a node N2[m], respectively.

### [Operation Method Example]

Next, an example of the operation method for the semiconductor device illustrated in FIG. 40 will be described. In this embodiment, an operation example of writing data to the memory cell 150 included in the memory string 155[1] and an operation example of reading data therefrom will be described.

Note that in the following description, a low-level potential (Low) and a high-level potential (High) do not represent any particular potentials, and specific potentials may vary depending on wirings. For example, a low-level potential and a high-level potential supplied to the wiring WWL may be different from a low-level potential and a high-level potential supplied to the wiring RWL.

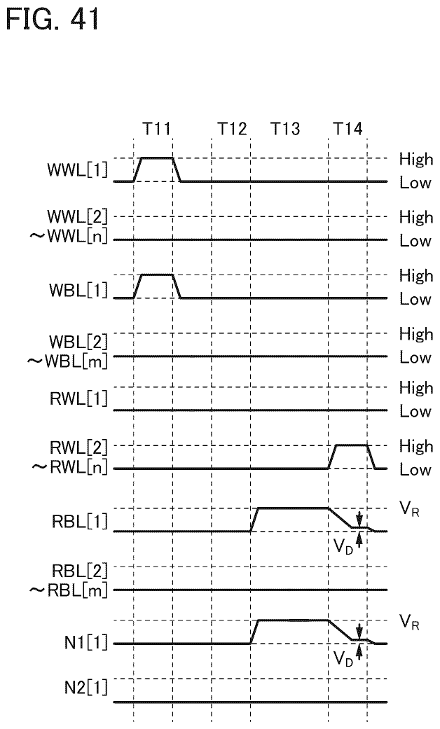

FIG. 41 is a timing chart showing an example of a method for driving the semiconductor device illustrated in FIG. 40. The timing chart in FIG. 41 shows the relationship between the potentials of the wirings in collective erasing in the memory string 155[1], writing in the first row of the memory string 155[1], and reading in the first row of the memory string 155[1]. FIG. 41 shows changes in potential level of the wiring WWL[1], a wiring WWL[2] to the wiring WWL[n], the wiring WBL[1], a wiring WBL[2] to the wiring WBL[m], the wiring RWL[1], a wiring RWL[2] to the wiring RWL[n], the wiring RBL[1], a wiring RBL[2] to the wiring RBL[m], the node N1[1], and the node N2[1]. As for the wiring WBL[1], data supplied to the wiring WBL[1] is shown.

In write operation in the first row of the memory string 155[1], data “1” is written to the memory cell 150[1,1] of the memory string 155[1], and data “0” is written to a memory cell 150[2,1] to the memory cell 150[n,1]. In read operation in the first row of the memory string 155[1], data written to the first row of the memory string 155[1] is read out. Note that in this operation, the data “1” is stored in the memory cell 150[1,1], and the data “O” is stored in the memory cells 150[2,1] to 150[n,1].

### <Write Operation>

FIG. 41 shows an example in which data is written to the memory cell 150[1,1]. In a period T11, a high-level potential is supplied to the wiring WWL[1]. Thus, the transistor WTr included in the memory cell 150[1,1] is sufficiently turned on. In addition, a low-level potential is supplied to each of the wirings WWL[2] to WWL[n]. Thus, the transistors WTr included in the memory cells 150[2,1] to 150[n,1] are turned off. Then, data is supplied to the wiring WBL[1], and a low-level potential is supplied to each of the wirings WBL[2] to WBL[m]. Since the transistor WTr included in the memory cell 150[1,1] is sufficiently on, the data reaches and is written to the storage node of the memory cell 150[1,1]. Since the transistors WTr included in the memory cells 150[2.1] to 150[n,1] are off, the data stored in the storage node of the respective memory cells 150[2,1] to 150[n,1] are retained.

As a result, the above-described data is supplied to the storage node of the memory cell 150[1,1], that is, the data “1” is written to the storage node of the memory cell 150[1,1]. In addition, a low-level potential is supplied to the storage node of each of a memory cell 150[1,2] to the memory cell 150[1,m], that is, the data “O” is written to the storage node of each of the memory cells 150[1,2] to 150[1,m].

A low-level potential is supplied to each of the wirings WBL[2] to WBL[m] electrically connected to the memory strings 155[2] to 155[m], respectively, whereby data retained in the memory cells 150[2,1] to 150[n,m] can be retained.

This embodiment describes the write operation with the focus on the memory string 155[1]; in the circuit configuration of the semiconductor device, when a high-level potential is supplied to the wiring WWL[i], the transistors WTr electrically connected to the wiring WWL[i] are all turned on. Thus, data writing to the memory strings 155[2] to 155[m] is performed concurrently with data writing to the memory string 155[1].

### <Read Operation>

FIG. 41 shows an example in which data is read from the memory cell 150[1,1]. In a period T12, the wirings WWL[1] to WWL[n], the wirings RWL[1] to RWL[n], the wirings WBL[1] to WBL[m], the node N1[1], and the node N2[1] each have a low-level potential.

In a period T13, a potential I′R is supplied to the wiring RBL[1]. Then, the wiring RBL[1] is brought into an electrically floating state. Accordingly, the potential of the node N1[1] becomes VR.

In a period T14, a low-level potential is supplied to the wiring RWL[1] connected to the memory cell 150 subjected to reading (the memory cell 150[1,1]). In addition, a high-level potential is supplied to each of the wirings RWL[2] to RWL[n] connected to the memory cells 150 not subjected to reading (the memory cells 150[2,1] to 150[n,1]). Thus, the transistors RTr included in the memory cells 150[2,1] to 150[ₙ,1] are sufficiently turned on. The on/off state of the transistor RTr in the memory cell 150[1,1] is determined based on the data retained in the storage node of the memory cell 150[1,1].

The potential of the node N1[1] is determined based on the potential VR of the node N1[1] and the data retained in the storage node of the memory cell 150[1,1]. Here, the potential of the node N1[1] is denoted by VD. By measurement of the potential VD of the node N1[1], the data retained in the storage node of the memory cell 150[1,1] can be read out.

For example, in the case where the data “1” is written to the storage node of the memory cell 150[1,1], electrical continuity is established between the node N2[1] and the node N1[1] that is connected to the memory cell 150[1,1], and the potential of the node N1[1] decreases (see FIG. 41). Meanwhile, in the case where the data “0” is written to the storage node of the memory cell 150[1,1], electrical continuity is not established between the node N2[1] and the node N1[1] that is connected to the memory cell 150[1,1], and the node N1[1] has the potential VR.

Note that a low-level potential is supplied to each of the wirings WWL[1] to WWL[n], whereby data retained in the storage node of each of the memory cells 150[1,1] to 150[n,m] can be retained.

Although the case where 2-level (1-bit) data is written to the memory cell in the method for driving the semiconductor device is described, a multilevel technique in which any of three or more levels of data is written to one of the memory cells may be employed. For example, data such as 4-level (2-bit) data, 8-level (3-bit) data, or 16-level (4-bit) data may be retained in the memory cell.

This embodiment describes the read operation with the focus on the memory string 155[1]; in the circuit configuration of the semiconductor device, data reading from the memory strings 155[2] to 155[m] can be performed concurrently with data reading from the memory string 155[1]. By turning off the transistor WTr, data retained in the storage node is not corrupted during the data read operation. Thus, only data included in the targeted memory string 155 can be read out.

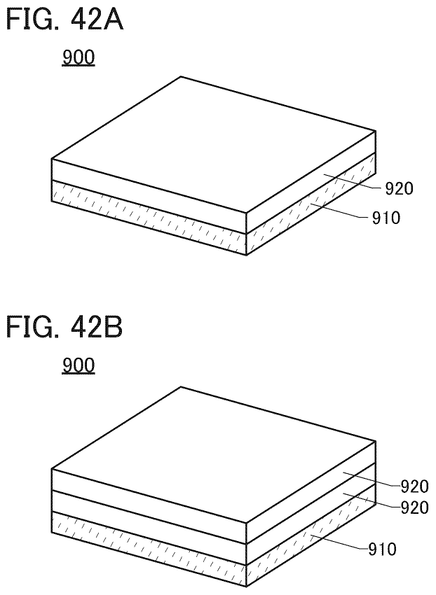

The driver circuit 910 and the memory array 920 included in the semiconductor device 900 may be provided on the same plane. Alternatively, as illustrated in FIG. 42A, the driver circuit 910 and the memory array 920 may be provided to overlap with each other. Overlapping the driver circuit 910 and the memory array 920 can shorten a signal propagation distance. As illustrated in FIG. 42B, a plurality of memory arrays 920 may be stacked over the driver circuit 910.

In the above memory array 920, a plurality of memory arrays 920[1] to 920[m] can be stacked. The memory arrays 920[1] to 920[m] included in the memory array 920 are arranged in a direction perpendicular to a surface of a substrate on which the driver circuit 910 is provided, in which case the memory density of the memory cells 951 can be increased. The memory arrays 920 can be formed by repeating the same manufacturing process in the vertical direction. In the semiconductor device 900, the manufacturing cost of the memory array 920 can be reduced.

Next, description is made on an example of an arithmetic processing device that can include the semiconductor device, such as the memory device described above.

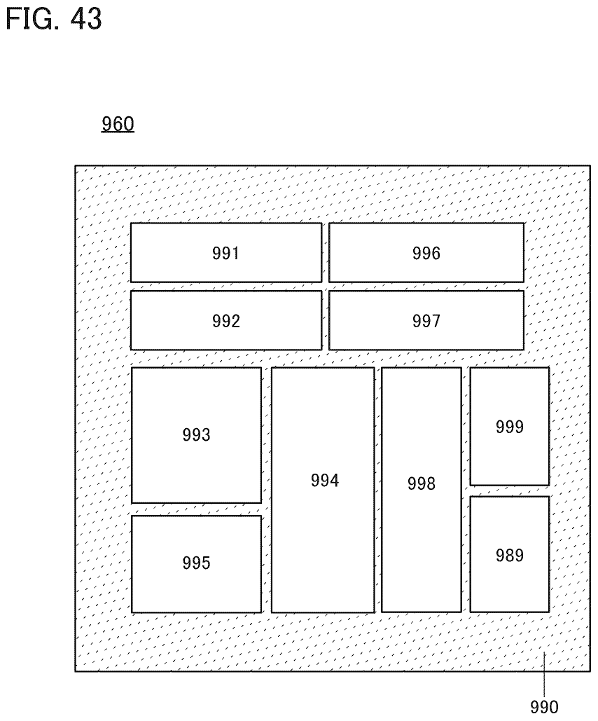

FIG. 43 is a block diagram of an arithmetic device 960. The arithmetic device 960 illustrated in FIG. 43 can be used for a CPU, for example. The arithmetic device 960 can also be used for a processor including a larger number of (several tens to several hundreds of) processor cores capable of parallel processing than a CPU, such as a graphics processing unit (GPU), a tensor processing unit (TPU), or a neural processing unit (NPU).

The arithmetic device 960 illustrated in FIG. 43 includes, over a substrate 990, an arithmetic logic unit (ALU) 991, an ALU controller 992, an instruction decoder 993, an interrupt controller 994, a timing controller 995, a register 996, a register controller 997, a bus interface 998, a cache 999, and a cache interface 989. A semiconductor substrate, an SOI substrate, a glass substrate, or the like is used as the substrate 990. The arithmetic device 960 may also include a rewritable ROM and a ROM interface. The cache 999 and the cache interface 989 may be provided in a separate chip.

The cache 999 is connected via the cache interface 989 to a main memory provided in another chip. The cache interface 989 has a function of supplying part of data retained in the main memory to the cache 999. The cache interface 989 also has a function of outputting part of data retained in the cache 999 to the ALU 991, the register 996, or the like through the bus interface 998.

As described later, the memory array 920 can be stacked over the arithmetic device 960. The memory array 920 can be used as a cache. Here, the cache interface 989 may have a function of supplying data retained in the memory array 920 to the cache 999. Moreover, in this case, the driver circuit 910 is preferably included in part of the cache interface 989.

Note that it is also possible that the cache 999 is not provided and only the memory array 920 is used as a cache.

The arithmetic device 960 illustrated in FIG. 43 is only an example with a simplified configuration, and the actual arithmetic device 960 has a variety of configurations depending on the application. For example, what is called a multicore configuration is preferably employed in which a plurality of cores each including the arithmetic device 960 in FIG. 43 operate in parallel. The larger number of cores can further enhance the arithmetic performance. The number of cores is preferably larger; for example, the number is preferably 2, further preferably 4, still further preferably 8, still further preferably 12, yet still further preferably 16 or larger. For application requiring extremely high arithmetic performance, e.g., a server, it is preferable to employ the multicore configuration including 16 or more, preferably 32 or more, further preferably 64 or more cores. The number of bits that the arithmetic device 960 can handle with an internal arithmetic circuit or a data bus can be 8, 16, 32, or 64, for example.

An instruction input to the arithmetic device 960 through the bus interface 998 is input to the instruction decoder 993 and decoded, and then input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction. Specifically, the ALU controller 992 generates signals for controlling the operation of the ALU 991. The interrupt controller 994 judges and processes an interrupt request from an external input/output device, a peripheral circuit, or the like on the basis of its priority, a mask state, or the like while the arithmetic device 960 is executing a program. The register controller 997 generates the address of the register 996, and reads/writes data from/to the register 996 in accordance with the state of the arithmetic device 960.

The timing controller 995 generates signals for controlling operation timings of the ALU 991, the ALU controller 992, the instruction decoder 993, the interrupt controller 994, and the register controller 997. For example, the timing controller 995 includes an internal clock generator for generating an internal clock signal on the basis of a reference clock signal, and supplies the internal clock signal to the above circuits.

In the arithmetic device 960 in FIG. 43, the register controller 997 selects operation of retaining data in the register 996 in accordance with an instruction from the ALU 991. That is, the register controller 997 selects whether data is retained by a flip-flop or by a capacitor in a memory cell included in the register 996. When data retention by the flip-flop is selected, power supply voltage is supplied to the memory cell in the register 996. When data retention by the capacitor is selected, the data is rewritten into the capacitor, and supply of power supply voltage to the memory cell in the register 996 can be stopped.

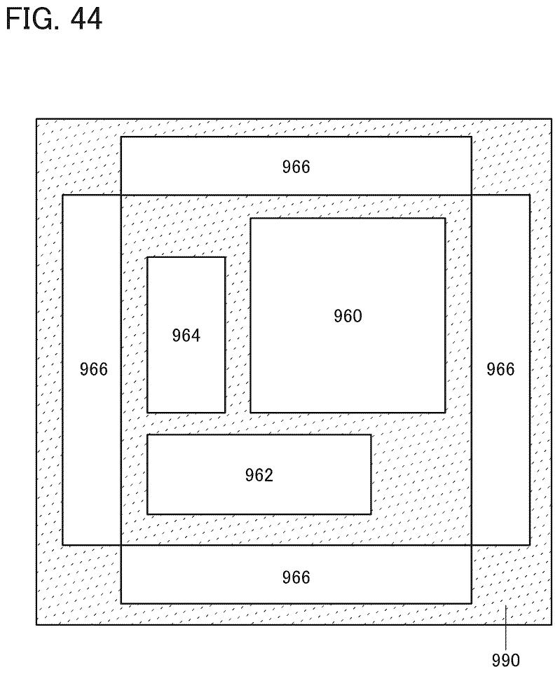

FIG. 44 illustrates an example in which the substrate 990 is provided with not only the arithmetic device 960 but also a memory device 962, an interface circuit 964, an input/output portion 966, and the like.

The memory device 962 can be used as a cache at a lower level than the cache 999 or as a main memory. The memory device 962 is connected to the cache interface 989 in the arithmetic device 960 through the interface circuit 964. The memory device 962 is connected to a main memory provided in another chip through the interface circuit 964 and the input/output portion 966.

The semiconductor device 900 including the memory array 920 can be used for the memory device 962.

The interface circuit 964 is provided with a variety of interface circuits and a bus line. The interface circuit 964 may include a power supply circuit, a clock generation circuit, or the like.

The interface circuit 964 can be provided with an inter integrated circuit (I2C), a serial peripheral interface (SPI), a general purpose input/output (GPIO), or the like.

The input/output portion 966 includes an input portion to which a signal, a potential, or the like is input from the outside, and an output portion from which a signal is output to the outside. The input/output portion 966 is provided with a plurality of connection terminals, and is connected to a substrate different from the substrate 990 through a connection wiring. Moreover, the input/output portion 966 may be provided with a buffer circuit, a protection circuit, or the like.

The substrate 990 can be connected to another substrate by a method such as wire bonding using a gold or copper wiring, flip-chip bonding using a bump, or direct bonding (hybrid bonding) using a direct bonding technique such as Cu—Cu bonding. Alternatively, as a bonding method without using a substrate, the following method may be used: two or more layers are bonded to each other with an insulating film and then a through electrode is formed, whereby electrodes or the like provided in the layers are connected to each other. A method using direct bonding or a through electrode is particularly preferably used, in which case the pitch width between connection electrodes can be extremely narrowed and thus a large number of connection electrodes can be arranged at high density, whereby a larger amount of data can be transmitted between layers.

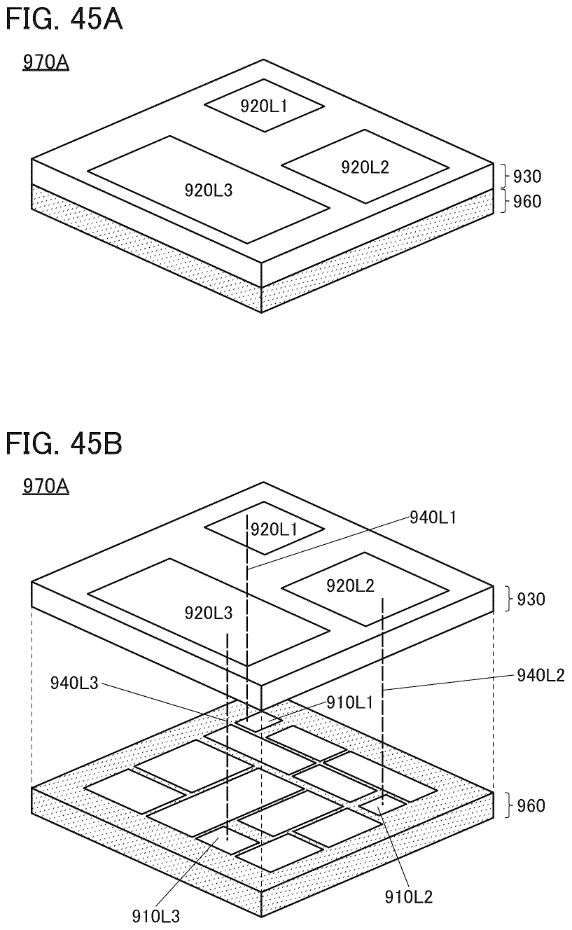

The memory array 920 and the arithmetic device 960 can be provided to overlap with each other. FIGS. 45A and 45B are perspective views of a semiconductor device 970A. The semiconductor device 970A includes a layer 930 provided with memory arrays over the arithmetic device 960. A memory array 920L1, a memory array 920L2, and a memory array 920L3 are provided in the layer 930. The arithmetic device 960 and each of the memory arrays overlap with each other. For easy understanding of the structure of the semiconductor device 970A, the arithmetic device 960 and the layer 930 are separately illustrated in FIG. 45B.

Overlapping the arithmetic device 960 and the layer 930 including the memory arrays can shorten the connection distance therebetween. Accordingly, the communication speed therebetween can be increased. Moreover, a short connection distance leads to lower power consumption.

As a method for stacking the layer 930 including the memory arrays and the arithmetic device 960, either of the following methods may be employed: a method in which the layer 930 including the memory arrays is stacked directly on the arithmetic device 960, which is also referred to as monolithic stacking, and a method in which the arithmetic device 960 and the layer 930 are formed over two different substrates, the substrates are bonded to each other, and the arithmetic device 960 and the layer 930 are electrically connected to each other with a through via or by a technique for bonding conductive films (e.g., Cu—Cu bonding). The former method does not require consideration of misalignment in bonding; thus, not only the chip size but also the manufacturing cost can be reduced.

Here, it is possible that the arithmetic device 960 does not include the cache 999 and the memory arrays 920L1, 920L2, and 920L3 provided in the layer 930 are each used as a cache. In this case, for example, the memory array 920L1, the memory array 920L2, and the memory array 920L3 can be used as an L1 cache (also referred to as a level 1 cache), an L2 cache (also referred to as a level 2 cache), and an L3 cache (also referred to as a level 3 cache), respectively. Among the three memory arrays, the memory array 920L3 has the largest capacity and the lowest access frequency. The memory array 920L1 has the smallest capacity and the highest access frequency.

Note that in the case where the cache 999 provided in the arithmetic device 960 is used as the L1 cache, the memory arrays provided in the layer 930 can each be used as the lower-level cache or the main memory. The main memory has higher capacity and lower access frequency than the cache.

As illustrated in FIG. 45B, a driver circuit 910L1, a driver circuit 910L2, and a driver circuit 910L3 are provided. The driver circuit 910L1 is connected to the memory array 920L1 through a connection electrode 940L1. Similarly, the driver circuit 910L2 is connected to the memory array 920L2 through a connection electrode 940L2, and the driver circuit 910L3 is connected to the memory array 920L3 through a connection electrode 940L3.

Note that although the case where three memory arrays function as caches is described here, the number of memory arrays may be one, two, or four or more.

In the case where the memory array 920L1 is used as a cache, the driver circuit 910L1 may function as part of the cache interface 989 or the driver circuit 910L1 may be connected to the cache interface 989. Similarly, each of the driver circuits 910L2 and 910L3 may function as part of the cache interface 989 or be connected thereto.

Whether the memory array 920 functions as the cache or the main memory is determined by the control circuit 912 included in each of the driver circuits 910. The control circuit 912 can make some of the memory cells 950 in the semiconductor device 900 function as RAM in accordance with a signal supplied from the arithmetic device 960.

In the semiconductor device 900, some of the memory cells 950 can function as the cache and the other memory cells 950 can function as the main memory. That is, the semiconductor device 900 can have both the function of the cache and the function of the main memory. The semiconductor device 900 of one embodiment of the present invention can function as a universal memory, for example.

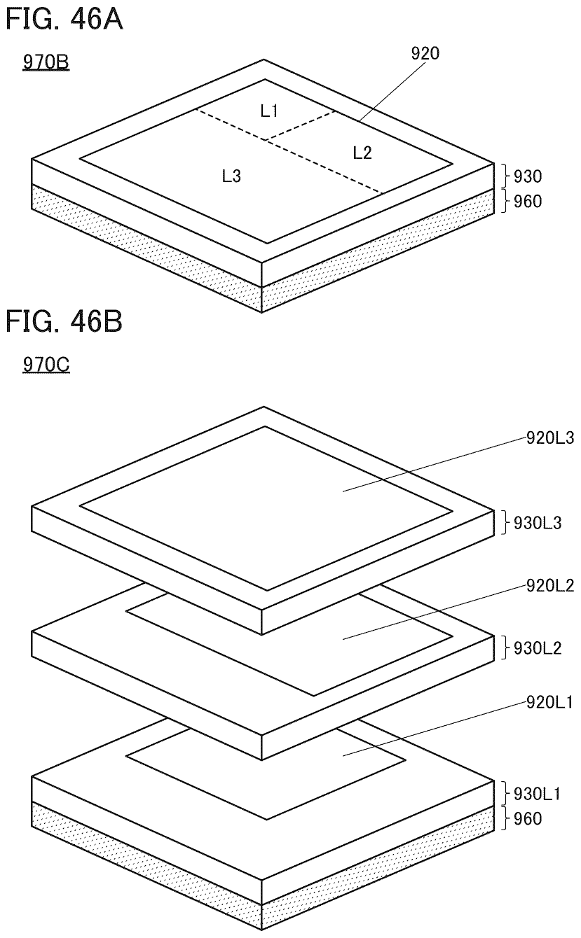

The layer 930 including one memory array 920 may be provided to overlap with the arithmetic device 960. FIG. 46A is a perspective view of a semiconductor device 970B.

In the semiconductor device 970B, one memory array 920 can be divided into a plurality of areas having different functions. FIG. 46A illustrates an example in which a region L1, a region L2, and a region L3 are used as the L1 cache, the L2 cache, and the L3 cache, respectively.

In the semiconductor device 970B, the capacity of each of the regions L1 to L3 can be changed depending on circumstances. For example, the capacity of the L1 cache can be increased by increasing the area of the region L1. With such a structure, the arithmetic processing efficiency can be improved and the processing speed can be improved.

Alternatively, a plurality of memory arrays may be stacked. FIG. 46B is a perspective view of a semiconductor device 970C.

In the semiconductor device 970C, a layer 930L1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic device 960 can be used as a high-level cache, and the memory array 920L3 physically farthest from the arithmetic device 960 can be used as a low-level cache or a main memory. Such a structure can increase the capacity of each memory array, leading to higher processing capability.

Note that this embodiment can be combined with any of the other embodiments in this specification as appropriate.

### Embodiment 3

In this embodiment, application examples of the memory device of one embodiment of the present invention will be described.

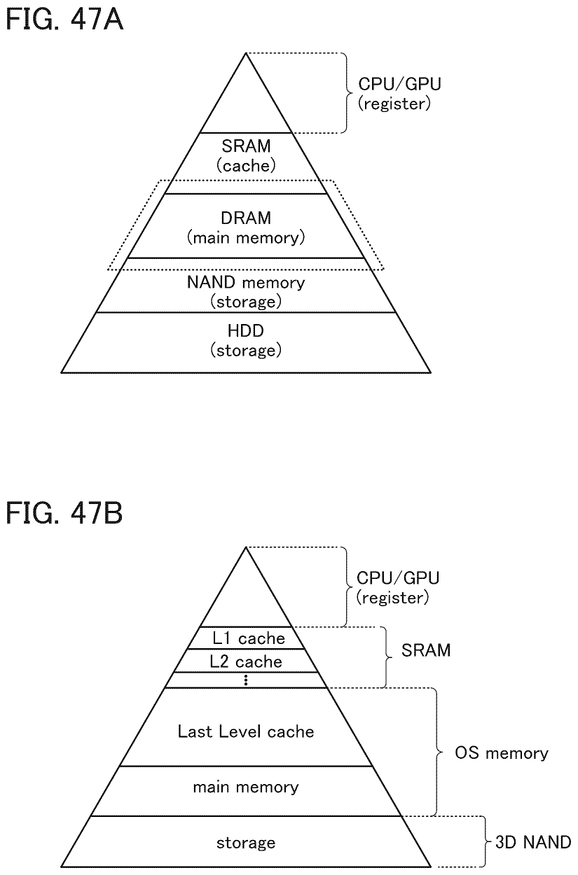

First, a hierarchy of memory devices used for the semiconductor device is described. FIG. 47A illustrates a conventional hierarchy of memory devices.

In FIG. 47A, memory devices closer to a processor (CPU/GPU) are accessed more frequently, and memory devices in a layer of the hierarchy with a longer base have larger data capacity. The memory devices closer to the processor require higher operation speed, and the memory devices farther from the processor require larger memory capacity and higher recording density. FIG. 47A illustrates an example in which a register is used as a memory included in the processor such as a CPU or a GPU, an SRAM is used as a cache memory, a DRAM is used as a main memory, and a NAND memory and a hard disk drive (HDD) are used as storage.

The memory included in the processor such as a CPU or a GPU is used for temporary storage of arithmetic operation results, for example, and thus is very frequently accessed by an arithmetic processing device. Accordingly, rapid operation is more important than the memory capacity of the memory. The register also has a function of retaining settings of the arithmetic processing device, for example.

The cache has a function of duplicating and retaining part of data retained in the main memory. Duplicating frequently used data and retaining the duplicated data in the cache facilitates rapid data access. The cache requires a smaller memory capacity than the main memory, but requires higher operation speed than the main memory. Data that is rewritten in the cache is duplicated, and the duplicated data is supplied to the main memory.

The main memory has a function of retaining a program and data that are read from the storage.

The storage has a function of retaining data that needs to be stored for a long time and programs used in the arithmetic processing device, for example. Therefore, the storage needs to have large memory capacity and high recording density rather than operation speed. For example, a high-capacity nonvolatile memory device such as an HDD or a NAND memory such as a 3D NAND memory can be used.

In one embodiment of the present invention, at least the DRAM used as the main memory among the various memory devices illustrated in FIG. 47A is replaced with a memory device using an oxide semiconductor (an OS memory). Refresh operation is essential particularly for the DRAM among the various memory devices, and the DRAM is a destructive read memory device and thus consumes significantly higher power than other memory devices. Therefore, power consumption can be significantly reduced by not using the DRAM. Note that in FIG. 47A, among the various memory devices, the memory devices to be replaced with an OS memory are in a range surrounded by a dashed line. That is, not only the DRAM used as the main memory but also some SRAMs used as the cache and some NAND memories used as the storage can be replaced with OS memories.

FIG. 47B shows an example of the semiconductor device of one embodiment of the present invention. FIG. 47B is a schematic view illustrating the hierarchy of various memory devices used in the semiconductor device.

Caches illustrated in FIG. 47B are a plurality of caches (the L1 and L2 caches) and a last level cache (LLC).

The plurality of caches are provided in the descending order of level, i.e., in the order of the L1 cache and the L2 cache. The higher-level cache is more frequently accessed by the processor, and thus is required to operate at higher speed. Since the operation speed can also be improved by reducing data capacity, the higher-level cache preferably has smaller data capacity. The high-level cache is preferably provided physically closer to the processor and connected through a shorter wiring, and thus is preferably provided in the same layer as the processor. The low-level cache and the processor may be provided in different layers.

The lowest-level cache can be referred to as an LLC. The LLC does not require higher operation speed than a higher-level cache, but desirably has large memory capacity. An after-mentioned OS memory of one embodiment of the present invention operates at high speed and can retain data for a long time, and thus can be suitably used as the LLC. Note that the OS memory of one embodiment of the present invention can also be used as a final level cache (FLC).

An SRAM can be used as each of the various caches. An OS memory can be suitably used as each of the LLC and the main memory. The memory device can operate at high speed and can retain data for a long time.

The structure exemplified above includes not a DRAM, which has been conventionally used as a main memory or the like, but the OS memory of one embodiment of the present invention.

Such a structure can achieve a drastic reduction in power consumption (to one-hundredth or less or one-thousandth or less of the power consumption in the case of using a DRAM). Thus, worldwide expansion of information processing devices including a computer, a server, or the like employing such a structure is expected to highly contribute to inhibition of global warming.

Note that this embodiment can be combined with any of the other embodiments in this specification as appropriate.

### Embodiment 4

An electronic device, a large computer, space equipment, and a data center (also referred to as DC) for which the semiconductor device described in the above embodiments can be used will be described in this embodiment. An electronic device, a large computer, space equipment, and a data center each including the semiconductor device of one embodiment of the present invention are effective in improving performance, for example, reducing power consumption.

### [Electronic Device]

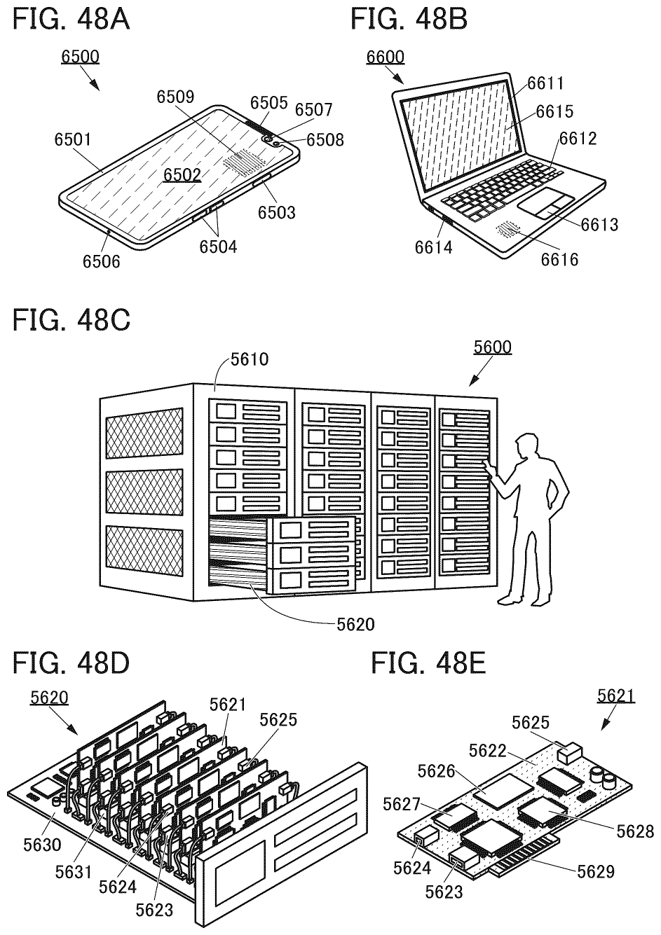

FIG. 48A is a perspective view of an electronic device 6500. The electronic device 6500 illustrated in FIG. 48A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, a control device 6509, and the like. Note that as the control device 6509, for example, one or more selected from a CPU, a GPU, and a memory device are included. The semiconductor device of one embodiment of the present invention can be used for the display portion 6502, the control device 6509, and the like.

An electronic device 6600 illustrated in FIG. 48B is an information terminal that can be used as a laptop computer. The electronic device 6600 includes a housing 6611, a keyboard 6612, a pointing device 6613, an external connection port 6614, a display portion 6615, a control device 6616, and the like. Note that as the control device 6616, for example, one or more selected from a CPU, a GPU, and a memory device are included. The semiconductor device of one embodiment of the present invention can be used for the display portion 6615, the control device 6616, and the like. Note that the semiconductor device of one embodiment of the present invention is preferably used for the control device 6509 and the control device 6616, in which case power consumption can be reduced.

### [Large Computer]

Next, FIG. 48C is a perspective view of a large computer 5600. In the large computer 5600 illustrated in FIG. 48C, a plurality of rack mount computers 5620 are stored in a rack 5610. Note that the large computer 5600 may be referred to as a supercomputer.

The computer 5620 can have a structure in a perspective view illustrated in FIG. 48D, for example. In FIG. 48D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 48E is an example of a processing board provided with a CPU, a GPU, a memory device, and the like. The PC card 5621 includes a board 5622. The board 5622 includes a connection terminal 5623, a connection terminal 5624, a connection terminal 5625, a semiconductor device 5626, a semiconductor device 5627, a semiconductor device 5628, and a connection terminal 5629. Note that FIG. 48E also illustrates semiconductor devices other than the semiconductor device 5626, the semiconductor device 5627, and the semiconductor device 5628, and the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. As another example, they can serve as an interface for outputting a signal calculated by the PC card 5621. Examples of the standard for each of the connection terminal 5623, the connection terminal 5624, and the connection terminal 5625 include Universal Serial Bus (USB), Serial ATA (SATA), and Small Computer System Interface (SCSI). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device or the like.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used as space equipment, such as devices processing and storing information.

The semiconductor device of one embodiment of the present invention can include an OS transistor. A change in electrical characteristics of the OS transistor due to radiation irradiation is small. That is, the OS transistor is highly resistant to radiation, and thus can be suitably used even in an environment where radiation can enter. For example, the OS transistor can be suitably used in outer space.

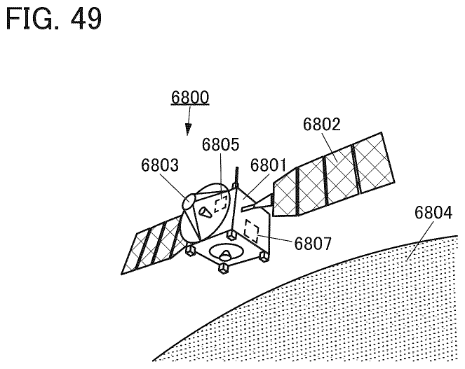

FIG. 49 illustrates an artificial satellite 6800 as an example of space equipment. The artificial satellite 6800 includes a body 6801, a solar panel 6802, an antenna 6803, a secondary battery 6805, and a control device 6807. In FIG. 49, a planet 6804 in outer space is illustrated as an example. Note that outer space refers to, for example, space at an altitude greater than or equal to 100 km, and outer space described in this specification may also include thermosphere, mesosphere, and stratosphere.

Although not illustrated in FIG. 49, a battery management system (also referred to as BMS) or a battery control circuit may be provided in the secondary battery 6805. The battery management system or the battery control circuit preferably uses the OS transistor, in which case it has low power consumption and high reliability even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device of one embodiment of the present invention is suitably used for the control device 6807. A change in electrical characteristics of the OS transistor due to radiation irradiation is smaller than a change in electrical characteristics of a Si transistor. Accordingly, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited to this example. The semiconductor device of one embodiment of the present invention can be suitably used for space equipment such as a spacecraft, a space capsule, or a space probe, for example.

As described above, an OS transistor has excellent effects of achieving a wide memory bandwidth and being highly resistant to radiation as compared with a Si transistor.

### [Data Center]

The semiconductor device of one embodiment of the present invention can be suitably used for, for example, a storage system in a data center or the like. Long-term management of data, such as guarantee of data immutability, is required for the data center. In the case where data is managed for a long term, it is necessary to increase the scale of data center facility for installation of storages and servers for storing an enormous amount of data, stable power supply for data retention, cooling equipment for data retention, or the like.

With use of the semiconductor device of one embodiment of the present invention for a storage system in a data center, electric power used for retaining data can be reduced and a semiconductor device for retaining data can be reduced in size. Accordingly, reductions in sizes of the storage system and the power supply for retaining data, downscaling of the cooling equipment, and the like can be achieved. Therefore, a space of the data center can be reduced.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention can achieve a data center that operates stably even in a high temperature environment. Thus, the reliability of the data center can be increased.

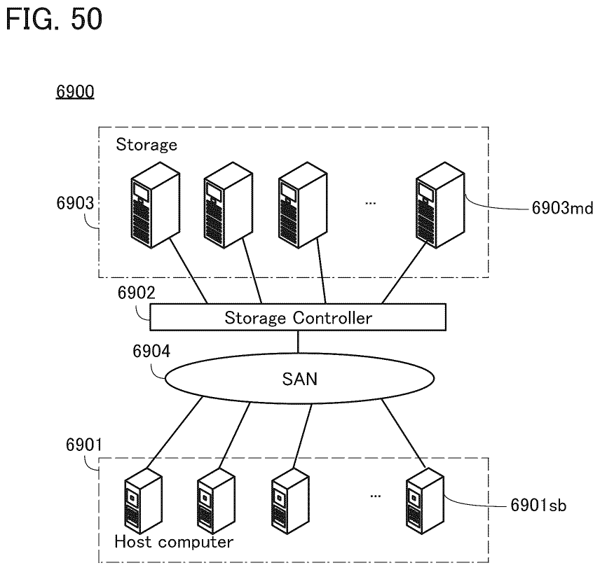

FIG. 50 illustrates a storage system that can be used in a data center. A storage system 6900 illustrated in FIG. 50 includes a plurality of servers 6901sb as a host 6901 (indicated as “Host computer” in the diagram). The storage system 6900 includes a plurality of memory devices 6903md as a storage 6903 (indicated as “Storage” in the diagram). In the illustrated example, the host 6901 and the storage 6903 are connected to each other through a storage area network 6904 (indicated as “SAN” in the diagram) and a storage control circuit 6902 (indicated as “Storage Controller” in the diagram).

The host 6901 corresponds to a computer which accesses data stored in the storage 6903. The host 6901 may be connected to another host 6901 through a network.

The data access speed, i.e., the time taken for storing and outputting data, of the storage 6903 is shortened by using a flash memory, but is still considerably longer than the data access speed of a DRAM that can be used as a cache memory in the storage 6903. In the storage system 6900, in order to solve the problem of low access speed of the storage 6903, a cache memory is normally provided in the storage 6903 to shorten the time for data storage and output. The above-described cache memory is used in the storage control circuit 6902 and the storage 6903. The data transmitted between the host 6901 and the storage 6903 is stored in the cache memories in the storage control circuit 6902 and the storage 6903 and then output to the host 6901 or the storage 6903.

With a configuration in which an OS transistor is used as a transistor for storing data in the cache memory to retain a potential based on data, the frequency of refreshing can be decreased, so that power consumption can be reduced. Furthermore, downscaling is possible by stacking memory cell arrays.

The use of the semiconductor device of one embodiment of the present invention for one or more selected from an electronic device, a large computer, space equipment, and a data center will produce an effect of reducing power consumption. While the demand for energy is expected to increase with higher performance or higher integration of semiconductor devices, the emission amount of greenhouse effect gases typified by carbon dioxide (CO₂) can be reduced with use of the semiconductor device of one embodiment of the present invention. Furthermore, the semiconductor device of one embodiment of the present invention has low power consumption and thus is effective as a global warming countermeasure.

The configurations, structures, methods, and the like described in this embodiment can be used in an appropriate combination with any of the configurations, structures, methods, and the like described in the other embodiments and the like.

This application is based on Japanese Patent Application Serial No. 2023-141469 filed with Japan Patent Office on Aug. 31, 2023 and Japanese Patent Application Serial No. 2023-147298 filed with Japan Patent Office on Sep. 12, 2023, the entire contents of which are hereby incorporated by reference.

What is claimed is:

1. A semiconductor device comprising:
a first transistor;
a second transistor; and
a first insulating layer,
wherein the first transistor comprises a first semiconductor layer, first to fifth conductive layers, and a second insulating layer,
wherein the second transistor comprises a second semiconductor layer, a sixth conductive layer, and a third insulating layer,
wherein the first semiconductor layer and the second semiconductor layer are positioned apart from each other over a substrate,
wherein the first conductive layer and the second conductive layer are positioned over the first semiconductor layer,
wherein the third conductive layer is positioned over the first conductive layer,
wherein the fourth conductive layer is positioned over the second conductive layer,
wherein the first insulating layer is positioned over the third conductive layer, the fourth conductive layer, and the second semiconductor layer and comprises a first opening and a second opening,
wherein the first opening overlaps with a region between the third conductive layer and the fourth conductive layer,
wherein the second opening overlaps with at least part of the second conductive layer and at least part of the second semiconductor layer,
wherein the second insulating layer overlaps with the first semiconductor layer in the first opening,
wherein the fifth conductive layer is positioned over the second insulating layer in the first opening,
wherein the third insulating layer overlaps with the second semiconductor layer in the second opening and comprises a third opening overlapping with at least the part of the second conductive layer,
wherein the sixth conductive layer comprises a region overlapping with the second semiconductor layer with the third insulating layer therebetween in the second opening, and a region in contact with at least the part of the second conductive layer in the third opening, and
wherein in a cross-sectional view in a channel width direction, a height of the first semiconductor layer is larger than a width of the first semiconductor layer.

2. The semiconductor device according to claim 1,
wherein in a cross-sectional view of the second transistor in a channel width direction, the first semiconductor layer comprises a region facing the second semiconductor layer.

3. The semiconductor device according to claim 1,
wherein a shortest distance between the first conductive layer and the second conductive layer is smaller than a shortest distance between the third conductive layer and the fourth conductive layer.

4. The semiconductor device according to claim 1, further comprising a fourth insulating layer,
wherein the fourth insulating layer comprises, in the first opening, a region in contact with at least part of a top surface of the first conductive layer, a region in contact with at least part of a top surface of the second conductive layer, a region in contact with a side surface of the third conductive layer, and a region in contact with a side surface of the fourth conductive layer.

5. The semiconductor device according to claim 1,
wherein the second transistor comprises seventh to tenth conductive layers,
wherein the seventh conductive layer and the eighth conductive layer are positioned over the second semiconductor layer,
wherein the ninth conductive layer is positioned over the seventh conductive layer,
wherein the tenth conductive layer is positioned over the eighth conductive layer, and
wherein the second opening overlaps with a region between the ninth conductive layer and tenth conductive layer.

6. The semiconductor device according to claim 5, further comprising a fifth insulating layer,
wherein the fifth insulating layer comprises, in the second opening, a region in contact with at least part of a top surface of the seventh conductive layer, a region in contact with at least part of a top surface of the eighth conductive layer, a region in contact with a side surface of the ninth conductive layer, a region in contact with a side surface of the tenth conductive layer, and a region in contact with a side surface of the fourth conductive layer and at least part of a top surface of the second conductive layer.

7. The semiconductor device according to claim 1,
wherein the first semiconductor layer comprises indium,
wherein the first semiconductor layer is perpendicular or substantially perpendicular to a surface of the substrate, and
wherein in cross-sectional observation of the first semiconductor layer with a transmission electron microscope, bright spots arranged in a layered manner in a direction perpendicular to the surface of the substrate are observed in each of the first to third regions.

8. The semiconductor device according to claim 1,
wherein the first semiconductor layer comprises indium,
wherein the first semiconductor layer is perpendicular or substantially perpendicular to a surface of the substrate,
wherein the first semiconductor layer comprises a first region, a second region in contact with the first region, and a third region in contact with the second region, and
wherein in cross-sectional observation of the first semiconductor layer with a transmission electron microscope, bright spots arranged in a layered manner in a direction perpendicular to the surface of the substrate are observed in each of the first to third regions.

9. The semiconductor device according to claim 8,
wherein the second region comprises zinc,
wherein the second region comprises a crystal, and
wherein a c-axis of the crystal is substantially parallel to a normal direction of a side surface of the first semiconductor layer.

10. The semiconductor device according to claim 8,
wherein the first region has a higher indium content than the second region, and
wherein the third region has a higher indium content than the second region.

11. A semiconductor device comprising:
a first transistor comprising a first semiconductor layer;
a second transistor comprising a second semiconductor layer;
a capacitor;
a third semiconductor layer; and
a first insulating layer,
wherein the first transistor comprises first to fifth conductive layers and a second insulating layer,
wherein the second transistor comprises a sixth conductive layer and a third insulating layer,
wherein the capacitor comprises a seventh conductive layer, the third insulating layer, and the sixth conductive layer,
wherein the first to third semiconductor layers are positioned apart from each other over a substrate,
wherein the first and second conductive layers are positioned over the first semiconductor layer,
wherein the third conductive layer is positioned over the first conductive layer,
wherein the fourth conductive layer is positioned over the second conductive layer,
wherein the seventh conductive layer is positioned over the third conductive layer,
wherein the first insulating layer is positioned over the third conductive layer, the fourth conductive layer, the second semiconductor layer, and the seventh conductive layer and comprises a first opening and a second opening,
wherein the first opening overlaps with a region between the third and fourth conductive layers,
wherein the second opening overlaps with at least part of the second conductive layer, at least part of the seventh conductive layer, and at least part of the second semiconductor layer,
wherein the second insulating layer overlaps with the first semiconductor layer in the first opening,
wherein the fifth conductive layer is positioned over the second insulating layer in the first opening,
wherein the third insulating layer overlaps with the second semiconductor layer in the second opening and comprises a third opening overlaps with at least the part of the second conductive layer,
wherein the sixth conductive layer comprises a region overlapping with the second semiconductor layer with the third insulating layer therebetween and a region overlapping with the seventh conductive layer with the third insulating layer therebetween in the second opening, and a region in contact with at least the part of the second conductive layer in the third opening, and
wherein in a cross-sectional view in a channel width direction, a height of the first semiconductor layer is larger than a width of the first semiconductor layer.

12. The semiconductor device according to claim 11,
wherein in a cross-sectional view of the second transistor in a channel width direction, the first semiconductor layer comprises a region facing the second semiconductor layer, and the second semiconductor layer comprises a region facing the third semiconductor layer.

13. The semiconductor device according to claim 11,
wherein a shortest distance between the first and second conductive layers is smaller than a shortest distance between the third conductive layer and the fourth conductive layer.

14. The semiconductor device according to claim 11, further comprising a fourth insulating layer,
wherein the fourth insulating layer comprises, in the first opening, a region in contact with at least part of a top surface of the first conductive layer, a region in contact with at least part of a top surface of the second conductive layer, a region in contact with a side surface of the third conductive layer, and a region in contact with a side surface of the fourth conductive layer.

15. The semiconductor device according to claim 11,
wherein the second transistor comprises eighth to eleventh conductive layers,
wherein the eighth and ninth conductive layers are positioned over the second semiconductor layer,
wherein the tenth conductive layer and the eleventh conductive layer are positioned over the eighth conductive layer and the ninth conductive layer, respectively, and
wherein the second opening overlaps with a region between the tenth conductive layer and the eleventh conductive layer.

16. The semiconductor device according to claim 15, further comprising a fifth insulating layer,
wherein the fifth insulating layer comprises, in the second opening, a region in contact with at least part of a top surface of the eighth conductive layer, a region in contact with at least part of a top surface of the ninth conductive layer, a region in contact with a side surface of the tenth conductive layer, a region in contact with a side surface of the eleventh conductive layer, a region in contact with a side surface of the fourth conductive layer and at least part of a top surface of the second conductive layer, and a region between the sixth conductive layer and the seventh conductive layer.

17. The semiconductor device according to claim 11,
wherein the first semiconductor layer comprises indium,
wherein the first semiconductor layer is perpendicular or substantially perpendicular to a surface of the substrate, and
wherein in cross-sectional observation of the first semiconductor layer with a transmission electron microscope, bright spots arranged in a layered manner in a direction perpendicular to the surface of the substrate are observed.

18. The semiconductor device according to claim 11,
wherein the first semiconductor layer comprises indium,
wherein the first semiconductor layer is perpendicular or substantially perpendicular to a surface of the substrate,
wherein the first semiconductor layer comprises a first region, a second region in contact with the first region, and a third region in contact with the second region, and
wherein in cross-sectional observation of the first semiconductor layer with a transmission electron microscope, bright spots arranged in a layered manner in a direction perpendicular to the surface of the substrate are observed in each of the first to third regions.

19. The semiconductor device according to claim 18,
wherein the second region comprises zinc,
wherein the second region comprises a crystal, and
wherein a c-axis of the crystal is substantially parallel to a normal direction of a side surface of the first semiconductor layer.

20. The semiconductor device according to claim 18,
wherein the first region has a higher indium content than the second region, and
wherein the third region has a higher indium content than the second region.
